(19) United States
(12) Patent Application Publication
(10) Pub. No.: US 2026/0014058 A1
(43) Pub. Date: Jan. 15, 2026

(54) METHODS AND SYSTEMS FOR COATING, CLEANING, AND INSPECTING PHARMACEUTICAL CONTAINERS FOR PARTICLES AND DEFECTS

(71) Applicant: SiO2 Medical Products, Inc., Auburn, AL (US)

(72) Inventors: Kenneth Wade Kelly, Auburn, AL (US); Eric S. Holmes, Auburn, AL (US); Robert S. Abrams, Auburn, AL (US); John Watson, Auburn, AL (US); Terry Braswell, Auburn, AL (US)

(21) Appl. No.: 18/876,019

(22) PCT Filed: Jun. 21, 2023
(86) PCT No.: PCT/US2023/068824

§ 371 Date: Dec. 17, 2024

Related U.S. Application Data
(60) Provisional application No. 63/353,846, filed on Jun. 21, 2022.
(60) Provisional application No. 63/355,400, filed on Jun. 24, 2022.

(51) Int. Cl. A61J 1/14; A61J 1/06; C23C 16/04; C23C 16/56; G01N 21/90

(52) U.S. Cl. CPC A61J 1/1468; A61J 1/065; A61J 1/1425; C23C 16/045; C23C 16/56; G01N 21/9018

(57) ABSTRACT

The present disclosure relates to methods and systems for coating pharmaceutical vessels. e.g. with a coating set that includes an oxygen barrier layer, that reduce the amount of particles present on the coated vessels. The present disclosure also relates to methods and systems for removing particles from vessels, e.g. after a coating is applied to an inner surface of the vessel. The present disclosure also relates to methods and systems for inspecting pharmaceutical vessels for particles prior to filling using machine-based visual analysis. Each of the above may be controlled and performed by one or more processors, thereby enabling a fully automated coating, cleaning, and/or inspecting operation for pharmaceutical vessels.

This application is a national stage entry of International Application No. PCT/US2023/068824, filed on Jun. 21, 2023, which claims priority to U.S. Provisional Patent Application No. 63/355,400, filed on Jun. 24, 2022, and U.S. Provisional Patent Application No. 63/353,846, filed on Jun. 21, 2022, the entirities of each of which are incorporated by reference herein.

### FIELD OF THE INVENTION

The field of the invention is the preparation of pharmaceutical containers, optionally ready-to-use containers, and particularly containers configured to be filled with injectable drugs such as vials, cartridges, and syringes, having few or no visible particles. The field of the invention is also the detection of visible particles and defects on ready-to-use pharmaceutical containers, and particularly containers configured to be filled with injectable drugs such as vials, cartridges, and syringes.

### BACKGROUND OF THE INVENTION

Because they offer a streamlined filling process, ready-to-use (RTU) containers are finding increased usage within the pharmaceutical industry. RTU containers, however, must be substantially free from visible defects and, in particular, removable particles.

The presence of particles in injectable drugs can pose serious risks to a patient. Accordingly, the USP requires certain guidelines regarding the presence of visible particles in injectable drugs, see USP <790> (“Visible Particulates in Injections”), and certain product quality tests for injectable drug products, see <1> (“Injections and Implanted Drug Products (Parenterals)—Product Quality Tests”). According to USP <790>, all products intended for parenteral administration must be visually inspected for the presence of particular matter as specified in Injections and Implanted Drug Products <1>. The products must be “essentially free” of visible particulates, as defined by USP <790> and USP <788> (“Particulate Matter in Injections”) or USP <789> (“Particulate Matter in Opthalmic Solutions”). USP <790>identifies sampling and inspection guidelines in ANSI/ASQ Z1.4 or SIO 2859-1 and identifies an AQL of 0.65%, also noting that alternative sampling plans with equivalent or better protection are acceptable. Indeed, pharmaceutical companies or contract development and manufacturing organizations (CDMOs) may require more stringent sampling plans and/or AQLs.

Typically, inspected units are examined manually and without magnification (except for optical correction as may be required to establish normal vision) against a black background and against a white background. An example of a workstation for manual visual inspection is shown in FIG. 1. Using a workstation such as that shown in FIG. 1, a trained visual inspector will examine a container against both a black background 1 and a white background 2 under a light source 3 of 2,000 to 3,750 lux, and with at least a five second viewing against each background. Another example workstation for the manual inspection is described in U.S. Pat. No. 5,940,176. That system utilizes opposing illumination sources above and below the vial, with the vial being positioned at a midpoint between the illumination sources. The background may be changeable between black and white backgrounds so that the vial can be inspected without moving it from the illumination midpoint.

Even when performed correctly, manual visual inspection is limited by the ability of the human eye to identify particles. Typically, for an empty container, the human eye is capable of seeing particles having sizes of about 80 micron or greater. According to some reports, during manual visual inspection, while the detection probability of a particle sized 200 micron or greater may be very high (e.g. close to 100%), that probability drops significantly (e.g. to 50% or less) for particles with sizes of about 100 micron and is close to 0% for particles with sizes less than 80 micron.

The automated visual inspection of empty containers, however, has been limited by the difficulty of an automated visual inspection system to accurately examine the transition regions of containers and/or to account for differences in the thickness of the container walls. Because of these problems, conventional automated visual inspection systems are not effective for the inspection of RTU containers to the levels required for injectable drugs.

Automated visual inspection systems have found some commercial use in detecting particulates in filled containers, i.e. after the container has been filled with an injectable drug product. In those systems, the filled container is spun so that any loose particles migrate to the centerline of the container. The automated visual inspection system thus need only inspect the container along that centerline. Because it relies on fluid being present within the container, such a system is infeasible for the visual inspection of empty containers such as RTU containers. Such a system also fails to inspect for visible particles that might remain adhered to the container wall or defects in the container wall.

One important consideration in manufacturing pharmaceutical packages or other vessels for storing or other contact with fluids, for example vials and pre-filled syringes, is that the contents of the pharmaceutical package or other vessel desirably will have a substantial shelf life. During this shelf life, it is important to isolate the material filling the pharmaceutical package or other vessel from the vessel wall containing it, or from barrier layers or other functional layers applied to the pharmaceutical package or other vessel wall to avoid leaching material from the pharmaceutical package or other vessel wall, barrier layer, or other functional layers into the prefilled contents or vice versa.

The traditional glass pharmaceutical packages or other vessels are prone to breakage or degradation during manufacture, filling operations, shipping, and use, which means that glass particulates may enter the drug. The presence of glass particles has led to many FDA Warning Letters and to product recalls.

As a result, some companies have turned to plastic pharmaceutical packages or other vessels, which provide greater dimensional tolerance and less breakage than glass, but its use for primary pharmaceutical packaging is limited due to its gas permeability: Plastic allows small molecule gases such as oxygen to permeate into (or out of) the article. In addition to oxygen, many plastic materials also allow moisture, i.e. water vapor, to permeate into (or out of) the article. The permeability of plastics to gases, such as oxygen and water vapor, is significantly greater than that of glass and, in many cases (as with oxygen-sensitive drugs such as epinephrine), plastics were historically unacceptable for that reason.

The problem of gas permeability has been addressed by adding an oxygen barrier coating or layer to the plastic pharmaceutical package. One such oxygen barrier layer is a very thin coating of SiOx, as defined below, e.g. applied by plasma enhanced chemical vapor deposition. Additional layers, such as a tie layer and/or a pH protective layer, e.g. as described and defined in U.S. Pat. No. 9,554,968, the entirety of which is incorporated herein by reference, may also be applied as part of a coating set applied to an inner surface of the vessel sidewall.

The coating of a vessel such an oxygen barrier coating or layer and/or with additional layers that may serve to improve the adhesion of the oxygen barrier coating or layer with the vessel wall, to protect the oxygen barrier coating or layer from dissolution by fluid stored within the lumen of the vessel, or both, however, may lead to the presence of particles on the vessel walls. In particular, when depositing one or more coatings or layers using PECVD, the coatings may deposit not only on the vessel walls as intended, but also on various components of the coating system. Flakes of coating may then be dislodged from the coating system component and may find their way onto a surface of the vessel, where they adhere as particles.

In coating systems of the sort described herein, for example, flakes of one or more PECVD coating materials that deposit on a source gas inlet probe using during the PECVD coating process may flake off and adhere to the inner wall of a vessel and/or the one or more surfaces of a vessel that are in direct contact with the system, typically an upper end surface of the vessel surrounding the opening to the lumen and a portion of an outer surface of a vessel side wall, e.g. upper and outer surfaces of a flange that surrounds the opening to the lumen.

### SUMMARY OF THE INVENTION

An aspect of the present invention is an automated system and method for visually inspecting pharmaceutical containers, e.g. ready-to-use (RTU) pharmaceutical containers, for the presence of particles and defects.

Embodiments of the present system and method may be configured to inspect the entirety or substantially the entirety of an RTU container, including all transition regions. Embodiments of the present system and method may also be configured to take into account variations in wall thickness and to differentiate particles or defects from thickness variations.

Embodiments of the present system and method may be configured to inspect an RTU container configured for the storage of an injectable drug, such as a vial, syringe barrel, or cartridge.

Embodiments of the present system and method may be configured to detect particles and defects having sizes as low as 25 micron.

Embodiments of the present system and method may be configured to detect particles within a range of sizes, for instance between 25 and 500 microns, alternatively between 30 and 500 microns, alternatively between 40 and 500 microns, alternatively between 50 and 500 microns, alternatively between 60 and 500 microns, alternatively between 70 and 500 microns, alternatively between 80 and 500 microns, alternatively between 25 and 400 microns, alternatively between 30 and 400 microns, alternatively between 40 and 400 microns, alternatively between 50 and 400 microns, alternatively between 60 and 400 microns, alternatively between 70 and 400 microns, alternatively between 80 and 400 microns, alternatively between 25 and 300 microns, alternatively between 30 and 300 microns, alternatively between 40 and 300 microns, alternatively between 50 and 300 microns, alternatively between 60 and 300 microns, alternatively between 70 and 300 microns, alternatively between 80 and 300 microns.

Other embodiments of the present system and method may be configured to detect visible particles that are less than 500 microns, alternatively less than 400 microns, alternatively less than 300 microns, alternatively less than 200 microns, alternatively less than 150 microns, alternatively less than 100 microns. Embodiments of the present system and method may be configured to detect particles that include those between 80 and 120 microns, between 50 and 80 microns, and/or between 25 and 50 microns.

Embodiments of the present system and method utilize a plurality of cameras, a plurality of lighting sources, and at least one processor. The system also comprises a plurality of vessel holders, which are configured to rotate the container in a controlled manner. The processor is configured to receive input from the plurality of cameras and process that information into output, i.e. particle detection information.

The system may comprise a body side camera, a shoulder angled camera, a top angled camera, a bottom angled camera, and a bottom camera. Each camera may be associated with an inspection station. A container may be moved between the plurality of inspection stations, which may include: a body side inspection station, a shoulder inspection station, a top inspection station, and a bottom transition region/bottom inspection station (note that the bottom angled camera that captures the bottom transition region of the container and the bottom camera that captures the bottom wall of the container may be associated with a single inspection station, though in other embodiments, there may be a separate/independent bottom transition region inspection station and bottom inspection station).

In order for embodiments of the present system and method to inspect the internal surfaces of the container, the container walls should be made of a transparent material, though it has been found that slight coloration may be present in the container walls and acceptable inspection results still obtained. In some embodiments, the container walls may be made of glass or plastic. In some embodiments, the container walls may be made of glass. In some embodiments, the container walls may be made of plastic. In some embodiments, the container walls may be made of a plastic selected from the group consisting of a polycarbonate, polystyrene, Polyethylene terephthalate (PET), polypropylene, polyethylene, polyamides, cyclic olefin polymer (COP), a cyclic olefin copolymer (COC), or a cyclic block copolymer (CBC). In some embodiments, the container walls may be made of a plastic selected from the group consisting of a cyclic olefin polymer (COP) or a cyclic olefin copolymer (COC).

In some embodiments, the container walls may comprise one or more coatings. For instance, the container walls may be made of a transparent plastic material and may comprise any one or more of the following coatings, each of which is configured to maintain the transparency of the vessel walls.

In some embodiments, for instance, at least one of the container walls may comprise an oxygen barrier coating or layer, the oxygen barrier coating or layer being effective to reduce the ingress of oxygen into the lumen compared to a container without the oxygen barrier coating or layer. For instance, at least one of the container walls may include an oxygen barrier coating or layer comprising or consisting essentially of SiOₓ, wherein x is from 1.5 to 2.9. The oxygen barrier coating or layer may be applied by plasma enhanced chemical vapor deposition (PECVD) or atomic layer deposition (ALD). In some embodiments, the oxygen barrier coating or layer may have a thickness of 1 to 1000 nm, optionally 2 to 1000 nm, optionally 10 to 1000 nm, optionally 10 to 500 nm, optionally 10 to 200 nm, optionally 20 to 100 nm. Particularly where the oxygen barrier coating or layer may be applied by ALD, the oxygen barrier coating or thickness may be between 1 and 15 nm thick, alternatively between 2 and 12 nm thick, alternatively between 3 and 10 nm thick, alternatively between 4 and 8 nm thick, alternatively between 5 and 7 nm thick. In some embodiments, the oxygen barrier coating or layer may be positioned between the interior surfaces of the vessel wall or walls and the lumen.

In addition to the oxygen barrier coating or layer, at least one of the container walls may further comprise a pH protective coating positioned between the oxygen barrier coating or layer and the lumen, the pH protective coating being effective to reduce dissolution of the oxygen barrier coating or layer by fluid within the lumen. The pH protective coating may comprise SiOxCy or SiNxCy wherein x is from about 0.5 to about 2.4 and y is from about 0.6 to about 3. The pH protective coating may be applied by plasma enhanced chemical vapor deposition (PECVD). The pH protective coating may be between 10 and 1000 nm thick. In some embodiments, the pH protective coating is at least coextensive with the oxygen barrier coating. In some embodiments, the pH protective coating may have an FTIR absorbance spectrum with a ratio greater than 0.75, and optionally greater than 0.9, between:
the maximum amplitude of the Si—O—Si symmetrical stretch peak between about 1000 and 1040 cm−1, and
the maximum amplitude of the Si—O—Si assymmetric stretch peak between about 1060 and about 1100 cm−1.

In addition to an oxygen barrier coating or layer, and optionally a pH protective layer, at least one of the container walls may also comprise a tie coating, the tie coating being positioned between the oxygen barrier coating and the wall interior surface or outer surface. In some embodiments, the tie coating may comprise SiOxCy or SiNxCy wherein x is from about 0.5 to about 2.4 and y is from about 0.6 to about 3. The tie coating may be applied by plasma enhanced chemical vapor deposition (PECVD) and may have an average thickness from 5 to 200 nm.

For example, in some embodiments, at least one of the container walls may comprise a trilayer coating such as those described for example in U.S. Pat. No. 9,554,968, the entirety of which is incorporated herein by reference. For instance, in some embodiments, the interior surface of the container walls may comprise:
an optional tie coating or layer comprising SiOxCy or SiNxCy, wherein x is from about 0.5 to about 2.4 and y is from about 0.6 to about 3, the tie coating or layer having an interior surface facing the lumen and an outer surface facing the wall interior surface;
a gas barrier coating or layer, optionally comprising SiOx, wherein x is from 1.5 to 2.9, the gas barrier coating or layer having an interior surface facing the lumen and an outer surface facing the interior surface of the tie coating or layer, the barrier coating or layer being effective to reduce the ingress of atmospheric gas into the lumen compared to a vessel without a barrier coating or layer; and
a pH protective coating or layer comprising SiOxCy or SiNxCy, wherein x is from about 0.5 to about 2.4 and y is from about 0.6 to about 3, the pH protective coating or layer having an interior surface facing the lumen and an outer surface facing the interior surface of the barrier coating or layer.

In some embodiments, at least one of the container walls may comprise a lubricity coating, such as those described in U.S. Pat. No. 7,985,188, the entirety of which is incorporated herein by reference. The lubricity coating or layer may consist essentially of SiOxCy, in which x is from about 0.5 to about 2.4 and y is from about 0.6 to about 3. The lubricity coating may be applied by plasma enhanced chemical vapor deposition (PECVD). The lubricity coating or layer may have a thickness between 10 and 1000 nm, optionally between 10 and 500 nm. In some embodiments, the lubricity coating or layer may have an FTIR absorbance spectrum with a ratio of at most 0.75 between:
the maximum amplitude of the Si—O—Si symmetrical stretch peak between about 1000 and 1040 cm−1, and
the maximum amplitude of the Si—O—Si assymmetric stretch peak between about 1060 and about 1100 cm−1.

In some embodiments, at least one of the container walls may comprise an anti-scratch and anti-static coating, such as those described in U.S. Pub. Pat. App. No. 2018/049945, the entirety of which is incorporated herein by reference.

In some embodiments, the present system and method may be adjustable and/or configurable based on the light transmission and refraction properties of the particular material or materials that make up the vessel walls.

Another aspect of the present invention is an RTU container, such as a vial, syringe, or cartridge, in which the container has been inspected for and found to be free of particles sized between 80 and 500 microns, optionally between 70 and 500 microns, optionally between 60 and 500 microns, optionally between 50 and 500 microns, optionally between 40 and 500 microns, optionally between 30 and 500 microns, optionally between 25 and 500 microns. The inspection may be performed using any of the systems and methods of the present disclosure.

Another aspect of the present invention is a batch or lot of RTU containers, such as vials, syringes, or cartridges, in which the containers have been inspected for particles sized between 80 and 500 microns, optionally between 70 and 500 microns, optionally between 60 and 500 microns, optionally between 50 and 500 microns, optionally between 40 and 500 microns, optionally between 30 and 500 microns, optionally between 25 and 500 microns, and in which the batch or lot has an AQL less than 0.5, optionally less than 0.4, optionally less than 0.3, optionally less than 0.2, optionally 0.1 or less. The inspection may be performed using any of the systems and methods of the present disclosure.

Another aspect of the present invention is an improved system and method for applying one or more coatings or layers, such as any one or more of those described above, to the inner surface of a vessel. The improved system and method described herein reduce the amount of particles, e.g. undesired flakes of coating, that may be present on one or more vessels after a coating cycle. In some embodiments, for instance, the system may be configured to reduce the contact area between the system and the vessel, thereby reducing the chances that a particle, e.g. a flake of coating, will end up present on a portion of the system that contacts the vessel and thereby become adhered to or embedded in the vessel. In some embodiments, the system may also be configured to provide for improved cleaning of the system components, particularly those which come into contact with the vessel.

Another aspect of the present invention is a system and method for removing particles from the equipment used to deposit one or more coatings on the inner wall of vessels, and in particular to remove particles from the components of the coating system that lead to potential contamination of the vessel with particles, e.g. the portions of the vessel holder that directly contact the vessel and/or the source gas inlet probe. In some embodiments, for instance, the coating system may comprise an electrode cavity cleaning unit, which is configured to create a vacuum within the electrode cavity that is suitable to remove particles, e.g. flakes of coating, from within the electrode cavity. The cleaning unit may be operated as a routine element of a coating process, e.g. the cleaning of electrode cavities may be performed after a defined number of coating cycles.

Another aspect of the present invention is a system and method for a machine-based visual inspection of the equipment used to deposit one or more coatings on the inner wall of vessels, and in particular on the components of the coating system that lead to potential contamination of the vessel with particles, e.g. the portions of the vessel holder that directly contact the vessel and/or the source gas inlet probe. In some embodiments, for instance, the coating system and method may comprise one or more cameras and optionally one or more lights positioned above the electrode.

The one or more cameras may be operably connected to one or more processors so that images taken by the one or more cameras are sent to the one or more processors. The one or more processors may be configured to receive the images and analyze the relevant portions of the image to detect the presence of particles, for instance using machine-based visual analysis similar to that described elsewhere herein (e.g. the defining of one or more inspection areas for each image and the visual analysis of each defined area for particles). The one or more processors may also be configured to determine the number of particles present in one or more electrode cavities, and more particularly on the vessel holder/sealing elements of the one or more electrode cavities, to determine the size of one or more detected particles, or both.

In some embodiments, the electrode cleaning operation may be initiated in response to a result of the visual inspection system/method. For instance, in some embodiments, the detection of particles above a certain threshold by the one or more processors may result in the one or more processors automatically activating the electrode cleaning process. In some embodiments, a visual inspection of the electrode may be performed immediately after the electrode cleaning process and if particles above a certain threshold (which may be any particles) are still detected, then the one or more processors may automatically initiate another cycle of the cleaning operation.

Another aspect of the present invention is a system and method for removing particles from vessels after the coating has been applied. In some embodiments, the system and method may comprise a cleaning station in which the inner surface of the vessel, i.e. the surface which defines the lumen and which has been provided with one or more coatings or layers using a PECVD coating process and system, is contacted with pressurized air, and desirably pressurized, ionized air, to remove particles, e.g. flakes of coating, that may be adhered thereto. In some embodiments, the system and method may comprise a cleaning station in which one or more outer surfaces of the vessel, e.g. the outer surfaces which come into direct contact with the coating system during the coating step, are contacted with pressurized air, and desirably pressurized, ionized air, to remove particles, e.g. flakes of coating, that may be adhered thereto. Either or both of these coating stations may also include a vacuum line and optionally a particle collection chamber, which serves to remove any particles that are dislodged from the vessel during the cleaning step without compromising a clean-room environment.

The removal of particles from the vessels may be performed with no washing, e.g. no contacting of the vessel surfaces with water.

Embodiments of the present invention may be fully automated. For instance, a series of vessels may be coated, cleaned, and inspected, e.g. in a clean-room environment, with the entire operation being continuous and controlled by one or more processors. The result is a system and method for the production of PECVD-coated pharmaceutical vessels, e.g. RTU containers, which are free or substantially free from particles, e.g. particles greater than 20 microns, alternatively particles greater than 25 microns, alternatively particles greater than 30 microns, alternatively particles greater than 40 microns, alternatively particles greater than 50 microns, and which system and method result in an extremely low number of vessels having to be scrapped due to the presence of particles or defects.

In some embodiments, the RTU container may, after coating, cleaning, and/or inspection, be filled with a pharmaceutical formulation of any of the following and sealed:

Biologic Drugs abatacept; abciximab; abobotulinumtoxinA; adalimumab; adalimumab-adaz; adalimumab-adbm; adalimumab-afzb; adalimumab-atto; adalimumab-bwwd; ado-trastuzumab emtansine; aflibercept; agalsidase beta; albiglutide; albumin chromated CR-51 serum; aldesleukin; alefacept; alemtuzumab; alglucosidase alfa; alirocumab; alteplase; anakinra; aprotinin; asfotas alfa; asparaginase; asparaginase Erwinia chrysanthemi; atezolizumab; avelumab; basiliximab; becaplermin; belatacept; belimumab; benralizumab; beractant; bevacizumab; bevacizumab-awwb; bevacizumab-bvzr; bezlotoxumab; blinatumomab; brentuximab vedotin; brodalumab; brolucizumab-dbll; burosumab-twza; calaspargase pegol-mknl; calfactant; canakinumab; caplacizumab-yhdp; capromab pendetide; cemiplimab-rwlc; cenegermin-bkbj; cerliponase alfa; certolizumab pegol; cetuximab; choriogonadotropin alfa; chorionic gonadotropin; chymopapain; collagenase; collagenase clostridium histolyticum; corticorelin ovine triflutate; crizanlizumab-tmca; daclizumab; daratumumab; daratumumab and hyaluronidase-fihj; darbepoetin alpha; denileukin diftitox; denosumab; desirudin; dinutuximab; dornase alfa; drotrecogin alfa; dulaglutide; dupilumab; durvalumab; ecallantide; eculizumab; efalizumab; elapegademase-Ivlr; elosulfase alfa; elotuzumab; emapalumab-Izsg; emicizumab-kxwh; enfortumab vedotin-ejfv; epoetin alfa; epoetin alfa-epbx; erenumab-aooe; etanercept; etanercept-szzs; etanercept-ykro; evolocumab; fam-trastuzumab deruxetecan-nxki; fibrinolysin and desoxyribonuclease combined [bovine], with chloramphenicol; filgrastim; filgrastim-aafi; filgrastim-sndz; follitropin alfa; follitropin beta; fremanezumab-vfrm; galcanezumab-gnlm; galsulfase; gemtuzumab ozogamicin; glucarpidase; golimumab; guselkumab; hyaluronidase; hyaluronidase human; ibalizumab-uiyk; ibritumomab tiuxetan; idarucizumab; idursulfase; imiglucerase; incobotulinumtoxinA; inebilizumab-cdon; infliximab; infliximab-abda; infliximab-axxq; infliximab-dyyb; infliximab-qbtx; inotuzumab ozogamicin; insulin aspart; insulin aspart protamine and insulin aspart; insulin degludec; insulin degludec and insulin aspart; insulin degludec and liraglutide; insulin detemir; insulin glargine; insulin glargine and lixisenatide; insulin glulisine; insulin human; insulin isophane human; insulin isophane human and insulin human; insulin lispro; insulin lispro protamine and insulin lispro; insulin lispro-aabc; interferon alfa-2a; interferon alfa-2b; interferon alfacon-1; interferon alfa-n3 (human leukocyte derived); interferon beta-1a; interferon beta-1b; interferon gamma-1b; ipilimumab; isatuximab-irfc; ixekizumab; lanadelumab-flyo; laronidase; lixisenatide; luspatercept-aamt; mecasermin; mecasermin rinfabate; menotropins; mepolizumab; methoxy polyethylene glycol-epoetin beta; metreleptin; mogamulizumab-kpkc; moxetumomab pasudotox-tdfk; muromanab-CD3; natalizumab; necitumumab; nivolumab; nofetumomab; obiltoxaximab; obinutuzumab; ocrelizumab; ocriplasmin; ofatumumab; olaratumab; omalizumab; onabotulinumtoxinA; oprelvekin; palifermin; palivizumab; pancrelipase; panitumumab; parathyroid hormone; pegademase bovine; pegaspargase; pegfilgrastim; pegfilgrastim-apgf; pegfilgrastim-bmez; pegfilgrastim-cbqv; pegfilgrastim-jmdb; peginterferon alfa-2a; peginterferon alfa-2a and ribavirin; peginterferon alfa-2b; peginterferon alfa-2b and ribavirin; peginterferon beta-1a; pegloticase; pegvaliase-pqpz; pegvisomant; pembrolizumab; pertuzumab; polatuzumab vedotin-piiq; poractant alfa; prabotulinumtoxinA-xvfs; radiolabeled albumin technetium Tc-99m albumin colloid kit; ramucirumab; ranibizumab; rasburicase; ravulizumab-cwvz; raxibacumab; reslizumab; reteplase; rilonacept; rimabotulinumtoxinB; risankizumab-rzaa; rituximab; rituximab and hyaluronidase human; rituximab-abbs; rituximab-pvvr; romiplostim; romosozumab-aqqg; sacituzumab govitecan-hziy; sacrosidase; sargramostim; sarilumab; sebelipase alfa; secukinumab; siltuximab; somatropin; tagraxofusp-erzs; taliglucerase alfa; tbo-filgrastim; technetium 99m tc fanolesomab; tenecteplase; teprotumumab-trbw; tesamorelin acetate; thyrotropin alfa; tildrakizumab-asmn; tocilizumab; tositumomab and iodine I-131 tositumomab; trastuzumab; trastuzumab and hyaluronidase-oysk; trastuzumab-anns; trastuzumab-dkst; trastuzumab-dttb; trastuzumab-pkrb; trastuzumab-qyyp; urofollitropin; urokinase; ustekinumab; vedolizumab; velaglucerase alfa; vestronidase alfa-vjbk; Ziv-Aflibercept; Amjevita (adalimumab-atto); Dupixent (dupilumab); Fulphila (pegfilgrastim-jmdb); llaris (canakinumab); Ixifi (infliximab-qbtx); Lyumjev (insulin lispro-aabc); Nyvepria (pegfilgrastim-apgf); Ogivri (trastuzumab-dkst); Semglee (insulin glargine); Uplizna (inebilizumab-cdon); A.P.L. (chorionic gonadotropin); Abrilada (adalimumab-afzb); Accretropin (somatropin); Actemra (tocilizumab); Acthrel (corticorelin ovine triflutate); Actimmune (interferon gamma-1b); Activase (alteplase); Adagen (pegademase bovine); Adakveo (crizanlizumab-tmca); Adcetris (brentuximab vedotin); Adlyxin (lixisenatide); Admelog (insulin lispro); Afrezza (insulin human); Aimovig (erenumab-aooe); Ajovy (fremanezumab-vfrm); Aldurazyme (laronidase); Alferon N Injection (interferon alfa-n3 (human leukocyte derived)); Amevive (alefacept); Amphadase (hyaluronidase); Anthim (obiltoxaximab); Apidra (insulin glulisine); Aranesp (darbepoetin alpha); Arcalyst (rilonacept); Arzerra (ofatumumab); Asparlas (calaspargase pegol-mknl); Avastin (bevacizumab); Avonex (interferon beta-1a); Avsola (infliximab-axxq); Basaglar (insulin glargine); Bavencio (avelumab); Benlysta (belimumab); Beovu (brolucizumab-dbll); Besponsa (inotuzumab ozogamicin); Betaseron (interferon beta-1b); Bexxar (tositumomab and iodine I-131 tositumomab); Blincyto (blinatumomab); Botox (onabotulinumtoxinA); Botox Cosmetic (onabotulinumtoxinA); Bravelle (urofollitropin); Brineura (cerliponase alfa); Cablivi (caplacizumab-yhdp); Campath (alemtuzumab); Cathflo Activase (alteplase); Cerezyme (imiglucerase); Chorionic Gonadotropin (chorionic gonadotropin); Chromalbin (albumin chromated CR-51 serum); Chymodiactin (chymopapain); Cimzia (certolizumab pegol); Cinqair (reslizumab); Cosentyx (secukinumab); Cotazym (pancrelipase); Creon (pancrelipase); Crysvita (burosumab-twza); Curosurf (poractant alfa); Cyltezo (adalimumab-adbm); Cyramza (ramucirumab); Darzalex (daratumumab); Darzalex Faspro (daratumumab and hyaluronidase-fihj); Draximage MAA (kit for the preparation of technetium Tc-99m albumin aggregated); Dysport (abobotulinumtoxinA); Egrifta (tesamorelin acetate); Egrifta SV (tesamorelin acetate); Elaprase (idursulfase); Elase-chloromycetin (fibrinolysin and desoxyribonuclease combined [bovine], with chloramphenicol); Elelyso (taliglucerase alfa); Elitek (rasburicase); Elspar (asparaginase); Elzonris (tagraxofusp-erzs); Emgality (galcanezumab-gnlm); Empliciti (elotuzumab); Enbrel (etanercept); Enbrel Mini (etanercept); Enhertu (fam-trastuzumab deruxetecan-nxki); Entyvio (vedolizumab); Epogen/Procrit (epoetin alfa); Erbitux (cetuximab); Erelzi (etanercept-szzs); Erelzi Sensoready (etanercept-szzs); Erwinaze (asparaginase Erwinia chrysanthemi); Eticovo (etanercept-ykro); Evenity (romosozumab-aqqg); Extavia (interferon beta-1b); Eylea (aflibercept); Fabrazyme (agalsidase beta); Fasenra (benralizumab); Fiasp (insulin aspart); Follistim (follitropin beta); Follistim AQ (follitropin beta); Follistim AQ Cartridge (follitropin beta); Gamifant (emapalumab-lzsg); Gazyva (obinutuzumab); Genotropin (somatropin); Gonal-f (follitropin alfa); Gonal-f RFF (follitropin alfa); Gonal-f RFF RediJect (follitropin alfa); Granix (tbo-filgrastim); Hadlima (adalimumab-bwwd); Hemlibra (emicizumab-kxwh); Herceptin (trastuzumab); Herceptin Hylecta (trastuzumab and hyaluronidase-oysk); Herzuma (trastuzumab-pkrb); Humalog (insulin lispro); Humalog Mix 50/50 (insulin lispro protamine and insulin lispro); Humalog Mix 75/25 (insulin lispro protamine and insulin lispro); Humatrope (somatropin); Humegon (menotropins); Humira (adalimumab); Humulin 70/30 (insulin isophane human and insulin human); Humulin N (insulin isophane human); Humulin R U-100 (insulin human); Humulin R U-500 (insulin human); Hydase (hyaluronidase); Hylenex recombinant (hyaluronidase human); Hyrimoz (adalimumab-adaz); Ilumya (tildrakizumab-asmn); Imfinzi (durvalumab); Increlex (mecasermin); Infasurf (calfactant); Infergen (interferon alfacon-1); Inflectra (infliximab-dyyb); Intron A (interferon alfa-2b); Iplex (mecasermin rinfabate); Iprivask (desirudin); Jeanatope (kit for iodinated 1-125 albumin); Jetrea (ocriplasmin); Jeuveau (prabotulinumtoxinA-xvfs); Kadcyla (ado-trastuzumab emtansine); Kalbitor (ecallantide); Kanjinti (trastuzumab-anns); Kanuma (sebelipase alfa); Kepivance (palifermin); Kevzara (sarilumab); Keytruda (pembrolizumab); Kineret (anakinra); Kinlytic (urokinase); Krystexxa (pegloticase); Lantus (insulin glargine); Lartruvo (olaratumab); Lemtrada (alemtuzumab); Leukine (sargramostim); Levemir (insulin detemir); Libtayo (cemiplimab-rwlc); Lucentis (ranibizumab); Lumizyme (alglucosidase alfa); Lumoxiti (moxetumomab pasudotox-tdfk); Macrotec (kit for the preparation of technetium Tc-99m albumin aggregated); Megatope (kit for iodinated I-131 albumin); Menopur (menotropins); Mepsevii (vestronidase alfa-vjbk); Microlite (radiolabeled albumin technetium Tc-99m albumin colloid kit); Mircera (methoxy polyethylene glycol-epoetin beta); Mvasi (bevacizumab-awwb); Myalept (metreleptin); Mylotarg (gemtuzumab ozogamicin); Myobloc (rimabotulinumtoxinB); Myozyme (alglucosidase alfa); Myxredlin (insulin human); N/A (raxibacumab); Naglazyme (galsulfase); Natpara (parathyroid hormone); Neulasta (pegfilgrastim); Neulasta Onpro (pegfilgrastim); Neumega (oprelvekin); Neupogen (filgrastim); NeutroSpec (technetium 99m tc fanolesomab); Nivestym (filgrastim-aafi); Norditropin (somatropin); Novarel (chorionic gonadotropin); Novolin 70/30 (insulin isophane human and insulin human); Novolin N (insulin isophane human); Novolin R (insulin human); Novolog (insulin aspart); Novolog Mix 50/50 (insulin aspart protamine and insulin aspart); Novolog Mix 70/30 (insulin aspart protamine and insulin aspart); Nplate (romiplostim); Nucala (mepolizumab); Nulojix (belatacept); Nutropin (somatropin); Nutropin AQ (somatropin); Ocrevus (ocrelizumab); Omnitrope (somatropin); Oncaspar (pegaspargase); Ontak (denileukin diftitox); Ontruzant (trastuzumab-dttb); Opdivo (nivolumab); Orencia (abatacept); Orthoclone OKT3 (muromanab-CD3); Ovidrel (choriogonadotropin alfa); Oxervate (cenegermin-bkbj); Padcev (enfortumab vedotin-ejfv); Palynziq (pegvaliase-pqpz); Pancreaze (pancrelipase); Pegasys (peginterferon alfa-2a); Pegasys Copegus Combination Pack (peginterferon alfa-2a and ribavirin); Pegintron (peginterferon alfa-2b); PegIntron/Rebetol Combo Pack (peginterferon alfa-2b and ribavirin); Pergonal (menotropins); Perjeta (pertuzumab); Pertzye (pancrelipase); Plegridy (peginterferon beta-1a); Polivy (polatuzumab vedotin-piiq); Portrazza (necitumumab); Poteligeo (mogamulizumab-kpkc); Praluent (alirocumab); Praxbind (idarucizumab); Pregnyl (chorionic gonadotropin); Procrit (epoetin alfa); Proleukin (aldesleukin); Prolia (denosumab); ProstaScint (capromab pendetide); Pulmolite (kit for the preparation of technetium Tc-99m albumin aggregated); Pulmotech MAA (kit for the preparation of technetium Tc-99m albumin aggregated); Pulmozyme (dornase alfa); Raptiva (efalizumab); Rebif (interferon beta-1a); Reblozyl (luspatercept-aamt); Regranex (becaplermin); Remicade (infliximab); Renflexis (infliximab-abda); Reopro (abciximab); Repatha (evolocumab); Repronex (menotropins); Retacrit (epoetin alfa-epbx); Retavase (reteplase); Revcovi (elapegademase-lvlr); Rituxan (rituximab); Rituxan Hycela (rituximab and hyaluronidase human); Roferon-A (interferon alfa-2a); Ruxience (rituximab-pvvr); Ryzodeg 70/30 (insulin degludec and insulin aspart); Saizen (somatropin); Santyl (collagenase); Sarclisa (isatuximab-irfc); Serostim (somatropin); Siliq (brodalumab); Simponi (golimumab); Simponi Aria (golimumab); Simulect (basiliximab); Skyrizi (risankizumab-rzaa); Soliqua 100/33 (insulin glargine and lixisenatide); Soliris (eculizumab); Somavert (pegvisomant); Stelara (ustekinumab); Strensiq (asfotas alfa); Sucraid (sacrosidase); Survanta (beractant); Sylvant (siltuximab); Synagis (palivizumab); Takhzyro (lanadelumab-flyo); Taltz (ixekizumab); Tanzeum (albiglutide); Tecentriq (atezolizumab); Tepezza (teprotumumab-trbw); Thyrogen (thyrotropin alfa); TNKase (tenecteplase); Toujeo (insulin glargine); Trasylol (aprotinin); Trazimera (trastuzumab-qyyp); Tremfya (guselkumab); Tresiba (insulin degludec); Trodelvy (sacituzumab govitecan-hziy); Trogarzo (ibalizumab-uiyk); Trulicity (dulaglutide); Truxima (rituximab-abbs); Tysabri (natalizumab); Udenyca (pegfilgrastim-cbqv); Ultomiris (ravulizumab-cwvz); Unituxin (dinutuximab); Vectibix (panitumumab); Verluma (nofetumomab); Vimizim (elosulfase alfa); Viokace (pancrelipase); Vitrase (hyaluronidase); Voraxaze (glucarpidase); VPRIV (velaglucerase alfa); Xeomin (incobotulinumtoxinA); Xgeva (denosumab); Xiaflex (collagenase clostridium histolyticum); Xigris (drotrecogin alfa); Xolair (omalizumab); Xultophy 100/3.6 (insulin degludec and liraglutide); Yervoy (ipilimumab); Zaltrap (Ziv-Aflibercept); Zarxio (filgrastim-sndz); Zenapax (daclizumab); Zenpep (pancrelipase); Zevalin (ibritumomab tiuxetan); Ziextenzo (pegfilgrastim-bmez); Zinbryta (daclizumab); Zinplava (bezlotoxumab); Zirabev (bevacizumab-bvzr); Zomacton (somatropin); Zorbtive/Serostim (somatropin);

### Inhalation Anesthetics

Aliflurane; Chloroform; Cyclopropane; Desflurane (Suprane); Diethyl Ether; Enflurane (Ethrane); Ethyl Chloride; Ethylene; Halothane (Fluothane); Isoflurane (Forane, Isoflo); Isopropenyl vinyl ether; Methoxyflurane; methoxyflurane; Methoxypropane; Nitrous Oxide; Roflurane; Sevoflurane (Sevorane, Ultane, Sevoflo); Teflurane; Trichloroethylene; Vinyl Ether; Xenon;

### Injectable Drugs

Ablavar (Gadofosveset Trisodium Injection); Abarelix Depot; Abobotulinumtoxin A Injection (Dysport); ABT-263; ABT-869; ABX-EFG; Accretropin (Somatropin Injection); Acetadote (Acetylcysteine Injection); Acetazolamide Injection (Acetazolamide Injection); Acetylcysteine Injection (Acetadote); Actemra (Tocilizumab Injection); Acthrel (Corticorelin Ovine Triflutate for Injection); Actummune; Activase; Acyclovir for Injection (Zovirax Injection); Adacel; Adalimumab; Adenoscan (Adenosine Injection); Adenosine Injection (Adenoscan); Adrenaclick; AdreView (lobenguane I 123 Injection for Intravenous Use); Afluria; Ak-Fluor (Fluorescein Injection); Aldurazyme (Laronidase); Alglucerase Injection (Ceredase); Alkeran Injection (Melphalan Hcl Injection); Allopurinol Sodium for Injection (Aloprim); Aloprim (Allopurinol Sodium for Injection); Alprostadil; Alsuma (Sumatriptan Injection); ALTU-238; Amino Acid Injections; Aminosyn; Apidra; Apremilast; Alprostadil Dual Chamber System for Injection (Caverject Impulse); AMG 009; AMG 076; AMG 102; AMG 108; AMG 114; AMG 162; AMG 220; AMG 221; AMG 222; AMG 223; AMG 317; AMG 379; AMG 386; AMG 403; AMG 477; AMG 479; AMG 517; AMG 531; AMG 557; AMG 623; AMG 655; AMG 706; AMG 714; AMG 745; AMG 785; AMG 811; AMG 827; AMG 837; AMG 853; AMG 951; Amiodarone HCl Injection (Amiodarone HCl Injection); Amobarbital Sodium Injection (Amytal Sodium); Amytal Sodium (Amobarbital Sodium Injection); Anakinra; Anti-Abeta; Anti-Beta7; Anti-Beta20; Anti-CD4; Anti-CD20; Anti-CD40; Anti-IFNalpha; Anti-IL13; Anti-OX40L; Anti-oxLDS; Anti-NGF; Anti-NRP1; Arixtra; Amphadase (Hyaluronidase Inj); Ammonul (Sodium Phenylacetate and Sodium Benzoate Injection); Anaprox; Anzemet Injection (Dolasetron Mesylate Injection); Apidra (Insulin Glulisine [rDNA origin]Inj); Apomab; Aranesp (darbepoetin alfa); Argatroban (Argatroban Injection); Arginine Hydrochloride Injection (R-Gene 10); Aristocort; Aristospan; Arsenic Trioxide Injection (Trisenox); Articane HCl and Epinephrine Injection (Septocaine); Arzerra (Ofatumumab Injection); Asclera (Polidocanol Injection); Ataluren; Ataluren-DMD; Atenolol Inj (Tenormin I.V. Injection); Atracurium Besylate Injection (Atracurium Besylate Injection); Avastin; Azactam Injection (Aztreonam Injection); Azithromycin (Zithromax Injection); Aztreonam Injection (Azactam Injection); Baclofen Injection (Lioresal Intrathecal); Bacteriostatic Water (Bacteriostatic Water for Injection); Baclofen Injection (Lioresal Intrathecal); Bal in Oil Ampules (Dimercarprol Injection); BayHepB; BayTet; Benadryl; Bendamustine Hydrochloride Injection (Treanda); Benztropine Mesylate Injection (Cogentin); Betamethasone Injectable Suspension (Celestone Soluspan); Bexxar; Bicillin C-R 900/300 (Penicillin G Benzathine and Penicillin G Procaine Injection); Blenoxane (Bleomycin Sulfate Injection); Bleomycin Sulfate Injection (Blenoxane); Boniva Injection (Ibandronate Sodium Injection); Botox Cosmetic (OnabotulinumtoxinA for Injection); BR3-FC; Bravelle (Urofollitropin Injection); Bretylium (Bretylium Tosylate Injection); Brevital Sodium (Methohexital Sodium for Injection); Brethine; Briobacept; BTT-1023; Bupivacaine HCl; Byetta; Ca-DTPA (Pentetate Calcium Trisodium Inj); Cabazitaxel Injection (Jevtana); Caffeine Alkaloid (Caffeine and Sodium Benzoate Injection); Calcijex Injection (Calcitrol); Calcitrol (Calcijex Injection); Calcium Chloride (Calcium Chloride Injection 10%); Calcium Disodium Versenate (Edetate Calcium Disodium Injection); Campath (Altemtuzumab); Camptosar Injection (Irinotecan Hydrochloride); Canakinumab Injection (llaris); Capastat Sulfate (Capreomycin for Injection); Capreomycin for Injection (Capastat Sulfate); Cardiolite (Prep kit for Technetium Tc99 Sestamibi for Injection); Carticel; Cathflo; Cefazolin and Dextrose for Injection (Cefazolin Injection); Cefepime Hydrochloride; Cefotaxime; Ceftriaxone; Cerezyme; Carnitor Injection; Caverject; Celestone Soluspan; Celsior; Cerebyx (Fosphenytoin Sodium Injection); Ceredase (Alglucerase Injection); Ceretec (Technetium Tc99m Exametazime Injection); Certolizumab; CF-101; Chloramphenicol Sodium Succinate (Chloramphenicol Sodium Succinate Injection); Chloramphenicol Sodium Succinate Injection (Chloramphenicol Sodium Succinate); Cholestagel (Colesevelam HCL); Choriogonadotropin Alfa Injection (Ovidrel); Cimzia; Cisplatin (Cisplatin Injection); Clolar (Clofarabine Injection); Clomiphine Citrate; Clonidine Injection (Duraclon); Cogentin (Benztropine Mesylate Injection); Colistimethate Injection (Coly-Mycin M); Coly-Mycin M (Colistimethate Injection); Compath; Conivaptan Hcl Injection (Vaprisol); Conjugated Estrogens for Injection (Premarin Injection); Copaxone; Corticorelin Ovine Triflutate for Injection (Acthrel); Corvert (Ibutilide Fumarate Injection); Cubicin (Daptomycin Injection); CF-101; Cyanokit (Hydroxocobalamin for Injection); Cytarabine Liposome Injection (DepoCyt); Cyanocobalamin; Cytovene (ganciclovir); D.H.E. 45; Dacetuzumab; Dacogen (Decitabine Injection); Dalteparin; Dantrium IV (Dantrolene Sodium for Injection); Dantrolene Sodium for Injection (Dantrium IV); Daptomycin Injection (Cubicin); Darbepoietin Alfa; DDAVP Injection (Desmopressin Acetate Injection); Decavax; Decitabine Injection (Dacogen); Dehydrated Alcohol (Dehydrated Alcohol Injection); Denosumab Injection (Prolia); Delatestryl; Delestrogen; Delteparin Sodium; Depacon (Valproate Sodium Injection); Depo Medrol (Methylprednisolone Acetate Injectable Suspension); DepoCyt (Cytarabine Liposome Injection); DepoDur (Morphine Sulfate XR Liposome Injection); Desmopressin Acetate Injection (DDAVP Injection); Depo-Estradiol; Depo-Provera 104 mg/ml; Depo-Provera 150 mg/ml; Depo-Testosterone; Dexrazoxane for Injection, Intravenous Infusion Only (Totect); Dextrose/Electrolytes; Dextrose and Sodium Chloride Inj (Dextrose 5% in 0.9% Sodium Chloride); Dextrose; Diazepam Injection (Diazepam Injection); Digoxin Injection (Lanoxin Injection); Dilaudid-HP (Hydromorphone Hydrochloride Injection); Dimercarprol Injection (Bal in Oil Ampules); Diphenhydramine Injection (Benadryl Injection); Dipyridamole Injection (Dipyridamole Injection); DMOAD; Docetaxel for Injection (Taxotere); Dolasetron Mesylate Injection (Anzemet Injection); Doribax (Doripenem for Injection); Doripenem for Injection (Doribax); Doxercalciferol Injection (Hectorol Injection); Doxil (Doxorubicin Hcl Liposome Injection); Doxorubicin Hcl Liposome Injection (Doxil); Duraclon (Clonidine Injection); Duramorph (Morphine Injection); Dysport (Abobotulinumtoxin A Injection); Ecallantide Injection (Kalbitor); EC-Naprosyn (naproxen); Edetate Calcium Disodium Injection (Calcium Disodium Versenate); Edex (Alprostadil for Injection); Engerix; Edrophonium Injection (Enlon); Eliglustat Tartate; Eloxatin (Oxaliplatin Injection); Emend Injection (Fosaprepitant Dimeglumine Injection); Enalaprilat Injection (Enalaprilat Injection); Enlon (Edrophonium Injection); Enoxaparin Sodium Injection (Lovenox); Eovist (Gadoxetate Disodium Injection); Enbrel (etanercept); Enoxaparin, Epicel; Epinephrine; Epipen; Epipen Jr.; Epratuzumab; Erbitux; Ertapenem Injection (Invanz); Erythropoieten; Essential Amino Acid Injection (Nephramine); Estradiol Cypionate; Estradiol Valerate; Etanercept; Exenatide Injection (Byetta); Evlotra; Fabrazyme (Adalsidase beta); Famotidine Injection; FDG (Fludeoxyglucose F 18 Injection); Feraheme (Ferumoxytol Injection); Feridex I.V. (Ferumoxides Injectable Solution); Fertinex; Ferumoxides Injectable Solution (Feridex I.V.); Ferumoxytol Injection (Feraheme); Flagyl Injection (Metronidazole Injection); Fluarix; Fludara (Fludarabine Phosphate); Fludeoxyglucose F 18 Injection (FDG); Fluorescein Injection (Ak-Fluor); Follistim AQ Cartridge (Follitropin Beta Injection); Follitropin Alfa Injection (Gonal-f RFF); Follitropin Beta Injection (Follistim AQ Cartridge); Folotyn (Pralatrexate Solution for Intravenous Injection); Fondaparinux; Forteo (Teriparatide (rDNA origin) Injection); Fostamatinib; Fosaprepitant Dimeglumine Injection (Emend Injection); Foscarnet Sodium Injection (Foscavir); Foscavir (Foscarnet Sodium Injection); Fosphenytoin Sodium Injection (Cerebyx); Fospropofol Disodium Injection (Lusedra); Fragmin; Fuzeon (enfuvirtide); GA101; Gadobenate Dimeglumine Injection (Multihance); Gadofosveset Trisodium Injection (Ablavar); Gadoteridol Injection Solution (ProHance); Gadoversetamide Injection (OptiMARK); Gadoxetate Disodium Injection (Eovist); Ganirelix (Ganirelix Acetate Injection); Gardasil; GC1008; GDFD; Gemtuzumab Ozogamicin for Injection (Mylotarg); Genotropin; Gentamicin Injection; GENZ-112638; Golimumab Injection (Simponi Injection); Gonal-f RFF (Follitropin Alfa Injection); Granisetron Hydrochloride (Kytril Injection); Gentamicin Sulfate; Glatiramer Acetate; Glucagen; Glucagon; HAE1; Haldol (Haloperidol Injection); Havrix; Hectorol Injection (Doxercalciferol Injection); Hedgehog Pathway Inhibitor; Heparin; Herceptin; hG-CSF; Humalog; Human Growth Hormone; Humatrope; HuMax; Humegon; Humira; Humulin; Ibandronate Sodium Injection (Boniva Injection); Ibuprofen Lysine Injection (NeoProfen); Ibutilide Fumarate Injection (Corvert); Idamycin PFS (Idarubicin Hydrochloride Injection); Idarubicin Hydrochloride Injection (Idamycin PFS); llaris (Canakinumab Injection); Imipenem and Cilastatin for Injection (Primaxin I.V.); Imitrex; Incobotulinumtoxin A for Injection (Xeomin); Increlex (Mecasermin [rDNA origin]Injection); Indocin IV (Indomethacin Inj); Indomethacin Inj (Indocin IV); Infanrix; Innohep; Insulin; Insulin Aspart [rDNA origin]Inj (NovoLog); Insulin Glargine [rDNA origin]Injection (Lantus); Insulin Glulisine [rDNA origin] Inj (Apidra); Interferon alfa-2b, Recombinant for Injection (Intron A); Intron A (Interferon alfa-2b, Recombinant for Injection); Invanz (Ertapenem Injection); Invega Sustenna (Paliperidone Palmitate Extended-Release Injectable Suspension); Invirase (saquinavir mesylate); lobenguane I 123 Injection for Intravenous Use (AdreView); lopromide Injection (Ultravist); loversol Injection (Optiray Injection); Iplex (Mecasermin Rinfabate [rDNA origin] Injection); Iprivask; Irinotecan Hydrochloride (Camptosar Injection); Iron Sucrose Injection (Venofer); Istodax (Romidepsin for Injection); Itraconazole Injection (Sporanox Injection); Jevtana (Cabazitaxel Injection); Jonexa; Kalbitor (Ecallantide Injection); KCL in D5NS (Potassium Chloride in 5% Dextrose and Sodium Chloride Injection); KCL in D5W; KCL in NS; Kenalog 10 Injection (Triamcinolone Acetonide Injectable Suspension); Kepivance (Palifermin); Keppra Injection (Levetiracetam); Keratinocyte; KFG; Kinase Inhibitor; Kineret (Anakinra); Kinlytic (Urokinase Injection); Kinrix; Klonopin (clonazepam); Kytril Injection (Granisetron Hydrochloride); lacosamide Tablet and Injection (Vimpat); Lactated Ringer's; Lanoxin Injection (Digoxin Injection); Lansoprazole for Injection (Prevacid I.V.); Lantus; Leucovorin Calcium (Leucovorin Calcium Injection); Lente (L); Leptin; Levemir; Leukine Sargramostim; Leuprolide Acetate; Levothyroxine; Levetiracetam (Keppra Injection); Lovenox; Levocarnitine Injection (Carnitor Injection); Lexiscan (Regadenoson Injection); Lioresal Intrathecal (Baclofen Injection); Liraglutide [rDNA] Injection (Victoza); Lovenox (Enoxaparin Sodium Injection); Lucentis (Ranibizumab Injection); Lumizyme; Lupron (Leuprolide Acetate Injection); Lusedra (Fospropofol Disodium Injection); Maci; Magnesium Sulfate (Magnesium Sulfate Injection); Mannitol Injection (Mannitol IV); Marcaine (Bupivacaine Hydrochloride and Epinephrine Injection); Maxipime (Cefepime Hydrochloride for Injection); MDP Multidose Kit of Technetium Injection (Technetium Tc99m Medronate Injection); Mecasermin [rDNA origin] Injection (Increlex); Mecasermin Rinfabate [rDNA origin] Injection (Iplex); Melphalan Hcl Injection (Alkeran Injection); Methotrexate; Menactra; Menopur (Menotropins Injection); Menotropins for Injection (Repronex); Methohexital Sodium for Injection (Brevital Sodium); Methyldopate Hydrochloride Injection, Solution (Methyldopate Hcl); Methylene Blue (Methylene Blue Injection); Methylprednisolone Acetate Injectable Suspension (Depo Medrol); MetMab; Metoclopramide Injection (Reglan Injection); Metrodin (Urofollitropin for Injection); Metronidazole Injection (Flagyl Injection); Miacalcin; Midazolam (Midazolam Injection); Mimpara (Cinacalet); Minocin Injection (Minocycline Inj); Minocycline Inj (Minocin Injection); Mipomersen; Mitoxantrone for Injection Concentrate (Novantrone); Morphine Injection (Duramorph); Morphine Sulfate XR Liposome Injection (DepoDur); Morrhuate Sodium (Morrhuate Sodium Injection); Motesanib; Mozobil (Plerixafor Injection); Multihance (Gadobenate Dimeglumine Injection); Multiple Electrolytes and Dextrose Injection; Multiple Electrolytes Injection; Mylotarg (Gemtuzumab Ozogamicin for Injection); Myozyme (Alglucosidase alfa); Nafcillin Injection (Nafcillin Sodium); Nafcillin Sodium (Nafcillin Injection); Naltrexone XR Inj (Vivitrol); Naprosyn (naproxen); NeoProfen (Ibuprofen Lysine Injection); Nandrol Decanoate; Neostigmine Methylsulfate (Neostigmine Methylsulfate Injection); NEO-GAA; NeoTect (Technetium Tc 99m Depreotide Injection); Nephramine (Essential Amino Acid Injection); Neulasta (pegfilgrastim); Neupogen (Filgrastim); Novolin; Novolog; NeoRecormon; Neutrexin (Trimetrexate Glucuronate Inj); NPH (N); Nexterone (Amiodarone HCl Injection); Norditropin (Somatropin Injection); Normal Saline (Sodium Chloride Injection); Novantrone (Mitoxantrone for Injection Concentrate); Novolin 70/30 Innolet (70% NPH, Human Insulin Isophane Suspension and 30% Regular, Human Insulin Injection); NovoLog (Insulin Aspart [rDNA origin] Inj); Nplate (romiplostim); Nutropin (Somatropin (rDNA origin) for Inj); Nutropin AQ; Nutropin Depot (Somatropin (rDNA origin) for Inj); Octreotide Acetate Injection (Sandostatin LAR); Ocrelizumab; Ofatumumab Injection (Arzerra); Olanzapine Extended Release Injectable Suspension (Zyprexa Relprevv); Omnitarg; Omnitrope (Somatropin [rDNA origin] Injection); Ondansetron Hydrochloride Injection (Zofran Injection); OptiMARK (Gadoversetamide Injection); Optiray Injection (loversol Injection); Orencia; Osmitrol Injection in Aviva (Mannitol Injection in Aviva Plastic Vessel); Osmitrol Injection in Viaflex (Mannitol Injection in Viaflex Plastic Vessel); Osteoprotegrin; Ovidrel (Choriogonadotropin Alfa Injection); Oxacillin (Oxacillin for Injection); Oxaliplatin Injection (Eloxatin); Oxytocin Injection (Pitocin); Paliperidone Palmitate Extended-Release Injectable Suspension (Invega Sustenna); Pamidronate Disodium Injection (Pamidronate Disodium Injection); Panitumumab Injection for Intravenous Use (Vectibix); Papaverine Hydrochloride Injection (Papaverine Injection); Papaverine Injection (Papaverine Hydrochloride Injection); Parathyroid Hormone; Paricalcitol Injection Fliptop Vial (Zemplar Injection); PARP Inhibitor; Pediarix; PEGIntron; Peginterferon; Pegfilgrastim; Penicillin G Benzathine and Penicillin G Procaine; Pentetate Calcium Trisodium Inj (Ca-DTPA); Pentetate Zinc Trisodium Injection (Zn-DTPA); Pepcid Injection (Famotidine Injection); Pergonal; Pertuzumab; Phentolamine Mesylate (Phentolamine Mesylate for Injection); Physostigmine Salicylate (Physostigmine Salicylate (injection)); Physostigmine Salicylate (injection) (Physostigmine Salicylate); Piperacillin and Tazobactam Injection (Zosyn); Pitocin (Oxytocin Injection); Plasma-Lyte 148 (Multiple Electrolytes Inj); Plasma-Lyte 56 and Dextrose (Multiple Electrolytes and Dextrose Injection in Viaflex Plastic Vessel); PlasmaLyte; Plerixafor Injection (Mozobil); Polidocanol Injection (Asclera); Potassium Chloride; Pralatrexate Solution for Intravenous Injection (Folotyn); Pramlintide Acetate Injection (Symlin); Premarin Injection (Conjugated Estrogens for Injection); Prep kit for Technetium Tc99 Sestamibi for Injection (Cardiolite); Prevacid I.V. (Lansoprazole for Injection); Primaxin I.V. (Imipenem and Cilastatin for Injection); Prochymal; Procrit; Progesterone; ProHance (Gadoteridol Injection Solution); Prolia (Denosumab Injection); Promethazine HCl Injection (Promethazine Hydrochloride Injection); Propranolol Hydrochloride Injection (Propranolol Hydrochloride Injection); Quinidine Gluconate Injection (Quinidine Injection); Quinidine Injection (Quinidine Gluconate Injection); R-Gene 10 (Arginine Hydrochloride Injection); Ranibizumab Injection (Lucentis); Ranitidine Hydrochloride Injection (Zantac Injection); Raptiva; Reclast (Zoledronic Acid Injection); Recombivarix HB; Regadenoson Injection (Lexiscan); Reglan Injection (Metoclopramide Injection); Remicade; Renagel; Renvela (Sevelamer Carbonate); Repronex (Menotropins for Injection); Retrovir IV (Zidovudine Injection); rhApo2L/TRAIL; Ringer's and 5% Dextrose Injection (Ringers in Dextrose); Ringer's Injection (Ringers Injection); Rituxan; Rituximab; Rocephin (ceftriaxone); Rocuronium Bromide Injection (Zemuron); Roferon-A (interferon alfa-2a); Romazicon (flumazenil); Romidepsin for Injection (Istodax); Saizen (Somatropin Injection); Sandostatin LAR (Octreotide Acetate Injection); Sclerostin Ab; Sensipar (cinacalcet); Sensorcaine (Bupivacaine HCl Injections); Septocaine (Articane HCl and Epinephrine Injection); Serostim LQ (Somatropin (rDNA origin) Injection); Simponi Injection (Golimumab Injection); Sodium Acetate (Sodium Acetate Injection); Sodium Bicarbonate (Sodium Bicarbonate 5% Injection); Sodium Lactate (Sodium Lactate Injection in AVIVA); Sodium Phenylacetate and Sodium Benzoate Injection (Ammonul); Somatropin (rDNA origin) for Inj (Nutropin); Sporanox Injection (Itraconazole Injection); Stelara Injection (Ustekinumab); Stemgen; Sufenta (Sufentanil Citrate Injection); Sufentanil Citrate Injection (Sufenta); Sumavel; Sumatriptan Injection (Alsuma); Symlin; Symlin Pen; Systemic Hedgehog Antagonist; Synvisc-One (Hylan G-F 20 Single Intra-articular Injection); Tarceva; Taxotere (Docetaxel for Injection); Technetium Tc 99m; Telavancin for Injection (Vibativ); Temsirolimus Injection (Torisel); Tenormin I.V. Injection (Atenolol Inj); Teriparatide (rDNA origin) Injection (Forteo); Testosterone Cypionate; Testosterone Enanthate; Testosterone Propionate; Tev-Tropin (Somatropin, rDNA Origin, for Injection); tgAAC94; Thallous Chloride; Theophylline; Thiotepa (Thiotepa Injection); Thymoglobulin (Anti-Thymocyte Globulin (Rabbit); Thyrogen (Thyrotropin Alfa for Injection); Ticarcillin Disodium and Clavulanate Potassium Galaxy (Timentin Injection); Tigan Injection (Trimethobenzamide Hydrochloride Injectable); Timentin Injection (Ticarcillin Disodium and Clavulanate Potassium Galaxy); TNKase; Tobramycin Injection (Tobramycin Injection); Tocilizumab Injection (Actemra); Torisel (Temsirolimus Injection); Totect (Dexrazoxane for Injection, Intravenous Infusion Only); Trastuzumab-DM1; Travasol (Amino Acids (Injection)); Treanda (Bendamustine Hydrochloride Injection); Trelstar (Triptorelin Pamoate for Injectable Suspension); Triamcinolone Acetonide; Triamcinolone Diacetate; Triamcinolone Hexacetonide Injectable Suspension (Aristospan Injection 20 mg); Triesence (Triamcinolone Acetonide Injectable Suspension); Trimethobenzamide Hydrochloride Injectable (Tigan Injection); Trimetrexate Glucuronate Inj (Neutrexin); Triptorelin Pamoate for Injectable Suspension (Trelstar); Twinject; Trivaris (Triamcinolone Acetonide Injectable Suspension); Trisenox (Arsenic Trioxide Injection); Twinrix; Typhoid Vi; Ultravist (lopromide Injection); Urofollitropin for Injection (Metrodin); Urokinase Injection (Kinlytic); Ustekinumab (Stelara Injection); Ultralente (U); Valium (diazepam); Valproate Sodium Injection (Depacon); Valtropin (Somatropin Injection); Vancomycin Hydrochloride (Vancomycin Hydrochloride Injection); Vancomycin Hydrochloride Injection (Vancomycin Hydrochloride); Vaprisol (Conivaptan Hcl Injection); VAQTA; Vasovist (Gadofosveset Trisodium Injection for Intravenous Use); Vectibix (Panitumumab Injection for Intravenous Use); Venofer (Iron Sucrose Injection); Verteporfin Inj (Visudyne); Vibativ (Telavancin for Injection); Victoza (Liraglutide [rDNA] Injection); Vimpat (lacosamide Tablet and Injection); Vinblastine Sulfate (Vinblastine Sulfate Injection); Vincasar PFS (Vincristine Sulfate Injection); Victoza; Vincristine Sulfate (Vincristine Sulfate Injection); Visudyne (Verteporfin Inj); Vitamin B-12; Vivitrol (Naltrexone XR Inj); Voluven (Hydroxyethyl Starch in Sodium Chloride Injection); Xeloda; Xenical (orlistat); Xeomin (Incobotulinumtoxin A for Injection); Xolair; Zantac Injection (Ranitidine Hydrochloride Injection); Zemplar Injection (Paricalcitol Injection Fliptop Vial); Zemuron (Rocuronium Bromide Injection); Zenapax (daclizumab); Zevalin; Zidovudine Injection (Retrovir IV); Zithromax Injection (Azithromycin); Zn-DTPA (Pentetate Zinc Trisodium Injection); Zofran Injection (Ondansetron Hydrochloride Injection); Zingo; Zoledronic Acid for Inj (Zometa); Zoledronic Acid Injection (Reclast); Zometa (Zoledronic Acid for Inj); Zosyn (Piperacillin and Tazobactam Injection); Zyprexa Relprevv (Olanzapine Extended Release Injectable Suspension);

### Liquid Drugs (Non-Injectable)

Abilify; AccuNeb (Albuterol Sulfate Inhalation Solution); Actidose Aqua (Activated Charcoal Suspension); Activated Charcoal Suspension (Actidose Aqua); Advair; Agenerase Oral Solution (Amprenavir Oral Solution); Akten (Lidocaine Hydrochloride Ophthalmic Gel); Alamast (Pemirolast Potassium Ophthalmic Solution); Albumin (Human) 5% Solution (Buminate 5%); Albuterol Sulfate Inhalation Solution; Alinia; Alocril; Alphagan; Alrex; Alvesco; Amprenavir Oral Solution; Analpram-HC; Arformoterol Tartrate Inhalation Solution (Brovana); Aristospan Injection 20 mg (Triamcinolone Hexacetonide Injectable Suspension); Asacol; Asmanex; Astepro; Astepro (Azelastine Hydrochloride Nasal Spray); Atrovent Nasal Spray (Ipratropium Bromide Nasal Spray); Atrovent Nasal Spray.06; Augmentin ES-600; Azasite (Azithromycin Ophthalmic Solution); Azelaic Acid (Finacea Gel); Azelastine Hydrochloride Nasal Spray (Astepro); Azelex (Azelaic Acid Cream); Azopt (Brinzolamide Ophthalmic Suspension); Bacteriostatic Saline; Balanced Salt; Bepotastine; Bactroban Nasal; Bactroban; Beclovent; Benzac W; Betimol; Betoptic S; Bepreve; Bimatoprost Ophthalmic Solution; Bleph 10 (Sulfacetamide Sodium Ophthalmic Solution 10%); Brinzolamide Ophthalmic Suspension (Azopt); Bromfenac Ophthalmic Solution (Xibrom); Bromhist; Brovana (Arformoterol Tartrate Inhalation Solution); Budesonide Inhalation Suspension (Pulmicort Respules); Cambia (Diclofenac Potassium for Oral Solution); Capex; Carac; Carboxine-PSE; Carnitor; Cayston (Aztreonam for Inhalation Solution); Cellcept; Centany; Cerumenex; Ciloxan Ophthalmic Solution (Ciprofloxacin HCL Ophthalmic Solution); Ciprodex; Ciprofloxacin HCL Ophthalmic Solution (Ciloxan Ophthalmic Solution); Clemastine Fumarate Syrup (Clemastine Fumarate Syrup); CoLyte (PEG Electrolytes Solution); Combiven; Comtan; Condylox; Cordran; Cortisporin Ophthalmic Suspension; Cortisporin Otic Suspension; Cromolyn Sodium Inhalation Solution (Intal Nebulizer Solution); Cromolyn Sodium Ophthalmic Solution (Opticrom); Crystalline Amino Acid Solution with Electrolytes (Aminosyn Electrolytes); Cutivate; Cuvposa (Glycopyrrolate Oral Solution); Cyanocobalamin (CaloMist Nasal Spray); Cyclosporine Oral Solution (Gengraf Oral Solution); Cyclogyl; Cysview (Hexaminolevulinate Hydrochloride Intravesical Solution); DermOtic Oil (Fluocinolone Acetonide Oil Ear Drops); Desmopressin Acetate Nasal Spray; DDAVP; Derma-Smoothe/FS; Dexamethasone Intensol; Dianeal Low Calcium; Dianeal PD; Diclofenac Potassium for Oral Solution (Cambia); Didanosine Pediatric Powder for Oral Solution (Videx); Differin; Dilantin 125 (Phenytoin Oral Suspension); Ditropan; Dorzolamide Hydrochloride Ophthalmic Solution (Trusopt); Dorzolamide Hydrochloride-Timolol Maleate Ophthalmic Solution (Cosopt); Dovonex Scalp (Calcipotriene Solution); Doxycycline Calcium Oral Suspension (Vibramycin Oral); Efudex; Elaprase (Idursulfase Solution); Elestat (Epinastine HCl Ophthalmic Solution); Elocon; Epinastine HCl Ophthalmic Solution (Elestat); Epivir HBV; Epogen (Epoetin alfa); Erythromycin Topical Solution 1.5% (Staticin); Ethiodol (Ethiodized Oil); Ethosuximide Oral Solution (Zarontin Oral Solution); Eurax; Extraneal (Icodextrin Peritoneal Dialysis Solution); Felbatol; Feridex I.V. (Ferumoxides Injectable Solution); Flovent; Floxin Otic (Ofloxacin Otic Solution); Flo-Pred (Prednisolone Acetate Oral Suspension); Fluoroplex; Flunisolide Nasal Solution (Flunisolide Nasal Spray.025%); Fluorometholone Ophthalmic Suspension (FML); Flurbiprofen Sodium Ophthalmic Solution (Ocufen); FML; Foradil; Formoterol Fumarate Inhalation Solution (Perforomist); Fosamax; Furadantin (Nitrofurantoin Oral Suspension); Furoxone; Gammagard Liquid (Immune Globulin Intravenous (Human) 10%); Gantrisin (Acetyl Sulfisoxazole Pediatric Suspension); Gatifloxacin Ophthalmic Solution (Zymar); Gengraf Oral Solution (Cyclosporine Oral Solution); Glycopyrrolate Oral Solution (Cuvposa); Halcinonide Topical Solution (Halog Solution); Halog Solution (Halcinonide Topical Solution); HEP-LOCK U/P (Preservative-Free Heparin Lock Flush Solution); Heparin Lock Flush Solution (Hepflush 10); Hexaminolevulinate Hydrochloride Intravesical Solution (Cysview); Hydrocodone Bitartrate and Acetaminophen Oral Solution (Lortab Elixir); Hydroquinone 3% Topical Solution (Melquin-3 Topical Solution); IAP Antagonist; Isopto; Ipratropium Bromide Nasal Spray (Atrovent Nasal Spray); Itraconazole Oral Solution (Sporanox Oral Solution); Ketorolac Tromethamine Ophthalmic Solution (Acular LS); Kaletra; Lanoxin; Lexiva; Leuprolide Acetate for Depot Suspension (Lupron Depot 11.25 mg); Levobetaxolol Hydrochloride Ophthalmic Suspension (Betaxon); Levocarnitine Tablets, Oral Solution, Sugar-Free (Carnitor); Levofloxacin Ophthalmic Solution 0.5% (Quixin); Lidocaine HCl Sterile Solution (Xylocaine MPF Sterile Solution); Lok Pak (Heparin Lock Flush Solution); Lorazepam Intensol; Lortab Elixir (Hydrocodone Bitartrate and Acetaminophen Oral Solution); Lotemax (Loteprednol Etabonate Ophthalmic Suspension); Loteprednol Etabonate Ophthalmic Suspension (Alrex); Low Calcium Peritoneal Dialysis Solutions (Dianeal Low Calcium); Lumigan (Bimatoprost Ophthalmic Solution 0.03% for Glaucoma); Lupron Depot 11.25 mg (Leuprolide Acetate for Depot Suspension); Megestrol Acetate Oral Suspension (Megestrol Acetate Oral Suspension); MEK Inhibitor; Mepron; Mesnex; Mestinon; Mesalamine Rectal Suspension Enema (Rowasa); Melquin-3 Topical Solution (Hydroquinone 3% Topical Solution); MetMab; Methyldopate Hcl (Methyldopate Hydrochloride Injection, Solution); Methylin Oral Solution (Methylphenidate HCl Oral Solution 5 mg/5 mL and 10 mg/5 ml); Methylprednisolone Acetate Injectable Suspension (Depo Medrol); Methylphenidate HCl Oral Solution 5 mg/5 mL and 10 mg/5 ml (Methylin Oral Solution); Methylprednisolone sodium succinate (Solu Medrol); Metipranolol Ophthalmic Solution (Optipranolol); Migranal; Miochol-E (Acetylcholine Chloride Intraocular Solution); Micro-K for Liquid Suspension (Potassium Chloride Extended Release Formulation for Liquid Suspension); Minocin (Minocycline Hydrochloride Oral Suspension); Nasacort; Neomycin and Polymyxin B Sulfates and Hydrocortisone; Nepafenac Ophthalmic Suspension (Nevanac); Nevanac (Nepafenac Ophthalmic Suspension); Nitrofurantoin Oral Suspension (Furadantin); Noxafil (Posaconazole Oral Suspension); Nystatin (oral) (Nystatin Oral Suspension); Nystatin Oral Suspension (Nystatin (oral)); Ocufen (Flurbiprofen Sodium Ophthalmic Solution); Ofloxacin Ophthalmic Solution (Ofloxacin Ophthalmic Solution); Ofloxacin Otic Solution (Floxin Otic); Olopatadine Hydrochloride Ophthalmic Solution (Pataday); Opticrom (Cromolyn Sodium Ophthalmic Solution); Optipranolol (Metipranolol Ophthalmic Solution); Patanol; Pediapred; PerioGard; Phenytoin Oral Suspension (Dilantin 125); Phisohex; Posaconazole Oral Suspension (Noxafil); Potassium Chloride Extended Release Formulation for Liquid Suspension (Micro-K for Liquid Suspension); Pataday (Olopatadine Hydrochloride Ophthalmic Solution); Patanase Nasal Spray (Olopatadine Hydrochloride Nasal Spray); PEG Electrolytes Solution (CoLyte); Pemirolast Potassium Ophthalmic Solution (Alamast); Penlac (Ciclopirox Topical Solution); PENNSAID (Diclofenac Sodium Topical Solution); Perforomist (Formoterol Fumarate Inhalation Solution); Peritoneal Dialysis Solution; Phenylephrine Hydrochloride Ophthalmic Solution (Neo-Synephrine); Phospholine lodide (Echothiophate lodide for Ophthalmic Solution); Podofilox (Podofilox Topical Solution); Pred Forte (Prednisolone Acetate Ophthalmic Suspension); Pralatrexate Solution for Intravenous Injection (Folotyn); Pred Mild; Prednisone Intensol; Prednisolone Acetate Ophthalmic Suspension (Pred Forte); Prevacid; PrismaSol Solution (Sterile Hemofiltration Hemodiafiltration Solution); ProAir; Proglycem; ProHance (Gadoteridol Injection Solution); Proparacaine Hydrochloride Ophthalmic Solution (Alcaine); Propine; Pulmicort; Pulmozyme; Quixin (Levofloxacin Ophthalmic Solution 0.5%); QVAR; Rapamune; Rebetol; Relacon-HC; Rotarix (Rotavirus Vaccine, Live, Oral Suspension); Rotavirus Vaccine, Live, Oral Suspension (Rotarix); Rowasa (Mesalamine Rectal Suspension Enema); Sabril (Vigabatrin Oral Solution); Sacrosidase Oral Solution (Sucraid); Sandimmune; Sepra; Serevent Diskus; Solu Cortef (Hydrocortisone Sodium Succinate); Solu Medrol (Methylprednisolone sodium succinate); Spiriva; Sporanox Oral Solution (Itraconazole Oral Solution); Staticin (Erythromycin Topical Solution 1.5%); Stalevo; Starlix; Sterile Hemofiltration Hemodiafiltration Solution (PrismaSol Solution); Stimate; Sucralfate (Carafate Suspension); Sulfacetamide Sodium Ophthalmic Solution 10% (Bleph 10); Synarel Nasal Solution (Nafarelin Acetate Nasal Solution for Endometriosis); Taclonex Scalp (Calcipotriene and Betamethasone Dipropionate Topical Suspension); Tamiflu; Tobi; TobraDex; Tobradex ST (Tobramycin/Dexamethasone Ophthalmic Suspension 0.3%/0.05%); Tobramycin/Dexamethasone Ophthalmic Suspension 0.3%/0.05% (Tobradex ST); Timolol; Timoptic; Travatan Z; Treprostinil Inhalation Solution (Tyvaso); Trusopt (Dorzolamide Hydrochloride Ophthalmic Solution); Tyvaso (Treprostinil Inhalation Solution); Ventolin; Vfend; Vibramycin Oral (Doxycycline Calcium Oral Suspension); Videx (Didanosine Pediatric Powder for Oral Solution); Vigabatrin Oral Solution (Sabril); Viokase; Viracept; Viramune; Vitamin K1 (Fluid Colloidal Solution of Vitamin K1); Voltaren Ophthalmic (Diclofenac Sodium Ophthalmic Solution); Zarontin Oral Solution (Ethosuximide Oral Solution); Ziagen; Zyvox; Zymar (Gatifloxacin Ophthalmic Solution); Zymaxid (Gatifloxacin Ophthalmic Solution);

### Drug Classes

5-alpha-reductase inhibitors; 5-aminosalicylates; 5HT3 receptor antagonists; adamantane antivirals; adrenal cortical steroids; adrenal corticosteroid inhibitors; adrenergic bronchodilators; agents for hypertensive emergencies; agents for pulmonary hypertension; aldosterone receptor antagonists; alkylating agents; alpha-adrenoreceptor antagonists; alpha-glucosidase inhibitors; alternative medicines; amebicides; aminoglycosides; aminopenicillins; aminosalicylates; amylin analogs; Analgesic Combinations; Analgesics; androgens and anabolic steroids; angiotensin converting enzyme inhibitors; angiotensin II inhibitors; anorectal preparations; anorexiants; antacids; anthelmintics; anti-angiogenic ophthalmic agents; anti-CTLA-4 monoclonal antibodies; anti-infectives; antiadrenergic agents, centrally acting; antiadrenergic agents, peripherally acting; antiandrogens; antianginal agents; antiarrhythmic agents; antiasthmatic combinations; antibiotics/antineoplastics; anticholinergic antiemetics; anticholinergic antiparkinson agents; anticholinergic bronchodilators; anticholinergic chronotropic agents; anticholinergics/antispasmodics; anticoagulants; anticonvulsants; antidepressants; antidiabetic agents; antidiabetic combinations; antidiarrheals; antidiuretic hormones; antidotes; antiemetic/antivertigo agents; antifungals; antigonadotropic agents; antigout agents; antihistamines; antihyperlipidemic agents; antihyperlipidemic combinations; antihypertensive combinations; antihyperuricemic agents; antimalarial agents; antimalarial combinations; antimalarial quinolines; antimetabolites; antimigraine agents; antineoplastic detoxifying agents; antineoplastic interferons; antineoplastic monoclonal antibodies; antineoplastics; antiparkinson agents; antiplatelet agents; antipseudomonal penicillins; antipsoriatics; antipsychotics; antirheumatics; antiseptic and germicides; antithyroid agents; antitoxins and antivenins; antituberculosis agents; antituberculosis combinations; antitussives; antiviral agents; antiviral combinations; antiviral interferons; anxiolytics, sedatives, and hypnotics; aromatase inhibitors; atypical antipsychotics; azole antifungals; bacterial vaccines; barbiturate anticonvulsants; barbiturates; BCR-ABL tyrosine kinase inhibitors; benzodiazepine anticonvulsants; benzodiazepines; beta-adrenergic blocking agents; beta-lactamase inhibitors; bile acid sequestrants; biologicals; bisphosphonates; bone resorption inhibitors; bronchodilator combinations; bronchodilators; calcitonin; calcium channel blocking agents; carbamate anticonvulsants; carbapenems; carbonic anhydrase inhibitor anticonvulsants; carbonic anhydrase inhibitors; cardiac stressing agents; cardioselective beta blockers; cardiovascular agents; catecholamines; CD20 monoclonal antibodies; CD33 monoclonal antibodies; CD52 monoclonal antibodies; central nervous system agents; cephalosporins; cerumenolytics; chelating agents; chemokine receptor antagonist; chloride channel activators; cholesterol absorption inhibitors; cholinergic agonists; cholinergic muscle stimulants; cholinesterase inhibitors; CNS stimulants; coagulation modifiers; colony stimulating factors; contraceptives; corticotropin; coumarins and indandiones; cox-2 inhibitors; decongestants; dermatological agents; diagnostic radiopharmaceuticals; dibenzazepine anticonvulsants; digestive enzymes; dipeptidyl peptidase 4 inhibitors; diuretics; dopaminergic antiparkinsonism agents; drugs used in alcohol dependence; echinocandins; EGFR inhibitors; estrogen receptor antagonists; estrogens; expectorants; factor Xa inhibitors; fatty acid derivative anticonvulsants; fibric acid derivatives; first generation cephalosporins; fourth generation cephalosporins; functional bowel disorder agents; gallstone solubilizing agents; gamma-aminobutyric acid analogs; gamma-aminobutyric acid reuptake inhibitors; gamma-aminobutyric acid transaminase inhibitors; gastrointestinal agents; general anesthetics; genitourinary tract agents; GI stimulants; glucocorticoids; glucose elevating agents; glycopeptide antibiotics; glycoprotein platelet inhibitors; glycylcyclines; gonadotropin releasing hormones; gonadotropin-releasing hormone antagonists; gonadotropins; group I antiarrhythmics; group II antiarrhythmics; group III antiarrhythmics; group IV antiarrhythmics; group V antiarrhythmics; growth hormone receptor blockers; growth hormones; H. pylori eradication agents; H2 antagonists; hematopoietic stem cell mobilizer; heparin antagonists; heparins; HER2 inhibitors; herbal products; histone deacetylase inhibitors; hormone replacement therapy; hormones; hormones/antineoplastics; hydantoin anticonvulsants; illicit (street) drugs; immune globulins; immunologic agents; immunosuppressive agents; impotence agents; in vivo diagnostic biologicals; incretin mimetics; inhaled anti-infectives; inhaled corticosteroids; inotropic agents; insulin; insulin-like growth factor; integrase strand transfer inhibitor; interferons; intravenous nutritional products; iodinated contrast media; ionic iodinated contrast media; iron products; ketolides; laxatives; leprostatics; leukotriene modifiers; lincomycin derivatives; lipoglycopeptides; local injectable anesthetics; loop diuretics; lung surfactants; lymphatic staining agents; lysosomal enzymes; macrolide derivatives; macrolides; magnetic resonance imaging contrast media; mast cell stabilizers; medical gas; meglitinides; metabolic agents; methylxanthines; mineralocorticoids; minerals and electrolytes; miscellaneous agents; miscellaneous analgesics; miscellaneous antibiotics; miscellaneous anticonvulsants; miscellaneous antidepressants; miscellaneous antidiabetic agents; miscellaneous antiemetics; miscellaneous antifungals; miscellaneous antihyperlipidemic agents; miscellaneous antimalarials; miscellaneous antineoplastics; miscellaneous antiparkinson agents; miscellaneous antipsychotic agents; miscellaneous antituberculosis agents; miscellaneous antivirals; miscellaneous anxiolytics, sedatives and hypnotics; miscellaneous biologicals; miscellaneous bone resorption inhibitors; miscellaneous cardiovascular agents; miscellaneous central nervous system agents; miscellaneous coagulation modifiers; miscellaneous diuretics; miscellaneous genitourinary tract agents; miscellaneous GI agents; miscellaneous hormones; miscellaneous metabolic agents; miscellaneous ophthalmic agents; miscellaneous otic agents; miscellaneous respiratory agents; miscellaneous sex hormones; miscellaneous topical agents; miscellaneous uncategorized agents; miscellaneous vaginal agents; mitotic inhibitors; monoamine oxidase inhibitors; monoclonal antibodies; mouth and throat products; mTOR inhibitors; mTOR kinase inhibitors; mucolytics; multikinase inhibitors; muscle relaxants; mydriatics; narcotic analgesic combinations; narcotic analgesics; nasal anti-infectives; nasal antihistamines and decongestants; nasal lubricants and irrigations; nasal preparations; nasal steroids; natural penicillins; neuraminidase inhibitors; neuromuscular blocking agents; next generation cephalosporins; nicotinic acid derivatives; nitrates; NNRTIs; non-cardioselective beta blockers; non-iodinated contrast media; non-ionic iodinated contrast media; non-sulfonylureas; nonsteroidal anti-inflammatory agents; norepinephrine reuptake inhibitors; norepinephrine-dopamine reuptake inhibitors; nucleoside reverse transcriptase inhibitors (NRTIs); nutraceutical products; nutritional products; ophthalmic anesthetics; ophthalmic anti-infectives; ophthalmic anti-inflammatory agents; ophthalmic antihistamines and decongestants; ophthalmic diagnostic agents; ophthalmic glaucoma agents; ophthalmic lubricants and irrigations; ophthalmic preparations; ophthalmic steroids; ophthalmic steroids with anti-infectives; ophthalmic surgical agents; oral nutritional supplements; otic anesthetics; otic anti-infectives; otic preparations; otic steroids; otic steroids with anti-infectives; oxazolidinedione anticonvulsants; parathyroid hormone and analogs; penicillinase resistant penicillins; penicillins; peripheral opioid receptor antagonists; peripheral vasodilators; peripherally acting antiobesity agents; phenothiazine antiemetics; phenothiazine antipsychotics; phenylpiperazine antidepressants; plasma expanders; platelet aggregation inhibitors; platelet-stimulating agents; polyenes; potassium-sparing diuretics; probiotics; progesterone receptor modulators; progestins; prolactin inhibitors; prostaglandin D2 antagonists; protease inhibitors; proton pump inhibitors; psoralens; psychotherapeutic agents; psychotherapeutic combinations; purine nucleosides; pyrrolidine anticonvulsants; quinolones; radiocontrast agents; radiologic adjuncts; radiologic agents; radiologic conjugating agents; radiopharmaceuticals; RANK ligand inhibitors; recombinant human erythropoietins; renin inhibitors; respiratory agents; respiratory inhalant products; rifamycin derivatives; salicylates; sclerosing agents; second generation cephalosporins; selective estrogen receptor modulators; selective serotonin reuptake inhibitors; serotonin-norepinephrine reuptake inhibitors; serotoninergic neuroenteric modulators; sex hormone combinations; sex hormones; skeletal muscle relaxant combinations; skeletal muscle relaxants; smoking cessation agents; somatostatin and somatostatin analogs; spermicides; statins; sterile irrigating solutions; streptomyces derivatives; succinimide anticonvulsants; sulfonamides; sulfonylureas; synthetic ovulation stimulants; tetracyclic antidepressants; tetracyclines; therapeutic radiopharmaceuticals; thiazide diuretics; thiazolidinediones; thioxanthenes; third generation cephalosporins; thrombin inhibitors; thrombolytics; thyroid drugs; tocolytic agents; topical acne agents; topical agents; topical anesthetics; topical anti-infectives; topical antibiotics; topical antifungals; topical antihistamines; topical antipsoriatics; topical antivirals; topical astringents; topical debriding agents; topical depigmenting agents; topical emollients; topical keratolytics; topical steroids; topical steroids with anti-infectives; toxoids; triazine anticonvulsants; tricyclic antidepressants; trifunctional monoclonal antibodies; tumor necrosis factor (TNF) inhibitors; tyrosine kinase inhibitors; ultrasound contrast media; upper respiratory combinations; urea anticonvulsants; urinary anti-infectives; urinary antispasmodics; urinary pH modifiers; uterotonic agents; vaccine; vaccine combinations; vaginal anti-infectives; vaginal preparations; vasodilators; vasopressin antagonists; vasopressors; VEGF/VEGFR inhibitors; viral vaccines; viscosupplementation agents; vitamin and mineral combinations; vitamins; protein-based vaccines; DNA-based vaccines; mRNA-based vaccines;

### Diagnostic Tests

17-Hydroxyprogesterone; ACE (Angiotensin I converting enzyme); Acetaminophen; Acid phosphatase; ACTH; Activated clotting time; Activated protein C resistance; Adrenocorticotropic hormone (ACTH); Alanine aminotransferase (ALT); Albumin; Aldolase; Aldosterone; Alkaline phosphatase; Alkaline phosphatase (ALP); Alpha1-antitrypsin; Alpha-fetoprotein; Alpha-fetoprotien; Ammonia levels; Amylase; ANA (antinuclear antbodies); ANA (antinuclear antibodies); Angiotensin-converting enzyme (ACE); Anion gap; Anticardiolipin antibody; Anticardiolipin antivbodies (ACA); Anti-centromere antibody; Antidiuretic hormone; Anti-DNA; Anti-Dnase-B; Anti-Gliadin antibody; Anti-glomerular basement membrane antibody; Anti-HBC (Hepatitis B core antibodies; Anti-HBs (Hepatitis B surface antibody; Antiphospholipid antibody; Anti-RNA polymerase; Anti-Smith (Sm) antibodies; Anti-Smooth Muscle antibody; Antistreptolysin O (ASO); Antithrombin III; Anti-Xa activity; Anti-Xa assay; Apolipoproteins; Arsenic; Aspartate aminotransferase (AST); B12; Basophil; Beta-2-Microglobulin; Beta-hydroxybutyrate; B-HCG; Bilirubin; Bilirubin, direct; Bilirubin, indirect; Bilirubin, total; Bleeding time; Blood gases (arterial); Blood urea nitrogen (BUN); BUN; BUN (blood urea nitrogen); CA 125; CA 15-3; CA 19-9; Calcitonin; Calcium; Calcium (ionized); Carbon monoxide (CO); Carcinoembryonic antigen (CEA); CBC; CEA; CEA (carcinoembryonic antigen); Ceruloplasmin; CH50Chloride; Cholesterol; Cholesterol, HDL; Clot lysis time; Clot retraction time; CMP; CO2; Cold agglutinins; Complement C3; Copper; Corticotrophin releasing hormone (CRH) stimulation test; Cortisol; Cortrosyn stimulation test; C-peptide; CPK (Total); CPK-MB; C-reactive protein; Creatinine; Creatinine kinase (CK); Cryoglobulins; DAT (Direct antiglobulin test); D-Dimer; Dexamethasone suppression test; DHEA-S; Dilute Russell viper venom; Elliptocytes; Eosinophil; Erythrocyte sedimentation rate (ESR); Estradiol; Estriol; Ethanol; Ethylene glycol; Euglobulin lysis; Factor V Leiden; Factor VIII inhibitor; Factor VIII level; Ferritin; Fibrin split products; Fibrinogen; Folate; Folate (serum; Fractional excretion of sodium (FENA); FSH (follicle stimulating factor); FTA-ABS; Gamma glutamyl transferase (GGT); Gastrin; GGTP (Gamma glutamyl transferase); Glucose; Growth hormone; Haptoglobin; HBeAg (Hepatitis Be antigen); HBs-Ag (Hepatitis B surface antigen); Helicobacter pylori; Hematocrit; I Hematocrit (HCT); Hemoglobin; Hemoglobin A1C; Hemoglobin electrophoresis; Hepatitis A antibodies; Hepatitis C antibodies; IAT (Indirect antiglobulin test); Immunofixation (IFE); Iron; Lactate dehydrogenase (LDH); Lactic acid (lactate); LDH; LH (Leutinizing hormone; Lipase; Lupus anticoagulant; Lymphocyte; Magnesium; MCH (mean corpuscular hemoglobin; MCHC (mean corpuscular hemoglobin concentration); MCV (mean corpuscular volume); Methylmalonate; Monocyte; MPV (mean platelet volume); Myoglobin; Neutrophil; Parathyroid hormone (PTH); Phosphorus; Platelets (plt); Potassium; Prealbumin; Prolactin; Prostate specific antigen (PSA); Protein C; Protein S; PSA (prostate specific antigen); PT (Prothrombin time); PTT (Partial thromboplastin time); RDW (red cell distribution width); Renin; Rennin; Reticulocyte count; reticulocytes; Rheumatoid factor (RF); Sed Rate; Serum glutamic-pyruvic transaminase (SGPT; Serum protein electrophoresis (SPEP); Sodium; T3-resin uptake (T3RU); T4, Free; Thrombin time; Thyroid stimulating hormone (TSH); Thyroxine (T4); Total iron binding capacity (TIBC); Total protein; Transferrin; Transferrin saturation; Triglyceride (TG); Troponin; Uric acid; Vitamin B12; White blood cells (WBC); Widal test.

### BRIEF DESCRIPTION OF THE DRAWINGS

FIG. 1 is a perspective view of a conventional, prior art workstation for manual visual inspection.

FIG. 2 is an exploded perspective view of a conventional nest and tub package of ready to use (RTU) vials

FIG. 3 is a cross-sectional view of a first example vial, showing a bottom wall, a side wall, a top opening, a shoulder region, a neck, a top flange, and a transition between the side wall and the bottom wall.

FIG. 4 is a cross-sectional view of a second example vial, showing a bottom wall, a side wall, a top opening, a shoulder region, a neck, a top flange, and a transition between the side wall and the bottom wall; and also including a cover (the combination of stopper 411 and cap 412).

FIG. 5 is a cross-sectional view of a first example syringe barrel, showing a side wall, a rear opening, a rear flange, a shoulder region, and a needle hub; and also including a plunger 509 and a rigid needle shield 511.

FIG. 6 is a cross-sectional view of a second example syringe barrel, showing a side wall, a rear opening, a rear flange, a shoulder region, and a Luer hub; and also including a plunger and a tip cap.

FIG. 7 is a perspective view of an example blood collection tube, showing a side wall, a bottom wall, a transition region between the side wall and the bottom wall; and also including a cap 270.

FIG. 8A is an example image of a vial collected by a side body camera in accordance with an embodiment of the vessel inspection system/method of the present disclosure.

FIG. 8B is the image of FIG. 8A, as modified by a processor to identify the areas of inspection applied to that image.

FIG. 9A is an example image of a vial collected by an angled shoulder camera in accordance with an embodiment of the vessel inspection system/method of the present disclosure.

FIG. 9B is the image of FIG. 9A, as modified by a processor to identify the areas of inspection applied to that image.

FIG. 10A is an example image of a vial collected by an angled top camera in accordance with an embodiment of the vessel inspection system/method of the present disclosure.

FIG. 10B is the image of FIG. 10A, as modified by a processor to identify the areas of inspection applied to that image.

FIG. 11A is an example image of a vial collected by an angled bottom camera in accordance with an embodiment of the vessel inspection system/method of the present disclosure.

FIG. 11B is the image of FIG. 8A, as modified by processor to identify the area of inspection applied to that image.

FIG. 12A is an example image of a vial collected by a bottom camera in accordance with an embodiment of the vessel inspection system/method of the present disclosure.

FIG. 12B is the image of FIG. 9A, as modified by processor to identify the area of inspection applied to that image.

FIG. 13A is a front perspective view of an embodiment of a side body inspection station of the vessel inspection system/method of the present disclosure.

FIG. 13B is a rear perspective view of the embodiment of a side body inspection station shown in FIG. 13A.

FIG. 14 is a rear, top perspective view of an embodiment of a shoulder inspection station of the vessel inspection system/method of the present disclosure.

FIG. 15 is rear perspective view of an embodiment of a top inspection station of the vessel inspection system/method of the present disclosure.

FIG. 16 is a perspective view of an embodiment of a rotatable vessel holder for a top inspection station of the vessel inspection system/method of the present disclosure.

FIG. 17 is a perspective view of an embodiment of an inspection station for both the bottom wall and the transition between the sidewall and the bottom wall of the vessel inspection system/method of the present disclosure.

FIG. 18 is a perspective view of an embodiment of a vessel coating system.

FIG. 19 is a cross-sectional view of an embodiment of a vessel coating system, configured to coat the inner surfaces of a vial and which includes a source gas inlet probe.

FIG. 20 is a cross-sectional view of an embodiment of a vessel coating system, configured to coat the inner surfaces of a vial and which does not include a source gas inlet probe.

FIG. 21A is a perspective view of an embodiment of a vessel coating system that includes a visual inspection system configured to collect and analyze images of the electrode cavities for the presence of particles.

FIG. 21B is an example image of electrode cavities collected by a camera of the visual inspection system shown in FIG. 21A.

FIG. 22 is a cross-sectional view of a first embodiment of a vessel holder of a coating system of the present disclosure.

FIG. 23 is a cross-sectional view of a second embodiment of a vessel holder of a coating system of the present disclosure.

FIG. 24 is a top perspective view of an embodiment of an electrode cleaning system of the present disclosure.

FIG. 25 is a cross-sectional view of the embodiment of an electrode cleaning system shown in FIG. 24.

FIG. 26 is a top perspective view of an embodiment of a cleaning system configured to remove particles from the inner surfaces of a vessel.

FIG. 27 is a cross-sectional view of the embodiment of a cleaning system shown in FIG. 26.

FIG. 28 is a top perspective view of an embodiment of a cleaning system configured to remove particles from at least a portion of the outer surfaces of a vessel.

FIG. 29 is a cross-sectional view of the embodiment of a cleaning system shown in FIG. 28, taken along the length of the system.

FIG. 30 is a cross-sectional view of the embodiment of a cleaning system shown in FIGS. 28-29, taken along the width of the system.

FIG. 31 is a chart showing the particle count of vials coated using a vessel coating system in which the vials and the coating system were cleaned according to the present disclosure compared against the particle count of vials coated using the same vessel coating system but without the cleaning steps.

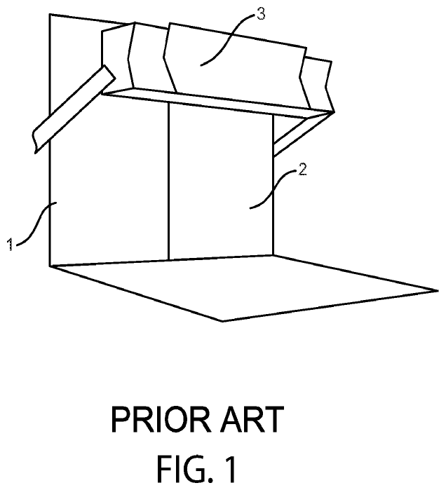

### DETAILED DESCRIPTION

In the context of the present invention, the following definitions and abbreviations are used:

The term “at least” in the context of the present invention means “equal or more” than the integer following the term. The word “comprising” does not exclude other elements or steps, and the indefinite article “a” or “an” does not exclude a plurality unless indicated otherwise. Whenever a parameter range is indicated, it is intended to disclose the parameter values given as limits of the range and all values of the parameter falling within said range.

“First” and “second” or similar references to, for example processing stations or processing devices refer to the minimum number of processing stations or devices that are present, but do not necessarily represent the order or total number of processing stations and devices or require additional processing stations and devices beyond the stated number. These terms do not limit the number of processing stations or the particular processing carried out at the respective stations. For example, a “first” station in the context of this specification can be either the only station or any one of plural station, without limitation. In other words, recitation of a “first” station allows but does not require an embodiment that also has a second or further station.

The word “comprising” does not exclude other elements or steps.

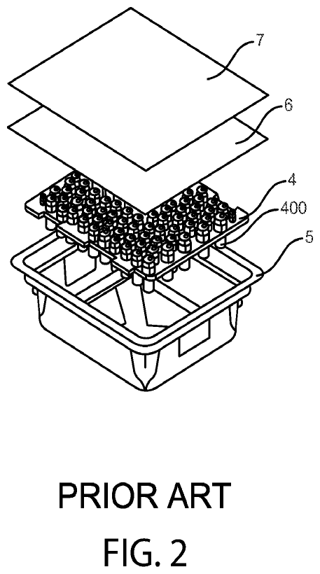

The term “ready-to-use” or “ready to use” or “RTU” refer to containers, such as vials, syringe barrels, cartridges, etc., that are empty, clean, and sterile such that they are configured to be filled without any additional processing. RTU containers are typically cleaned (e.g. washed) and then packaged in a nest-and-tub configuration, with the tray and tub being sealed with a Tyvek® seal. The nest-and-tub configuration of containers is then sterilized. An example of a nest-and-tub configuration of RTU vials is shown in FIG. 2. As shown in the illustrated example, a typical nest-and-tub configuration of RTU vials may include a nest 4 which holds a plurality of vials 400, a tub 5 which encloses the nest and vials, an inlay 6, and a seal 7.

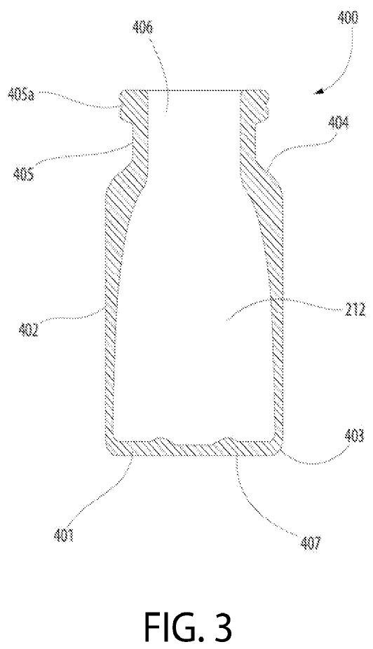

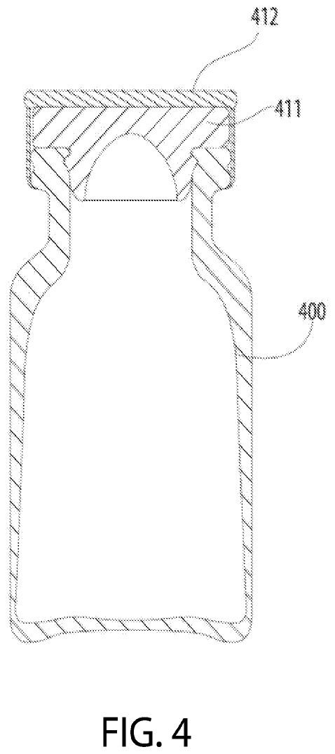

An example vial 400 is shown in FIG. 3. Vials 400 of the present disclosure may include a bottom wall 401, a side wall extending 402 upward from the bottom wall, a curved lower edge joining the bottom wall and the side wall 403, a radially inwardly extending shoulder 404 formed at the top of the side wall, and a neck 405 extending upwardly from the shoulder, the neck ending at a neck flange 405a which defines an opening 406 leading to the vial interior, i.e. lumen 212. The bottom wall 401 may have a flat or substantially flat lower surface 407 as shown in FIG. 3. Alternatively, the bottom wall 401 may have an outer resting ring and a central, curved push-up region, as is the case for conventional vials such as that shown in FIG. 4. Vials having both types of bottoms may be coated, cleaned, and inspected using the methods and systems disclosed herein. Vials 400 may be made of borosilicate glass or transparent thermoplastic materials, such as cyclic olefin polymers (COP) or cyclic olefin copolymers (COC).

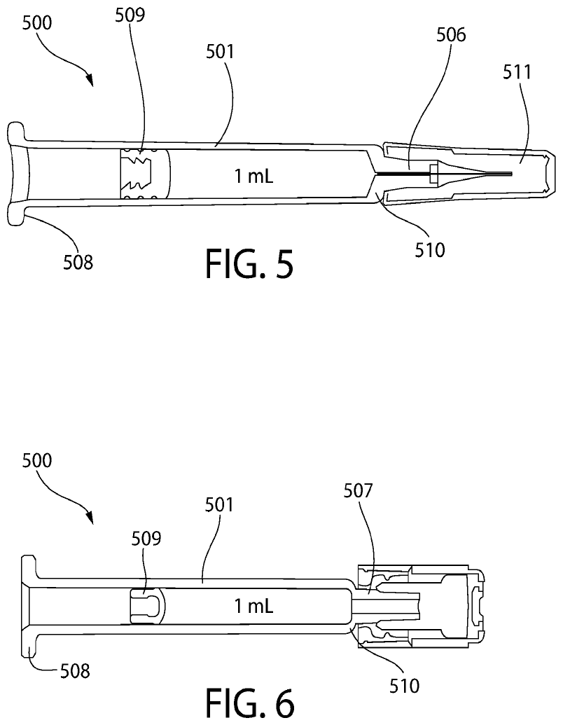

Example syringes are shown in FIGS. 5 and 6. In particular, FIG. 5 shows a syringe having a needle hub 506 and needle, which is shown being covered and protected by a rigid needle shield 511. FIG. 6 shows a syringe having a luer hub 507 in place of a needle, which is shown being covered by a tip cap. In both instances, the syringe barrel 500 comprises a side wall portion 501 spanning between a rear end, which comprises an opening to the lumen, and a front end, which comprises a needle hub 506 or the luer hub 507. The rear end of the syringe barrel comprises a flange 508 having an upper surface surrounding the opening to the lumen and an outer surface that extends beyond the main portion of the side wall 501. At the front end of the syringe barrel, the side wall portion 501 contains a shoulder 510 wheren the side wall transitions from the main side wall portion to the needle hub 506 or luer hub 507 portion. Both syringes are also shown as containing a plunger 509, though the plunger is not part of the syringe barrel 500.

For purposes of the coating, cleaning, and vessel inspection technology described herein, the rear end of a syringe barrel should be considered equivalent to the top portion of a vial, as both contain an opening to the lumen. Moreover, though the shoulder 510 of a syringe barrel is positioned toward the front end, it is contemplated that identical or substantially identical inspection techniques may be applied to the shoulder portion 510 of a syringe barrel as are described with regard to a shoulder portion 404 of a vial 400. In general, though no such embodiment is illustrated, it is contemplated that identical or substantially identical inspection techniques may be applied to the various portions of a syringe barrel as are shown and described with respect to a vial.

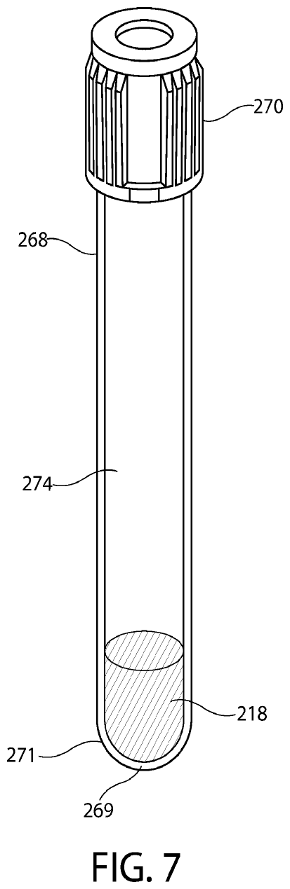

An example blood collection tube 274 is shown in FIG. 7. The blood collection tube comprises a side wall 268 that spans between a closed bottom end and an open top end. The open top end, which includes an opening to the central lumen, is illustrated as being covered by a cap 270. The open top end may or may not include a small flange. The closed bottom end comprises a small bottom wall 269. The blood collection tube also comprises a transition region 271 between the side wall 268 and the bottom wall 269.

For purposes of the coating, cleaning, and inspection technology described herein, a blood collection tube 274 should be considered similar to an example vial 400 in that both comprise a side wall portion 268, an opening to the lumen at a top end of the vessel, and a closed bottom end. Like a vial, a blood collection tube 274 also has a transition region 271 between the side wall 268 and a bottom wall 269. Unlike a vial 400, a blood collection tube 274 typically does not include a shoulder. Although no such embodiment is illustrated, it is contemplated that identical or substantially identical inspection techniques may be applied to the various portions of a blood collection tube 274 as are shown and described with regard to a vial 400

RTU containers are supplied to a pharmaceutical company or contract development and manufacturing organization (CDMO) for filling. In a sterile environment, the pharmaceutical company or CDMO unseals the tray and tub, fills the containers, and seals the containers, for example by inserting a rubber stopper 411 into the opening of a vial and optionally applying an additional cap 412, typically made of a metal such as aluminum and crimped over the top of the stopper and neck flange 405a of the vial, by inserting a plunger 509 into a syringe barrel or cartridge, or by a blood collection tube cap 270. RTU containers eliminate the need for the pharmaceutical company to process the containers, e.g. by washing or sterilizing, prior to filling.

The word “syringe” is meant to include syringes having embedded needles, such as staked needle syringes, as well as those which instead have Luer lock or Luer cone fluid outlets. The term “syringe barrel” is meant to refer to the barrel of the syringe, including, if present, any embedded needle and/or any removable cap or needle shield, but excluding the plunger, which is inserted after filling.

The term “Acceptable Quality Level” or “AQL” means the maximum percent defective (or maximum number of defects per 100 units) that can be considered acceptable. AQL is measured in defects per 100 units. AQLs dictate the maximum number of defective containers beyond which a batch or lot is rejected.

The present invention will now be described more fully, with reference to the accompanying drawings, in which several embodiments are shown. This invention can, however, be embodied in many different forms and should not be construed as limited to the embodiments set forth here. Rather, these embodiments are examples of the invention, which has the full scope indicated by the language of the claims. Like numbers refer to like or corresponding elements throughout.

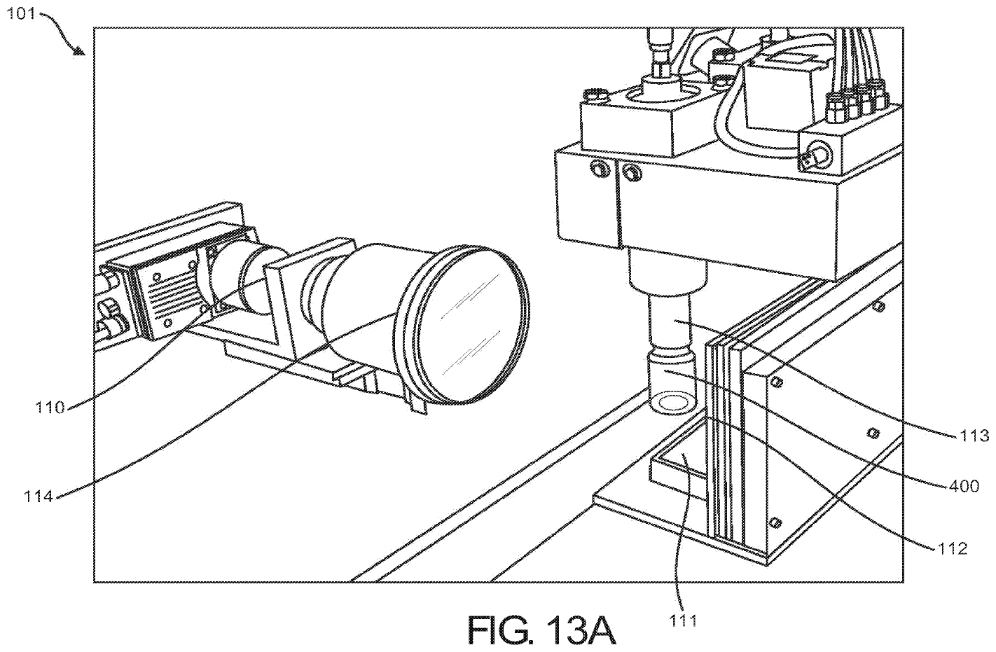

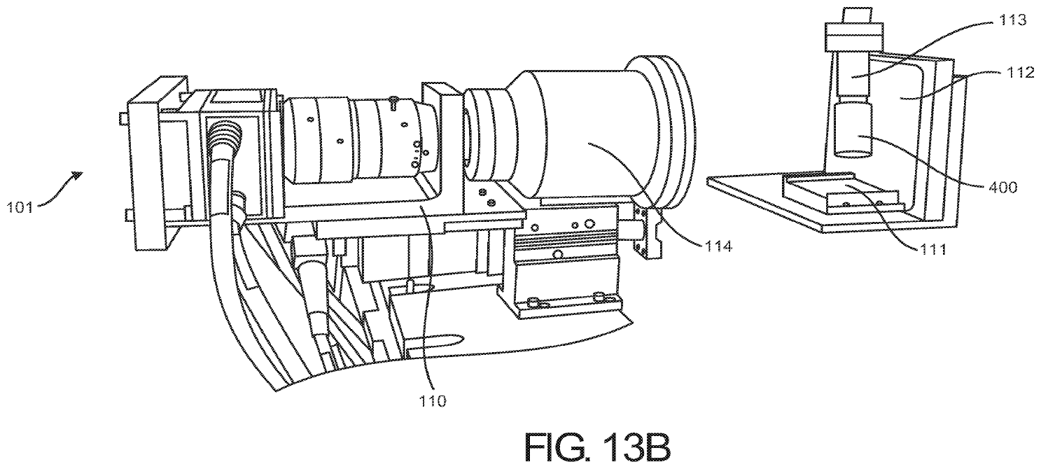

A plurality of vials 400 were inspected using the system shown in FIG. 13A through FIG. 17 and described herein.

The vials 400 are moved between a variety of inspection stations, including a side body inspection station 101, an angled shoulder inspection station 102, an angled top inspection station 103, an angled bottom inspection station 104, and a bottom inspection station 105, though in some embodiments, including the illustrated embodiment, the angled bottom inspection station and bottom inspection station may be combined in a single station 104,105. Transport of the plurality of vials 400 between each station 101, 102, 103, 104, 105 may be automated, as may be the placement and positioning of a vial in each inspection station. In some embodiments, the plurality of vials 400 may be transported along one or more transport lines until reaching a predetermined point at which at least one of the vials is removed from the transport line by one of a vessel holder or vessel conveying unit (depending on which inspection station). The vessel holder or vessel conveying unit may then convey the vessel to the inspection station 101, 102, 103, 104, 105 or certain components of the inspection station, e.g. the bottom light and side light, may be brought into position adjacent the vessel holder so as to partially form the vessel compartment of the inspection station in the immediate vicinity of the transport line, e.g. directly above the transport line. Where a vessel conveying unit is used, the vessel conveying unit may also position the vial on the vessel holder of the inspection station for inspection. Once the images have been captured, the vessel holder or vessel conveying unit may then return the vial to the transport unit and the vial may be transported to a subsequent inspection station until each inspection has been performed.

Moreover, in any embodiment, a number of identical inspection stations may be arranged next to one another so that multiple vials 400 are inspected at a given time.

### Side Body Inspection

FIGS. 13A and 13B show a side body inspection station 101, also referred to as a sidewall inspection station. The side body inspection station 101 comprises a body side camera 110, a bottom light 111, a side light 112, and a vessel holder 113.

The bottom light 111 is configured and positioned such that the bottom light is below a vial 400 and the light shines upward, e.g. through the bottom of the vial and around all sides of the vial. In some embodiments, the bottom light 111 may be a direct backlight, e.g. a 63 mm×60 mm Direct Backlight, Blue LED, M12, or similar light. The use of blue light is optional but desirable because it enhances the color of plasma flake particles, such as may be present from one or more coatings on the sidewall of the vial 400. The side light 112 is positioned such that the side light is behind a vial 400 from the perspective of the camera 110 (i.e. on an opposite side of the vial from the camera) and the light shines through the sidewall of the vial and beyond the sides of the vial as viewed from the camera. In some embodiments, the side light 112 may be a direct backlight, e.g. a 100 mm×100 mm High Output Flat Light, Blue, M12, or similar light. Again, the use of blue light is optional but desirable because it enhances the color of plasma flake particles, such as may be present from one or more coatings on the sidewall of the vial 400. The high output flat light is desirably used in place of a direct backlight of the sort used as the bottom light 111 because in this embodiment, the body side camera 110 comprises a telecentric lens 114.

In the illustrated embodiment, the bottom light 111 and the side light 112 define the bottom and rear surfaces of a vessel compartment 115 within which a vial 400 is held. Here, the sides and front of the vessel compartment 115 are completely open. However, in other embodiments, one or both of the sides and/or the front may be partially or completely closed.

The body side camera 110 is positioned in front of the vessel compartment 115 and the lens is directed at the vessel compartment. The body side camera 110 is desirably an area scan camera. Preferably, the body side camera 110 is an area scan camera that captures at least a 60° arc of the vial sidewall, so that the entire vial sidewall 402 can inspected using six or fewer image captures. For instance, the body side camera 110 may be an area scan camera that capture at least a 65° arc of the vessel sidewall (which provides overlap with adjacent arcs and thus ensures that the entirety of the sidewall is captured and inspected). In some embodiments, the body side camera 110 may be a Cognex In-Sight 9912M, 12.0MP camera.

The body side camera 110 may also comprise a high resolution telecentric lens 114 (as well as the associated lens bracket and bandpass filter). The use of a telecentric lens 114 is desirable because of the relatively large area of the vial sidewall 402 that is captured at this inspection station 101. If a standard lens is used, the captured image is likely to be subject to a slight fisheye effect, which interferes with the accurate measurement of particle sizes, i.e. particles present at the top and bottom portions of the sidewall 402 will appear differently than particles present at the middle portion of the side wall. By using a telecentric lens 114, the system can be calibrated to measure particle size consistently across the entire sidewall 402 of the vial 400. In other (nonillustrated) embodiments, it is envisioned that multiple cameras having standard lenses may be used in place of a single camera 110 bearing a telecentric lens 114, or even that a single camera having a standard lens may be used and the system calibrated to account for the resulting fisheye effect. If a telecentric lens 114 is not used, the side light 112 may not need to be as bright as that used in the illustrated embodiment.

The vessel holder 113 is configured to hold a vial 400 from above, without contacting the sidewall 402 of the vial or otherwise interfering with sightlines around the sidewall of the vial, including the side of the neck 405 and the side of the neck flange 405a. In the illustrated embodiment, for example, the vessel holder 113 interacts with the top of the neck flange 405a of the vial, e.g. by clamping, suction, or the like, such that the vial 400 is suspended from the vessel holder within the vessel compartment 115. As such, the vessel holder 113 forms at least a partial top surface of the vessel compartment 115.

The vessel holder 113 is also configured to rotate the vial so that the full 360° of the sidewall 402 can be image captured and inspected. In some embodiments, the vessel holder 113 is configured to rotate continuously, which allows for a high throughput inspection process. For example, the vessel holder 116 of the illustrated embodiment is configured to rotate at a speed of up to about 120 rpm. Continuous rotation, of course, requires that the camera 110 have the shutter open very briefly. For instance, the camera 110 may be selected and the lights 111, 112 configured and positioned such that the shutter remains open for less than one millisecond when capturing an image. In other embodiments, the vial 400 may be rotated discontinuously, i.e. the vial may be held steady for each image capture and rotated in between the image captures.

In the illustrated embodiment, the vessel holder 113 is movable relative to the camera 110 and lights 111, 112. In this manner, the vessel holder 113 may pick up a vial 400, e.g. from a transport line or a different inspection station, and position the vial within the vessel compartment 115 for inspection. In other embodiments, certain components such as the lights 111, 112 may instead be moved into place next to the vessel holder 113, e.g. the vessel holder may remove a vial 400 from a transport line and then the lights 111, 112 may be brought into position in the immediate vicinity (e.g. directly above) the transport line to form the vessel compartment 115 of the inspection station 101.

Although the inspection station 101 is described as oriented in the drawings, in other non-illustrated embodiments, the vessel compartment 115 may be flipped 180 degrees, such that the bottom light 111 forms the top of the vessel compartment and the vessel holder 113 forms at least a partial bottom of the vessel compartment. Indeed, so long as the relationships between the camera 110, the lights 111, 112, and the vial 400 that allow for accurate image capture are maintained, the components can be oriented in any desirable manner.

It is also contemplated that, in other non-illustrated embodiments, the side body inspection station 101 and the angled shoulder inspection station 102 may be combined, such that an angled shoulder camera 120 may capture images during the same rotation of the vial 400 as the side body camera 110. This could be done by, for example, having the image captures of the two cameras 110, 120 offset in time from one another and varying the characteristics, e.g. intensity, of the light as may be needed between the light characteristics used for image capture by the side body camera 110 and the light characteristics used for image capture by the angled shoulder camera 120. This could also be done by using one or more cameras having standard lenses for the side body inspection (or a camera having a telemetric lens for the angled shoulder camera, though this may be undesirable for other reasons).

To inspect the sidewall 402 of a vial, the vial 400 is picked up by the vessel holder 113 and positioned within the vessel compartment 115 of the sidewall inspection station 101. While the bottom light 111 and the side light 112 are illuminated, the vial 400 is rotated 360° about its longitudinal axis. During that rotation, the camera 110 captures a number of images, e.g. six images, of the side body portion of the vial. Together the captured images show the entire 360° surface of the vial side body portion. The captured images are processed by one or more system processors to identify (i) the presence of particles within the designated side body inspection areas and (ii) the size of any identified particles.

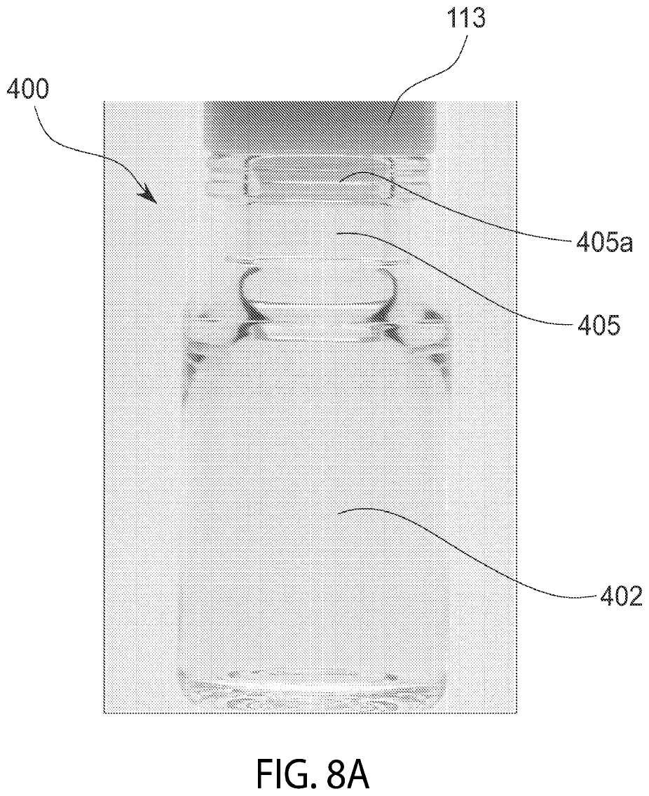

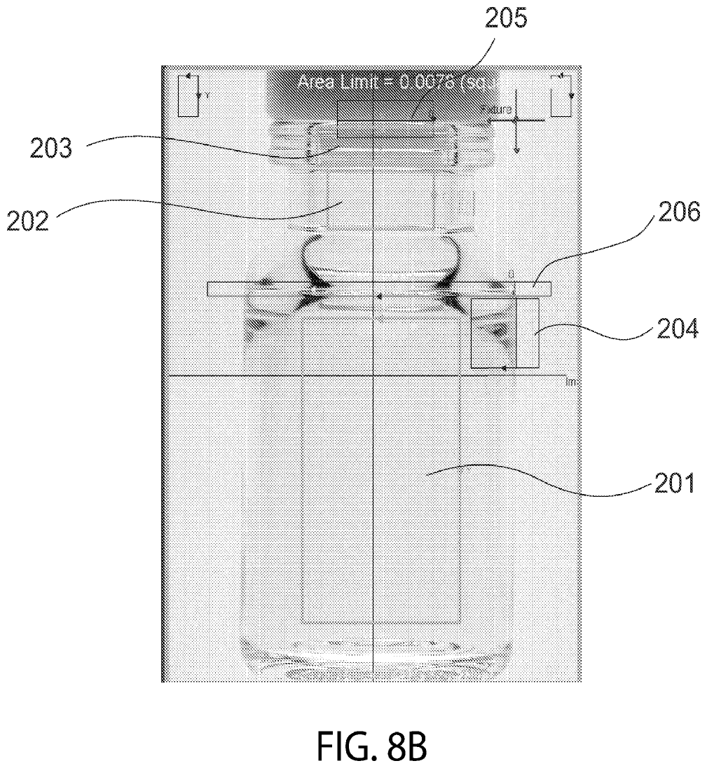

An example of an image capture taken by the side body camera 110 during this inspection process is shown in FIG. 8A. FIG. 8B shows the same image, as processed by the system, and in particular the one or more processors. The processor identifies independent inspection area or areas, an example of which are shown on FIG. 8B as boxes 201, 202, and 203. In order to ensure that the inspection areas 201, 202, 203 are properly identified, the system may not rely solely on the center of the image (which would require that the vessel holder 113 position the vial 400 in perfect alignment with the center of the camera lens). Rather, as shown in FIG. 8B as boxes 204, 205, and 206 the system may be configured to identify image elements that correspond with certain portions of the vial 400, such as the side of the vial in the captured image (in box 204), the top of the vial in the captured image (in box 205), and/or the shadow in the captured image that represents a shoulder portion of the vial (in box 206). The system may then determine the precise placement of the inspection area or areas 201, 202, 203 based on the location of those image elements.

As shown in FIG. 8B, the side body portion of a vial 400 may be divided into three side body inspection areas: a main body portion 201, a neck portion 202, and a neck flange side portion 203. The system may be separately calibrated for each inspection area in order to account for surface features or the like. For instance, the system may be calibrated to account for the image elements caused by surface features present on the neck flange side portion 203 such that they are not misidenfied as particles or defects. The presence of a similar image element in the main body portion 201 may be correctly identified as a particle or defect.

As shown in FIG. 8B, the shoulder portion 404 of the vial is subjected to a significant shadowing effect and is thus unable to be inspected using the camera and light configuration of the side body inspection station 101. Similarly, the transition region 403 between the main body of the sidewall 402 and the bottom wall 401 of the vial is subject to distortion and is unable to be inspected using the camera and light configuration of the side body inspection station 101. Accordingly, the vial 400 is transported to further inspections stations.

In other embodiments of the vessel inspection system and method disclosed herein, e.g. where the system is configured to inspect a syringe barrel, the inspection area or areas defined by the one or more processors may differ, e.g. a different number of inspection areas may be defined by the one or more processors, the inspection areas may have different dimensions, etc. For instance, because the sidewall of a blood collection tube typically has few, if any, geometric features such as a shoulder portion or a neck portion, only a single inspection area (of relatively high aspect ratio) may be applied to each image. Additionally, minor modifications may be made to the system components to accommodate the differing geometry of the specific vessel/container being inspected. Regardless of those distinctions, however, the inspection system and method of the present disclosure may be applied to any of a variety of containers, including syringe barrels (and cartridge barrels) and blood collection tubes.

### Shoulder Inspection

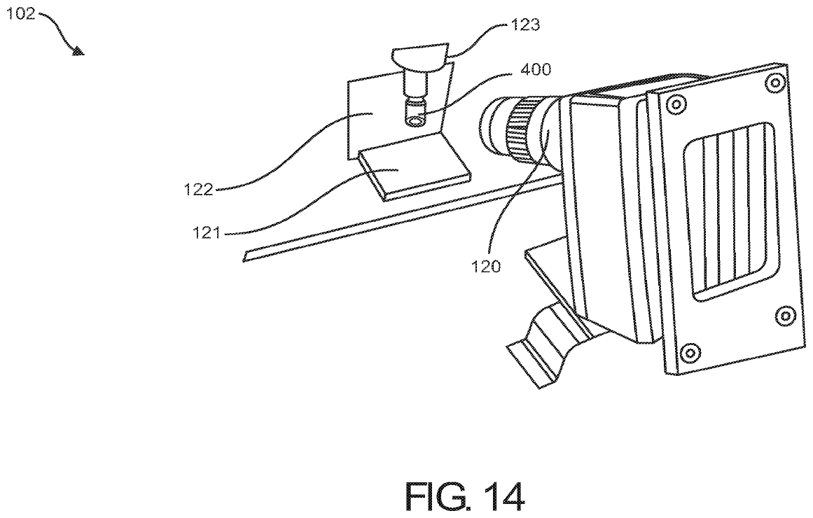

FIG. 14 shows a shoulder inspection station 102, also known as an angled shoulder inspection station. The angled shoulder inspection station 102 comprises an angled shoulder camera 120, a bottom light 121, a side light 122, and a vessel holder 123.

The bottom light 121 is configured and positioned such that the bottom light is below a vial 400 and the light shines upward, e.g. through the bottom of the vial and around all sides of the vial. In some embodiments, the bottom light 121 may be a direct backlight, e.g. a 63 mm×60 mm Direct Backlight, Blue LED, M12, or similar light. The use of blue light is optional but desirable because it enhances the color of plasma flake particles, such as may be present from one or more coatings on the sidewall of the vial. The side light 122 is positioned such that the side light is behind a vial 400 from the perspective of the camera 120 (i.e., the side light and the camera are on opposing sides of the vial) and the light shines through the sidewall of the vial and beyond the sides of the vial as viewed from the camera. In some embodiments, the side light 122 may be a direct backlight, e.g. an 83 mm×75 mm Direct Backlight, Blue LED, M12, or similar light. Again, the use of blue light is optional but desirable because it enhances the color of plasma flake particles, such as may be present from one or more coatings on the sidewall of the vial.

In the illustrated embodiment, the bottom light 121 and the side light 122 define the bottom and rear surfaces of the vessel compartment 125 within which a vial 400 is held. Here, the sides and front of the vessel compartment 125 are completely open. However, in other embodiments, one or both of the sides and/or the front may be partially or completely closed.

The angled shoulder camera 120 is positioned in front of and above the vial 400 and vessel compartment 125 and the lens is directed toward the vial and more generally the vessel compartment. More particularly, the angled shoulder camera 120 is positioned and directed at the vessel compartment 125 in such a manner as to capture images of the vial shoulder 404 that are free from shadows or other interference. The angled shoulder camera 120 is desirably an area scan camera. Preferably, the angled shoulder camera 120 is an area scan camera that captures at least a 60° arc of the vial shoulder, so that the entire vial shoulder 404 can inspected using six image captures. For instance, the angled shoulder camera 120 may be an area scan camera that capture at least a 65° arc of the vial shoulder 404, which provides overlap with adjacent arcs and thus ensures that the entirety of the shoulder is captured and inspected. For example, the angled shoulder camera 120 may be a Cognex In-Sight 9912M, 12.0MP, or similar camera. The angled shoulder camera 120 may also comprise a 50 mm Lens (as well as the associated lens spacer (20 mm) and bandpass filter).

The vessel holder 123 is configured to hold a vial 400 from above, without contacting the sidewall of the vial or otherwise interfering with sightlines around the sidewall of the vial. In the illustrated embodiment, for example, the vessel holder 123 interacts with the top of the neck flange 405a of the vial 400, e.g. by clamping, suction, or the like, such that the vial is suspended from the vessel holder within the vessel compartment 125. As such, the vessel holder 123 forms at least a partial top surface of the vessel compartment 125.

The vessel holder 123 is also configured to rotate the vial so that the full 360° of the shoulder 404 can be image captured and inspected. In some embodiments, the vessel holder 123 is configured to rotate continuously, which allows for a high throughput inspection process. For example, the vessel holder 123 may be configured to rotate at a speed of up to about 120 rpm. Continuous rotation, of course, requires that the camera 120 have the shutter open very briefly. For instance, the camera 120 may be selected and the lights 121, 122 configured and positioned such that the shutter remains open for less than one millisecond when capturing an image. In other embodiments, the vial 400 may be rotated discontinuously, i.e. the vial may be held steady for each image capture and rotated in between the image captures.

In the illustrated embodiment, the vessel holder 123 is movable relative to the camera 120 and lights 121, 122. In this manner, the vessel holder 123 may pick up a vial 400, e.g. from a transport line or a different inspection station, and position the vial within the vessel compartment 125 for inspection. In other embodiments, certain components such as the lights 121, 122 may instead be moved into place next to the vessel holder 123, e.g. the vessel holder may remove a vial 400 from a transport line and then the lights 121, 122 may be brought into position in the immediate vicinity (e.g. directly above) the transport line to form the vessel compartment 125 of the inspection station 102.

Although the inspection station 102 is described as oriented in the drawings, in other non-illustrated embodiments, the vessel compartment 125 may be flipped 180 degrees, such that the bottom light 121 forms the top of the vessel compartment and the vessel holder 123 forms at least a partial bottom of the vessel compartment. In such an embodiment, the angled shoulder camera 120 would of course be located in front of and below the vial 400 and more generally the vessel compartment 125. Indeed, so long as the relationships between the camera 120, the lights 121, 122, and the vial 400 that allow for accurate image capture are maintained, the components can be oriented in any desirable manner.

It is also contemplated that, in other non-illustrated embodiments, the side body inspection station 101 and the angled shoulder inspection station 102 may be combined, such that an angled shoulder camera 120 may capture images during the same rotation of the vial as the side body camera 110. This could be done by, for example, having the image captures of the two cameras 110, 120 offset in time from one another and varying the characteristics, e.g. intensity, of the light as may be needed between the light characteristics used for image capture by the side body camera and the light characteristics used for image capture by the angled shoulder camera. This could also be done by using one or more cameras having standard lenses for the side body inspection (or a camera having a telemetric lens for the angled shoulder camera, though this may be undesirable for other reasons).

To inspect the shoulder 404 of a vial, the vial 400 is picked up by the vessel holder 123 and positioned within the vessel compartment 125 of the shoulder inspection station 102. While the bottom light 121 and the side light 122 are illuminated, the vial 400 is rotated 360° about its longitudinal axis. During that rotation, the angled shoulder camera 120 captures a number of images, e.g. six images, of the shoulder portion 404 of the vial. Together the captured images show the entire 360° surface of the vial shoulder portion 404. The captured images are processed by the one or more system processors to identify (i) the presence of particles within the designated shoulder inspection area or areas and (ii) the size of any identified particles.

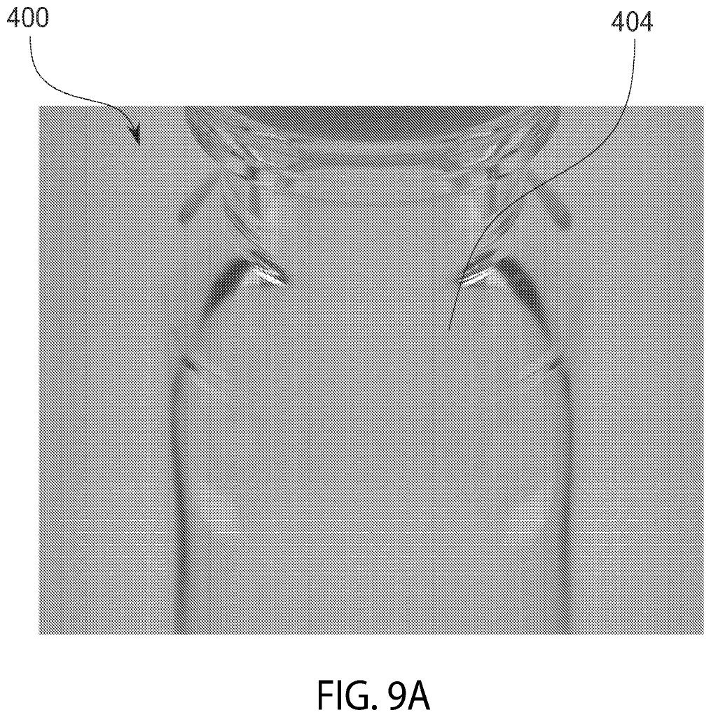

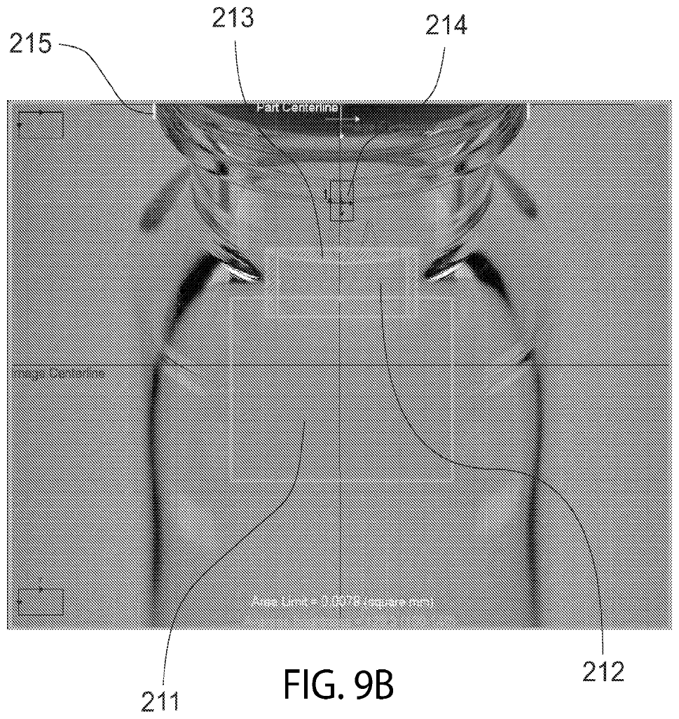

An example of an image capture taken by the angled shoulder camera 120 during this inspection process is shown in FIG. 9A. FIG. 9B shows the same image, as processed by the system. The processor identifies the independent inspection area or areas, an example of which are shown on FIG. 9B as boxes 211, 212 (minus the areas shown in cross-hatching 213). In order to ensure that the inspection areas 211, 212 are properly identified, the system may not rely solely on the center of the image (which would require that the vessel holder 123 position the vial 400 in perfect alignment with the center of the camera lens). Rather, as shown in FIG. 9B as box 214 and lines 215, the system may be configured to identify image elements that correspond with certain portions of the vial 400, such as the sides of the vial and more particularly the sides of the vial neck flange 405a in the captured image (e.g. as determined from lines 215) and/or the bottom of the vial neck flange 405a in the captured image (e.g. as shown in box 214). The system may then determine the precise placement of the inspection area or areas 211, 212 based on the location of those image elements.

As shown in FIG. 9B, the shoulder 404 of a vial may be divided into multiple inspection areas 211, 212 to account for shadowing effects or other interference. For instance, the box 212 shown in FIG. 9B has a smaller width than box 211 due to the shadows that are immediately adjacent the left and right sides of box 212. If necessary, the system may also be separately calibrated for each inspection area 211, 212 in order to account for surface features or the like.

In other embodiments of the vessel inspection system and method disclosed herein, e.g. where the system is configured to inspect a syringe barrel, the inspection area or areas defined by the one or more processors may differ. Additionally, minor modifications may be made to the system components to accommodate the differing geometry of the specific vessel/container being inspected. For instance, because the shoulder of a syringe barrel is located toward the front end and the opening to the lumen is located at the rear end, the vessel holder may hold the syringe barrel by the needle shield or tip cap, i.e. with the opening to the lumen being the lower, suspended end. Regardless of those distinctions, however, the inspection system and method of the present disclosure may be applied to any of a variety of containers, including syringe barrels (and cartridge barrels) and blood collection tubes.

### Top Inspection

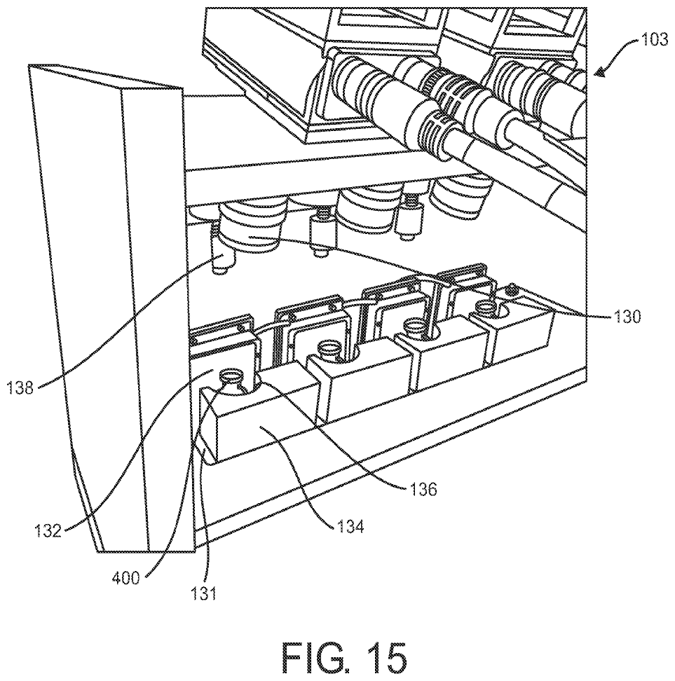

FIG. 15 shows a top inspection station 103, also known as an angled top inspection station. The angled top inspection station 103 comprises an angled top camera 130, a bottom light 131, a side light 132, a vessel holder 133, and a reflective wall 134.

The bottom light 131 is configured and positioned such that the bottom light is below a vial 400 and the light shines upward, e.g. through the bottom of the vial and around all sides of the vial. The bottom light 131 may be a direct backlight, e.g. a 63 mm×60 mm Direct Backlight, Blue LED, M12, or similar light. The use of blue light is optional but desirable because it enhances the color of plasma flake particles, such as may be present from one or more coatings on the sidewall of the vial. The side light 132 is positioned such that the side light is behind a vial 400 from the perspective of the camera 130 (i.e., the side light and the camera are on opposing sides of the vial) and the light shines through the sidewall of the vial and beyond the sides of the vial as viewed from the camera. The side light 132 may be a direct backlight, e.g. a 51 mm×51 mm Direct Backlight, Blue LED, M12, or similar light. Again, the use of blue light is optional but desirable because it enhances the color of plasma flake particles, such as may be present from one or more coatings on the sidewall of the vial.

In the illustrated embodiment, the bottom light 131 and the side light 132 define the bottom and rear surfaces of the vessel compartment 135 within which a vial 400 is held. The top inspection station 103 also comprises a reflective wall 134 positioned on an opposite side of the vessel holder 133 and vial 400 from the side light 132. The reflective wall 134 thus forms at least a partial front surface of the vessel compartment 135. As shown in FIG. 15, the reflective wall 134 may also comprise a concave surface 136 that is configured to extend at least partially around the vial 400. As such, the reflective wall 134 forms at least a partial left and right side surface of the vessel compartment 135. The reflective wall 134 reflects light that is illuminated from the side light 132 and the bottom light 131 and is configured to eliminate shadows from appearing on the top surface of the vials, i.e. the upper surface of the neck flange 405a, in the image captures.

The angled top camera 130 is positioned in front of and above the vial 400 and more generally the vessel compartment 135 and the lens is directed toward the vial and more generally the vessel compartment. More particularly, the angled top camera 130 is positioned and directed at the vessel compartment 135 in such a manner as to capture images of the vial top surface that are free from shadows or other interference. The angled top camera 130 is desirably an area scan camera. Preferably, the angled top camera 130 is an area scan camera that captures at least a 60° arc of the vial top surface, so that the entire vial top surface can inspected using six image captures. For instance, the angled top camera 130 may be an area scan camera that capture at least a 65° arc of the vial top surface (which provides overlap with adjacent arcs and thus ensures that the entirety of the top surface is captured and inspected). For example the angled top camera 130 may be a Cognex In-Sight 9912M, 12.0MP, or similar camera. The angled top camera 130 of this embodiment may also comprise a 50 mm Lens (as well as the associated lens spacer (20 mm) and bandpass filter).

The vessel holder 133 is configured to rotate the vial 400 so that the full 360° of the top can be image captured and inspected. In some embodiments, the vessel holder 133 is configured to rotate continuously, which allows for a high throughput inspection process. For example, the vessel holder 133 may be configured to rotate at a speed of up to about 120 rpm. Continuous rotation, of course, requires that the camera 130 have the shutter open very briefly. For instance, the camera 130 may be selected and the lights 131, 132 configured and positioned such that the shutter remains open for less than one millisecond when capturing an image. In other embodiments, the vial 400 may be rotated discontinuously, i.e. the vial may be held steady for each image capture and rotated in between the image captures.

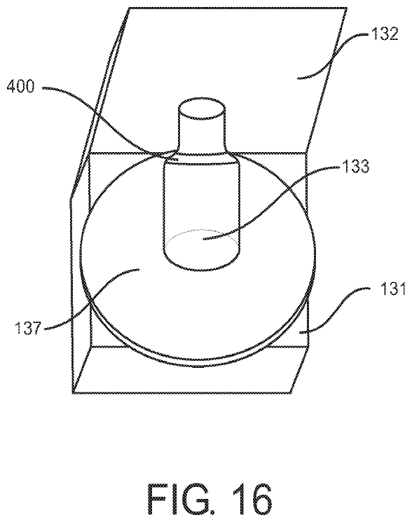

As shown in FIG. 16, the vessel holder 133 may comprise a rotatable platform 137 that supports the bottom surface, or base 401, of the vial. The rotatable platform 137 is preferably configured so that it does not interrupt or distort the bottom light 131. For instance, the rotatable platform 137 may be made of a material that fluoresces the bottom light 131 without significant distortion that would give rise to shadows or the like in the image captures. Alternatively, the rotatable vessel holder 133, e.g. platform 137, may itself comprise at least a portion of the bottom light 131. In some embodiments, for example, the bottom light 131 or a portion thereof may serve as the rotatable vessel holder 133.

In contrast to the side body and shoulder inspection stations 101, 102, the vessel holder 133 of the top surface inspection station 103 of the illustrated embodiment is not movable to transport the vial 400 into and out of the inspection station, though in other (non-illustrated) embodiments it may be. Rather, the top surface inspection station 103 may also comprise a vessel conveying element 138 that is configured to pick up a vial 400, e.g. from a transport line or a different inspection station, and position the vial within the vessel compartment 135 and more specifically on the vessel holder 133. Once the images have been obtained, the vessel conveying element 138 may then pick up the vial 400 and either return it to a transport line or convey it directly to a different inspection station.

Although the inspection station 103 is described as oriented in the drawings, in other non-illustrated embodiments, the vessel compartment 135 may be flipped 180 degrees, such that the bottom light 131 forms the top of the vessel compartment. In such an embodiment, the angled top camera 130 would of course be located in front of and below the vial 400 and more generally the vessel compartment 135. Indeed, so long as the relationships between the camera 130, the lights 131, 132, and the vial 400 that allow for accurate image capture are maintained, the components can be oriented in any desirable manner.

To inspect the top of a vial, the vial 400 is positioned upright on the vessel holder 133, i.e. with its base 401 resting on the vessel holder, and within the vessel compartment 135 of the top inspection station 103. While the bottom light 131 and the side light 132 are illuminated, the vial 400 is rotated 360° about its longitudinal axis, e.g. by operation of the rotatable vessel holder 133, e.g. platform 137. During that rotation, the angled top camera 130 captures a number of images, e.g. six images, of the top portion of the vial, i.e. the upper surface of the vial neck flange 405a. Together the captured images show the entire 360° surface of the top portion of the vial. The captured images are processed by the one or more system processors to identify (i) the presence of particles within the designated top surface inspection area or areas and (ii) the size of any identified particles.

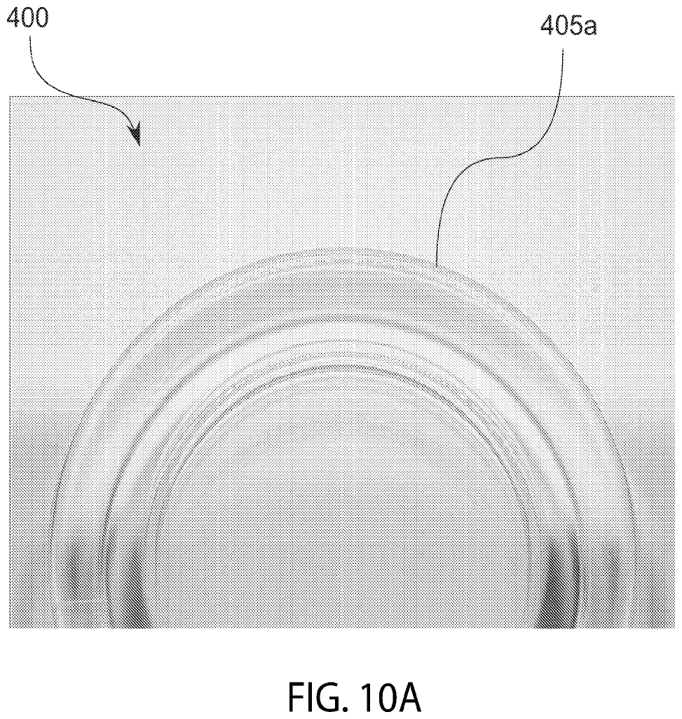

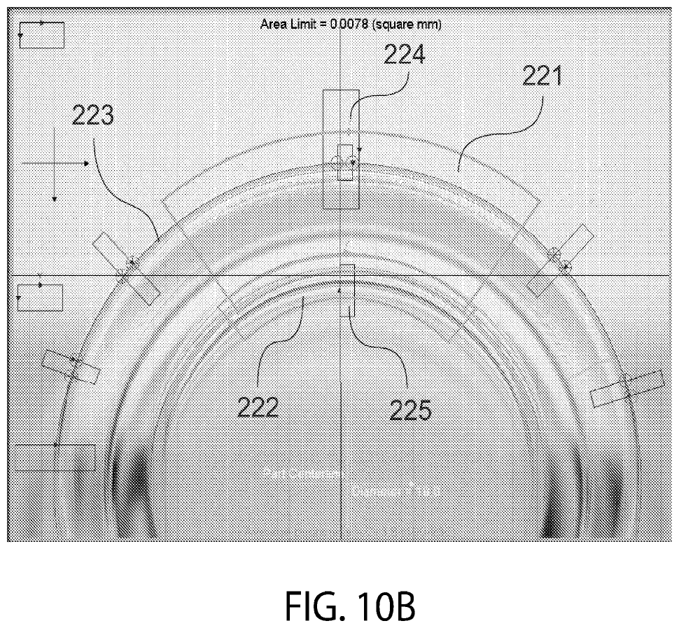

An example of an image capture taken by the angled top camera 130 during this inspection process is shown in FIG. 10A. FIG. 10B shows the same image, as processed by the system. The processor identifies the independent inspection area or areas, an example of which are shown on FIG. 10B as boxes 221, 222. In order to ensure that the inspection areas are properly identified, the system may not rely solely on the center of the image (which would require that the vessel holder 133 and/or the vessel transport element 138 position the vial 400 in perfect alignment with the center of the camera lens). Rather, as shown in FIG. 10B as lines 223 and/or boxes 224, 225, the system may be configured to identify image elements that correspond with certain portions of the vial, such as the outer edge of the vial, and more particularly the outer edge of the vial neck flange 405a, in the captured image (shown by line 223 and box 224) and/or a portion of the inner surface of the vial (e.g. a shadow line shown by box 225) in the captured image. The system may then determine the precise placement of the inspection area or areas 221, 222 based on the location of those image elements.

As shown in FIG. 10B, the top surface of a vial may be divided into multiple inspection areas 221, 222 to account for shadowing effects or other interference. For instance, the inspection area identified with box 222 shown in FIG. 10B may need to be separately calibrated from the inspection area identified with box 221 in order to account for surface features, shadows, or the like.

In other embodiments of the vessel inspection system and method disclosed herein, e.g. where the system is configured to inspect a syringe barrel or blood collection tube, the inspection area or areas defined by the one or more processors may differ. Additionally, minor modifications may be made to the system components to accommodate the differing geometry of the specific vessel/container being inspected (note that the rear end of a syringe barrel should be considered equivalent to the top of a vial for purposes of this inspection process, both defining an opening to the lumen and typically having a flange). Regardless of those distinctions, however, the inspection system and method of the present disclosure may be applied to any of a variety of containers, including syringe barrels (and cartridge barrels) and blood collection tubes.

### Bottom Transition Region Inspection

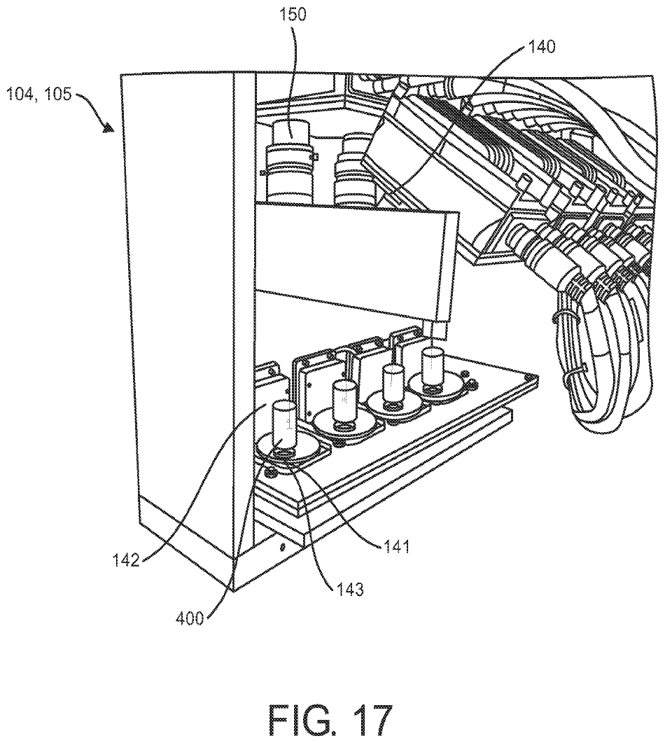

FIG. 17 shows a combined bottom transition region and bottom surface inspection station 104, 105. In other embodiments, however the bottom surface inspection station 105 may be separate from the bottom transition region inspection station 104. The combined bottom transition region and bottom surface inspection station 104,105 (or, if separate, the bottom transition region inspection station 104) comprises an angled bottom camera 140, a bottom light 141, a side light 412, and a vessel holder 143.

The bottom light 141 is configured and positioned such that the bottom light is below a vial 400 and the light shines upward, e.g. through the top of the vial (which is oriented upside down, with its top closer to the bottom light than its bottom) and around all sides of the vial. The bottom light 141 may be a direct backlight, e.g. a 63 mm×60 mm Direct Backlight, Blue LED, M12, or similar light. The use of blue light is optional but desirable because it enhances the color of plasma flake particles, such as may be present from one or more coatings on the sidewall and/or bottom wall of the vial. The side light 142 is positioned such that the side light is behind a vial 400 from the perspective of the camera 140 (i.e. the side light and the camera are on opposing sides of the vial) and the light shines through the sidewall of the vial and beyond the sides of the vial as viewed from the camera. The side light 142 may be a direct backlight, e.g. a 51 mm×51 mm Direct Backlight, Blue LED, M12, or similar light. Again, the use of blue light is optional but desirable because it enhances the color of plasma flake particles, such as may be present from one or more coatings on the sidewall and/or bottom wall of the vial.

In the illustrated embodiment, the bottom light 141 and the side light 142 define the bottom and rear surfaces of a vessel compartment 145 within which a vial 400 is held. Here, the sides and front of the vessel compartment 145 are completely open. However, in other embodiments, one or both of the sides and/or the front may be partially or completely closed.

The angled bottom camera 140 is positioned in front of and above the vial 400 and more generally the vessel compartment 145 and the lens is directed at the vial and more generally the vessel compartment. More particularly, the angled bottom camera 140 is positioned and directed at the vessel compartment 145 in such a manner as to capture images of the transition region 403 between the sidewall main body 402 and the bottom wall 401 of the vial that are free from shadows or other interference. The angled bottom camera 140 is desirably an area scan camera. Preferably, the angled bottom camera 140 is an area scan camera that captures at least a 60° arc of the transition region 403, so that the entire vial transition region can inspected using six image captures. For instance, the angled bottom camera 140 may be an area scan camera that captures at least a 65° arc of the transition region 403, which provides overlap with adjacent arcs and thus ensures that the entirety of the transition region is captured and inspected. For example, the angled bottom camera 140 may be a Cognex In-Sight 9912M, 12.0MP, or similar camera. The angled bottom camera 140 of this embodiment may also comprise a 50 mm Lens (as well as the associated lens spacer (20 mm) and bandpass filter).

The vessel holder 143 is configured to rotate the vial 400 so that the full 360° of the transition region 403 can be image captured and inspected. In some embodiments, the vessel holder 143 is configured to rotate continuously, which allows for a high throughput inspection process. For example, the vessel holder 143 may be configured to rotate at a speed of up to about 120 rpm. Continuous rotation, of course, requires that the camera 140 have the shutter open very briefly. For instance, the camera 140 may be selected and the lights 141, 142 configured and positioned such that the shutter remains open for less than one millisecond when capturing an image. In other embodiments, the vial 400 may be rotated discontinuously, i.e. the vial may be held steady for each image capture and rotated in between the image captures.

The vessel holder 143 may comprise a rotatable platform 147 that supports the top surface of the vial, e.g. the upper surface of the vial neck flange 405a (the vial being placed upside down on the vessel holder as shown in FIG. 13). The rotatable platform 147 is preferably configured so that it does not interrupt or distort the bottom light 141. For instance, the rotatable platform 147 may be made of a material that fluoresces the bottom light without significant distortion that would give rise to shadows or the like in the image captures. Alternatively, the rotatable platform 147 may itself comprise at least a portion of the bottom light 141. In some (nonillustrated) embodiments, for example, the bottom light 141 or a portion thereof may serve as the vessel holder 143, e.g. rotatable platform 147.

In contrast to the side body and shoulder inspection stations 101, 102, the vessel holder 143 in the illustrated embodiment of the angled bottom inspection station 104 is not movable to bring the vial 400 into and out of the inspection station, though in other (non-illustrated) embodiments it may be. Rather, the angled bottom surface inspection station 104 may also comprise a vessel conveying element 148 that is configured to pick up a vial 400, e.g. from a transport line or a different inspection station, and position the vial within the vessel compartment 145 and more specifically on the vessel holder 143. Once the images have been obtained, the vessel conveying element 148 may then pick up the vial 400 and either return it to a transport line or convey it directly to a different inspection station.

Although the inspection station 104 is described as oriented in the drawings, in other non-illustrated embodiments, the vessel compartment 145 may be flipped 180 degrees, such that the bottom light 141 forms the top of the vessel compartment. In such an embodiment, the angled bottom camera 140 would of course be located in front of and below the vial 400 and more generally the vessel compartment 145 and the vial would not be oriented upside-down. Indeed, so long as the relationships between the cameras 140, the lights 141, 142, and the vial 400 that allow for accurate image capture are maintained, the components can be oriented in any desirable manner.

To inspect the transition region 403 of a vial, the vial 400 is positioned on the vessel holder 143 and within the vessel compartment 145 of the angled bottom inspection station 104. While the bottom light 141 and the side light 142 are illuminated, the vial 400 is rotated 360° about its longitudinal axis, e.g. by operation of the rotatable vessel holder 143, e.g. platform 147. During that rotation, the angled bottom camera 140 captures a number of images, e.g. six images, of the transition region 403 of the vial. Together the captured images show the entire 360° surface of the transition region 403 of the vial. The captured images are processed by the one or more system processors to identify (i) the presence of particles within the designated transition region inspection area or areas and (ii) the size of any identified particles.

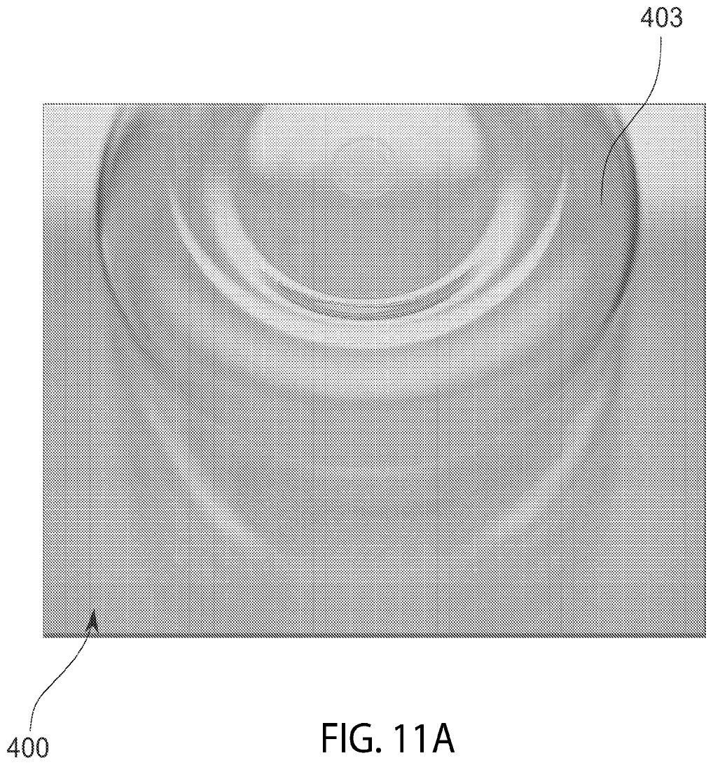

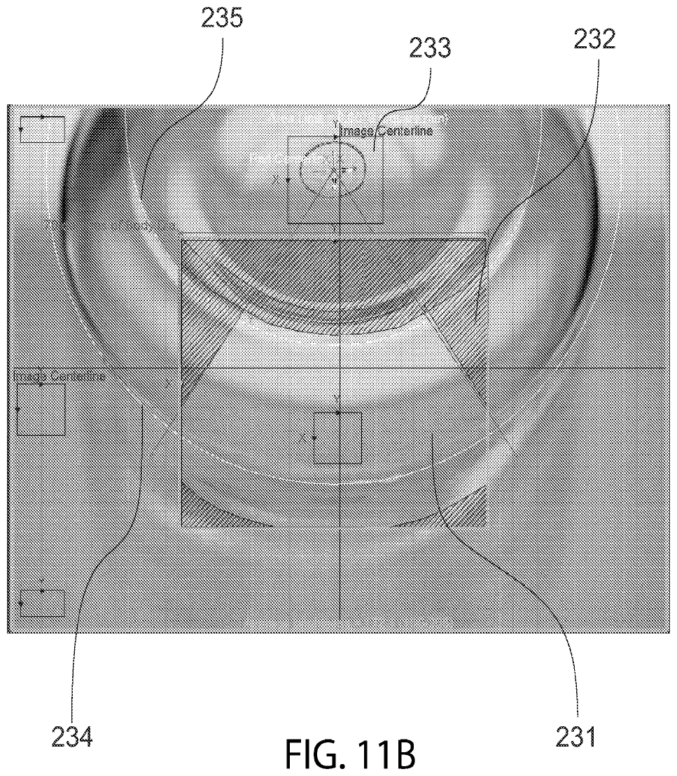

An example of an image capture taken by the angled bottom camera 140 during this inspection process is shown in FIG. 11A. FIG. 11B shows the same image, as processed by the system. The processor identifies the inspection area or areas, which in this instance for example is a single inspection area shown on FIG. 11B as box 231 (minus the portions shown in cross-hatching 232). In order to ensure that the inspection area or areas 231 are properly identified, the system may not rely solely on the center of the image (which would require that the vessel holder 143 and/or vessel transport element 148 position the vial 400 in perfect alignment with the center of the camera lens). Rather, as shown in FIG. 11B as box 233 and lines 234, 235, the system may be configured to identify image elements that correspond with certain portions of the vial, such as the side edge of the vial sidewall in the captured image (e.g. shown by line 234), the side edge of the vial base in the captured image (e.g. as shown by line 235), and/or the center of the base of the vial (e.g. as shown in box 233). The system may then determine the precise placement of the inspection area or areas 231 based on the location of those image elements.

In other, non-illustrated embodiments, the transition region 403 of a vial may be divided into multiple inspection areas to account for shadowing effects or other interference. If necessary, the system may also be separately calibrated for each inspection area in order to account for surface features or the like.

In other embodiments of the vessel inspection system and method disclosed herein, e.g. where the system is configured to inspect a blood collection tube, the inspection area or areas defined by the one or more processors may differ. Additionally, minor modifications may be made to the system components to accommodate the differing geometry of the specific vessel/container being inspected. Regardless of those distinctions, however, the inspection system and method of the present disclosure may be applied to any of a variety of containers, including syringe barrels (and cartridge barrels) and blood collection tubes.

### Bottom Surface Inspection

As noted above, FIG. 17 shows a combined bottom transition region station and bottom surface inspection station 104,105. In other embodiments, however the bottom surface inspection station 105 may be separate from the bottom transition region inspection station 104. The combined bottom transition region and bottom surface inspection station 104,105 (or, if separate, the bottom surface inspection station 105) comprises a bottom camera 150, a bottom light 141, optionally a side light 142, and a vessel holder 143.

The bottom light 141 is configured and positioned such that the bottom light is below a vial 400 and the light shines upward, e.g. through the top of the vial (which is placed upside down such that the top of the vial is closer to the bottom light than the base of the vial) and around all sides of the vial. The bottom light 141 may be a direct backlight, e.g. a 63 mm×60 mm Direct Backlight, Blue LED, M12, or similar light. The use of blue light is optional but desirable because it enhances the color of plasma flake particles, such as may be present from one or more coatings on the sidewall and/or bottom wall of the vial. The side light 142 is optional. Here, the side light 142 is a direct backlight, specifically a 51 mm×51 mm Direct Backlight, Blue LED, M12. Again, the use of blue light is optional but desirable because it enhances the color of plasma flake particles, such as may be present from one or more coatings on the sidewall and/or bottom wall of the vial.

In the illustrated embodiment, the bottom light 141 and optionally the side light 142 used during inspection of the vial bottom wall 401 define the bottom and rear surfaces of the vessel compartment 145 within which a vial is held. Here, the sides and front of the vessel compartment are completely open. However, in other embodiments, one or both of the sides and/or the front may be partially or completely closed. Alternatively, where the bottom surface inspection station 105 is independent from the bottom transition region inspection station 104, the side light 142 may be absent and all sides of the vessel compartment 145 may be open.

The bottom camera 150 is positioned above the vessel compartment 145 and the lens is directed at the vessel compartment. More particularly, the bottom camera 150 is positioned and directed at the vessel compartment in such a manner as to capture images of the bottom wall 401 of the vial that are free from shadows or other interference. Desirably, the bottom camera 150 is an area scan camera. For example, the bottom camera 150 may be a Cognex In-Sight 9912M, 12.0MP, or similar camera. The bottom camera 150 may also comprise a 50 mm Lens (as well as the associated lens spacer (15 mm) and bandpass filter). In contrast to the other cameras 110, 120, 130, 140 described herein, the bottom camera 150 may be able to capture the entire bottom wall 401 of the vial in a single image capture.

The bottom wall inspection station 105 may also comprise a vessel holder 143. For instance, where the bottom wall inspection station 105 is combined with the transition region inspection station 104, the bottom wall inspection station may comprise a rotatable vessel holder 143 as described above. In other embodiments in which the bottom wall inspection station 105 is independent from the transition region inspection station 104, the vessel holder 143 need not be rotatable (since the entire bottom wall may be captured in a single image capture and thus the vial need not be rotated). For instance, the vial 400 could be placed directly on the bottom light 141, which may serve as the vessel holder, or on a fixed (non-rotatable) platform that did not interfere with the bottom light.

In some embodiments, the bottom wall inspection station 105 also comprises a vessel transport element 148 that is configured to pick up a vial 400, e.g. from a transportation line or a different inspection station, and position the vial within the vessel compartment and, if present, on the vessel holder 143. Once the images have been obtained, the vessel conveying element 148 may then pick up the vial 400 and either return it to a transport line or convey it directly to a different inspection station.

Although the inspection station 105 is described as oriented in the drawings, in other non-illustrated embodiments, the vessel compartment 145 may be flipped 180 degrees, such that the bottom light 141 forms the top of the vessel compartment. In such an embodiment, the bottom camera 150 would of course be located below the vessel compartment 145 and the vial 400 would not be oriented upside-down. Indeed, so long as the relationships between the camera 150, the light 141, and the vial 400 that allow for accurate image capture are maintained, the components can be oriented in any desirable manner.

To inspect the bottom wall 401 of a vial, the vial 400 is positioned within the vessel compartment 145 and, if present, on the vessel holder 143 of the bottom wall inspection station 105. While the bottom light 141 and optionally the side light 142 are illuminated, the bottom camera 150 captures at least one image of the bottom wall 401 of the vial, which either alone (e.g., if one) or together (e.g., if more than one) show the entire bottom wall of the vial. The captured image or images are processed by the one or more system processors to identify (i) the presence of particles within the designated bottom wall inspection area or areas and (ii) the size of any identified particles.

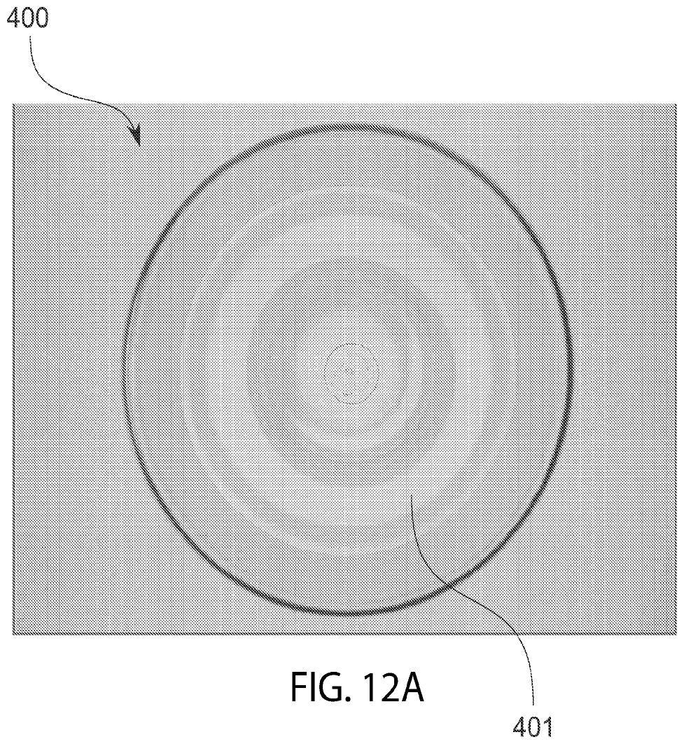

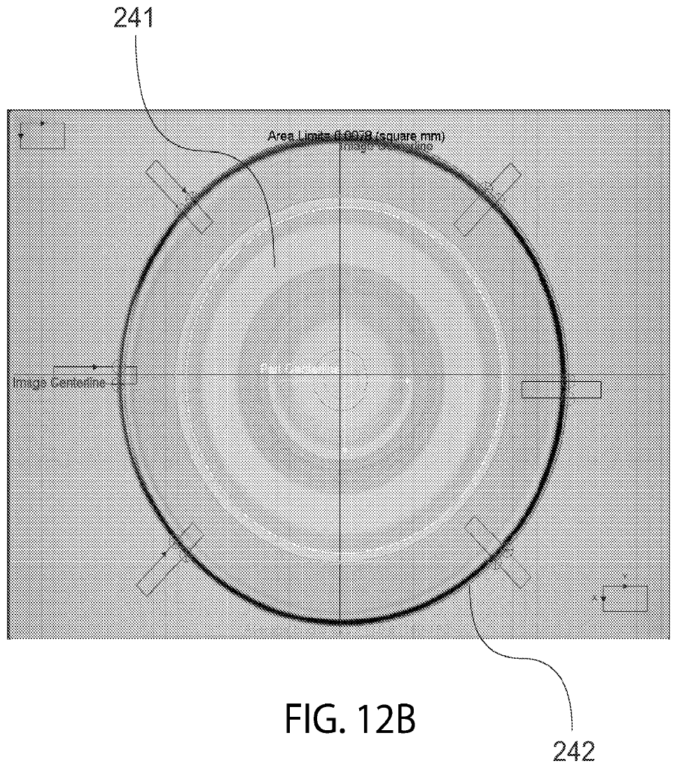

An example of an image capture taken by the bottom camera 150 during this inspection process is shown in FIG. 12A. FIG. 12B shows the same image, as processed by the system. The processor identifies the inspection area or areas, which in this instance is a single inspection area shown on FIG. 12B as circle 241. In order to ensure that the inspection area or areas are properly identified, the system may not rely solely on the center of the image (which would require that the vial 400 be positioned in perfect alignment with the center of the camera lens). Rather, as shown in FIG. 12B, the system may be configured to identify image elements that correspond with certain portions of the vial, such as the side edge of the vial in the captured image (shown by line 242) and/or the center of the bottom wall of the vial in the captured image. The system may then determine the precise placement of the inspection area or areas based on the location of those image elements.

In other, non-illustrated embodiments, the bottom wall 401 of a vial may be divided into multiple inspection areas to account for shadowing effects or other interference. If necessary, the system may also be separately calibrated for each inspection area in order to account for surface features or the like.

In other embodiments of the vessel inspection system and method disclosed herein, e.g. where the system is configured to inspect a blood collection tube, the inspection area or areas defined by the one or more processors may differ. Additionally, minor modifications may be made to the system components to accommodate the differing geometry of the specific vessel/container being inspected. Regardless of those distinctions, however, the inspection system and method of the present disclosure may be applied to any of a variety of containers, including syringe barrels (and cartridge barrels) and blood collection tubes.

With the exception of the bottom camera 150, which captured a single image of the bottom wall 401 of the vial while the vial 400 was static, each vial was rotated continuously and each camera 110, 120, 130, 140 captured images of the vial during rotation.

Although in all of the above embodiments it has been described that the vial (or other container) is rotated during the image capture process, it is also contemplated that in alternative embodiments the camera and/or side light may rotate around the vial in order to capture images across the full circumference of the vial. In other embodiments, a plurality of cameras may be present at different positions around the vessel compartment of a given inspection station and either (i) a plurality of side lights may be provided and illuminated at different times to provide each of the cameras with a desired light profile or (ii) one or more side lights may be rotated around the vial to provide each of the camera with a desired light profile.

Application of the one or more inspection areas to each image may be performed by one or more processors. Determining whether there are any particles or defects within the one or more inspection areas, the number of particles or defects within the one or more inspection areas, a size of any particles or defects that are identified, or any combination thereof, may also be performed by the one or more processors. For instance, one or more processors may be configured to receive the one or more images from each camera, apply one or more inspection areas to each image, and determine whether there are particles and/or defects in each of the one or more inspection areas.

In some embodiments, the one or more processors may be configured to determine whether, within each of the one or more inspection areas, there are any particles or defects 25 microns or greater, alternatively 30 microns or greater, alternatively 40 microns or greater, alternatively 50 microns or greater, alternatively 60 microns or greater, alternatively 70 microns or greater, alternatively between 25 and 500 microns, alternatively between 30 and 500 microns, alternatively between 40 and 500 microns, alternatively between 50 and 500 microns, alternatively between 60 and 500 microns, alternatively between 70 and 500 microns, alternatively between 80 and 500 microns, alternatively between 25 and 400 microns, alternatively between 30 and 400 microns, alternatively between 40 and 400 microns, alternatively between 50 and 400 microns, alternatively between 60 and 400 microns, alternatively between 70 and 400 microns, alternatively between 80 and 400 microns, alternatively between 25 and 300 microns, alternatively between 30 and 300 microns, alternatively between 40 and 300 microns, alternatively between 50 and 300 microns, alternatively between 60 and 300 microns, alternatively between 70 and 300 microns, alternatively between 80 and 300 microns.

The surface area of particles may be an important criterion that determines if a certain vessel meets the quality standards in terms of presence of particulates. In some embodiments, the one or more processors may be configured, e.g. equipped with image analysis tools, to determine, e.g. quantify, the surface area of an identified particle. The one or more processors may then compare the surface area of the identified particle against a threshold value. If the surface area of the identified particle exceeds the threshold value, then the vessel, e.g. vial, may be removed from a transport line. In some embodiments, the threshold particle surface area above which will necessitate rejection of the vessel, e.g. vial, may be 0.0019 mm².

In some embodiments, a vial (or other container) may be removed from a transport line if the vial is found to contain particles and/or defects within the one or more inspection areas. In other embodiments, a vial may be removed from a transport line if the vial is found to contain particles and/or defects which are determined to be above a threshold value (which may be zero particles or defects or zero particles or defects of a minimum size for example). For example, the threshold value may relate to the number of particles or defects, the threshold value may relate to the size of a particle or defect, or the threshold value may relate to a combination of the number of particles or defects and the size of each particle or defect. The one or more processors may be configured to determine whether-based on an analysis of the one or more images-a vial exceeds the threshold value for particles and/or defects.

In some embodiments, the one or more processors may be configured to determine whether a detected defect is a cosmetic defect or a critical defect. If a defect determined to be a critical defect, the vial may be removed from the transport line. Determining, by at least one processor, whether a defect is a cosmetic defect or a critical defect may comprise analyzing a shape of the defect, a depth of the defect, or a combination thereof.

In some embodiments, one or more of the inspection stations may compensate for changes in ambient lighting in one or more of the following. For instance one or more, and optionally each, of the side body camera, the angled shoulder camera, the angled top camera, the angled bottom camera, and the bottom camera may be configured to compensate for changes in ambient lighting. One way in which this may be done is for one or more, and optionally each, of the cameras to include a bandpass filter, such as a bandpass filter that only passes light having wavelengths required for the detection of particles and/or defects.

Further, in some embodiments, the intensity of the one or more back lights, the intensity of the one or more side lights, or both may be monitored to ensure that the intensity/intensities remains within a defined range. That monitoring may also be performed by the one or more processors. To ensure that each vial has proper lighting during inspection, the inspection may be halted if the intensity of the one or more back lights, the one or more side lights, or both fall outside of the defined range.

### Systems and Methods for Applying Coating Sets to Vessels

Another aspect of the invention is an improved method and system for producing vessels, e.g. RTU pharmaceutical containers such as vials, syringe (or cartridge) barrels, blood collection tubes, and the like, having a coating set made up of one or more coatings on their interior surfaces and which have reduced particles, e.g. are free or substantially free from particles. The one or more coatings can be applied in any of a variety of manners, including for instance plasma enhanced chemical vapor deposition (PECVD) and atomic layer deposition (ALD). For many of the embodiments described herein, at least one of the coatings is applied by PECVD. In some embodiments, for example, at least a gas barrier layer and pH protective layer may be applied by PECVD. In other embodiments, however, a gas barrier layer (e.g. of SiO₂, Al₂O₃, or a combination thereof) may be applied by atomic layer deposition and a pH protective layer may be applied by PECVD. Additional details regarding the deposition of a gas barrier layer to the inner surfaces of a pharmaceutical vessel by ALD can be found in PCT/US2021/038548, the entirety of which is incorporated by reference. Additional details regarding the deposition of one or more layers to the inner surfaces of a pharmaceutical vessel by PECVD can be found in PCT/US2021/045819, the entirety of which is incorporated by reference herein.

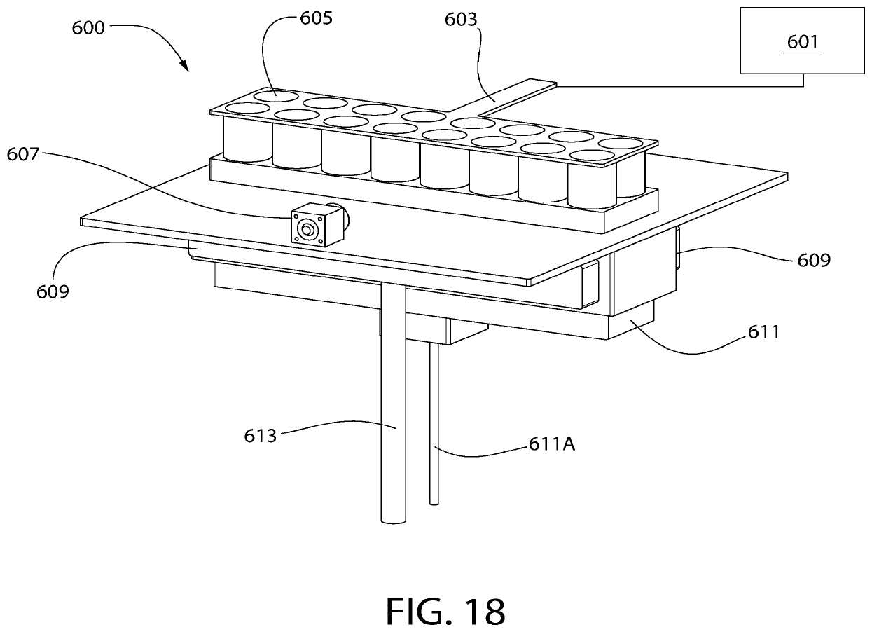

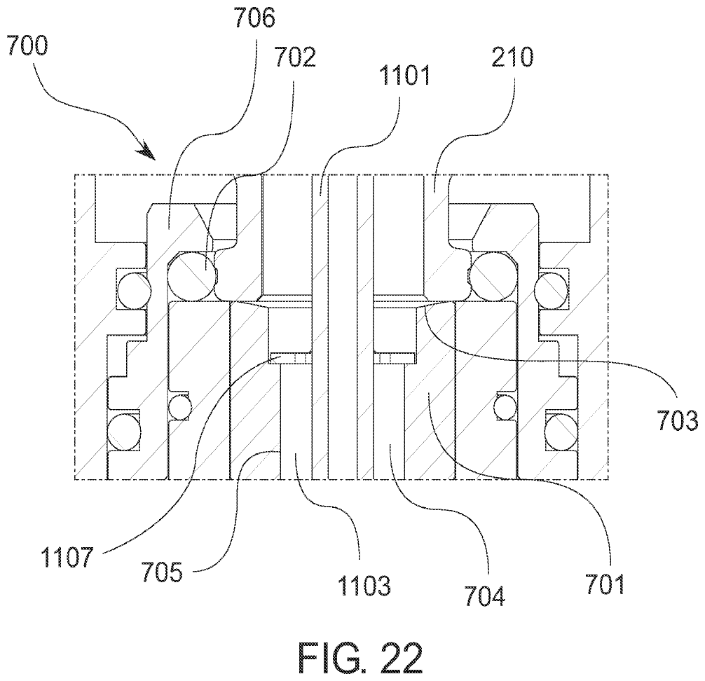

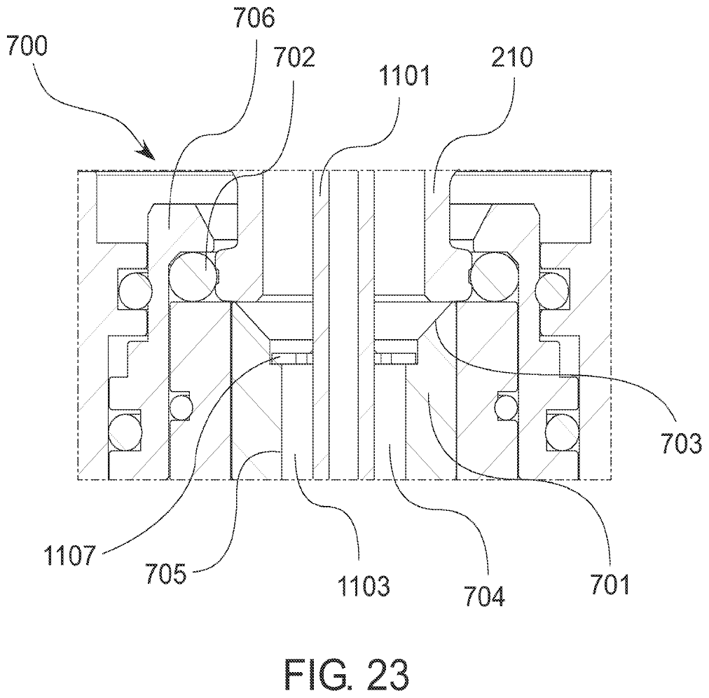

FIG. 18 illustrates a pulsed RF PECVD reactor, in accordance with an example embodiment of the disclosure. Referring to FIG. 18, there is shown pulsed RF PECVD reactor 600 comprising an RF power supply 601, electrode 603, vessel cavities 605, camera 607, exhaust manifolds 609, gas inlet manifold 611, and vacuum line 613. At the bottom of each vessel cavity 605 is a vessel holder 1105, 1107 against which an opening of the vessel is placed and through which precursor gas flows into the vessel (from the gas inlet manifold 611) and exhaust gas flows out of the vessel (to the exhaust manifold 609). The vessel holder will be described in more detail with reference to FIGS. 22-23.

The RF power supply 601 may comprise suitable circuitry for providing an RF signal at a desired power level, duty cycle, pulse duration, and frequency, for example, to the electrode 603. The RF power supply 601 may comprise a tunable matching impedance network for tuning its output impedance to match that of the electrode 603. The RF power supply 601 may provide RF voltages with 100 mV resolution for optimum control of the plasma. In addition, the generated RF signal may have a pulse high power of 250 W to 1000 W, although power may be increased to several kW depending on other parameters. The pulse low power may be 0 W and the power frequency may be 13.65 MHz, for example. The duty cycle may be varied between 1% and 99%, preferably between 50% and 99%. The pulse train frequency may range from 250 Hz to 5000 Hz, which may be extended to 10000 Hz. Although the coating system described herein utilizes pulsed RF power, in other embodiments a different power supply may be utilized. In other words, the power supply need not be an RF power supply but rather may be a different power supply, e.g. a microwave power supply.

The electrode 603 may comprise a metal component for communicating the signal from the power supply to the individual PECVD chambers defined by the vessel cavities 605 and the vessels themselves. The electrode 603 comprises a plurality of orifices in the top surface within which the vessels to be coated are placed into individual vessel cavities 605.

The vessel cavities 605 comprise a portion of the electrode 603 within which the portions of the vessels to be coated are placed and each of which substantially surrounds the vessel wall. The potential between the electrode 603 and a ground plane (not shown) is configured to generate a plasma with the input gas provided by the gas inlet manifold 611. In this example, there are sixteen vessel cavities 605, with two rows of eight, although the disclosure is not so limited.

In some embodiments, the vessel cavities 605 may have “window” openings in the walls of the electrode 603 that define the vessel cavities, enabling a camera 607 to have a view of the plasma generated by the applied RF signal in each vessel.

The camera 607 may comprise, for example, CCD or CMOS imaging sensors for monitoring the deposition. The camera 607 may be utilized to monitor plasma intensity, uniformity, and/or color, for example, to ensure the plasma conditions have been correctly configured for deposition and/or maintained during the deposition of the coating. In some embodiments, such as that illustrated in FIG. 18, more than one camera may be needed to monitor the deposition of all, e.g. sixteen, chambers. In that illustrated embodiment, for example, a camera 607 may be placed on each side of the electrode 603. In other embodiments, the vessel cavities 605 may be arranged and configured so that a single camera 607 may be utilized to monitor the plasma in all of the vessels being coated. By staggering the vessel cavities 605 in a first row with the vessel cavities in a second row, each cavity may comprise a single window, with all of the windows facing in the same direction. Accordingly, one or more cameras 607, and preferably one, may be placed on a single side of the electrode 603 and used to monitor the plasma conditions within the vessels contained in both rows of cavities during the PECVD coating process.

In one embodiment the camera 607 may capture and interrogate images of the plasma in the visible light range. In another embodiment the camera 607 may capture and interrogate images of the plasma in the infrared range. In another embodiment the camera 607 may capture and interrogate images of the plasma in the ultraviolet (UV) range. Light within any one or more of these wavelength ranges may be captured and interrogated to assess the quality of the plasma process.

The interrogation of the captured images may be performed by a processor that is operably linked with the camera 607 and which is optionally further operably linked with a display and/or user interface. If, by interrogation of an image captured by the camera 607, it is determined that the plasma within one or more vessels is not within a predefined acceptable range of one or more properties, e.g. intensity, uniformity, or color, then an operator may be alerted, one or more of the PECVD variables (e.g. gas flowrates, vacuum level, RF power level, pulsing rate, etc.) may be adjusted, and/or the process may be stopped for system maintenance. The vessel(s) for which the plasma was deemed unacceptable may be discarded.

The exhaust manifolds 609 comprise a network of gas flow lines that enable the combining of multiple exhaust outputs down to one, enabling a single vacuum system/pump to evacuate a plurality of chambers equally, thus providing a uniform and consistently reproducible vacuum within each of the plurality of vessel lumens. In this example, each of the two sides of the exhaust manifold 609 combines the output from eight vessel lumens into one output line, with each output line coupled together at the vacuum line 613.

The vacuum line 613 may provide vacuum to the vessel cavities via the exhaust manifold 609, and the vacuum may be enabled by one or more pumps (not illustrated). By providing the same pressure at each vessel, the vessel-to-vessel uniformity in a deposition process may be ensured.

The gas inlet manifold 611 comprises a network of gas flow lines that enable the splitting of a single input gas line into multiple input lines for supplying gas to the vessels to be coated, enabling a single input port 611A to provide gas to each vessel equally, thus providing a uniform and consistently reproducible flow of precursor gas in each of the plurality of vessel lumens. In this example, the gas inlet manifold splits the output of gas input port 611A equally between sixteen vessels.

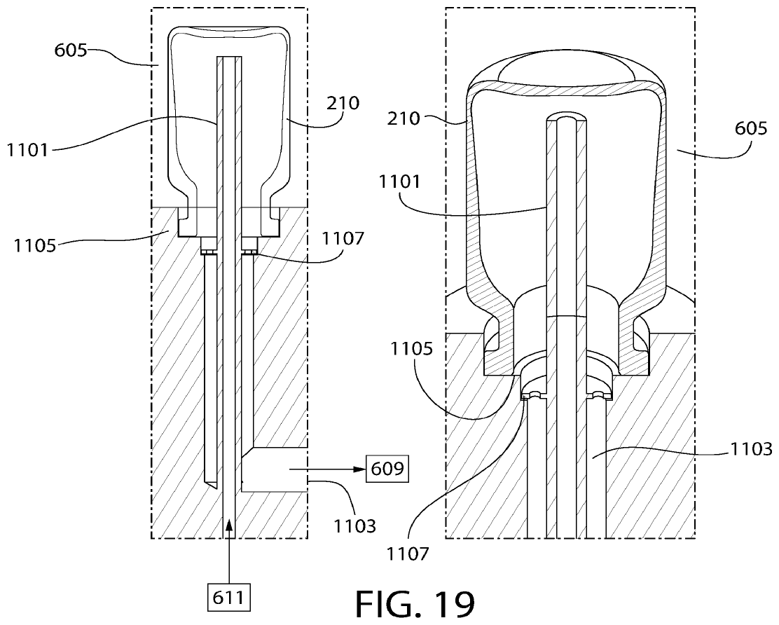

FIG. 19 illustrates a pulsed RF PECVD vessel deposition arrangement, in accordance with an example embodiment of the disclosure. Referring to FIG. 19 there is shown a cross-sectional view and a zoomed-in cross-sectional view of vessel 210, here a vial, placed within a vessel cavity 605 with the opening of the vessel 210 oriented downward in vessel holder 1105. In this example, there is also shown a gas delivery probe 1101 for supplying one or more precursor gases into the vessel 210 during the pulsed PECVD deposition process. In addition, the gas delivery probe 1101 may act as an inner electrode (e.g. may comprise metal and may be grounded), so that with the electrode 603 providing an RF signal, an electric field is generated thereby igniting a plasma within the vessel 210 during the deposition process.

FIG. 19 also shows a plasma screen 1107, that extends across the opening of the vacuum port 1103 and which ensures that the plasma is confined above the screen 1107 and in the vessel 210. In any embodiment, the plasma screen 1107 may take any of a variety of forms. In some embodiments, for instance, the plasma screen 1107 may comprise a perforated grate, e.g. a perforated metal disc or plate, as shown in the illustrated embodiments. In other embodiments, the plasma screen 1107 may comprise a metal mesh.

During the pulsed plasma PECVD coating process, one or more precursor gases flow from the gas inlet manifold 611 into the gas delivery probe 1101 and into the vessel 210 where a plasma may be generated by the pulsed RF signal, thereby causing deposition of the desired coating on the inner surfaces of the vessel 210 walls. The desired level of vacuum is maintained by flow of gas through the vacuum port 1103 to the exhaust manifold 609 described previously. Because the outlet of the gas delivery probe 1101 is positioned near the end of the vessel opposite the opening through which the vacuum is pulled, the precursor gases flow along the length of the vessel to provide a substantially uniform gas distribution and the coating can be applied substantially uniformly along the wall of the vessel.

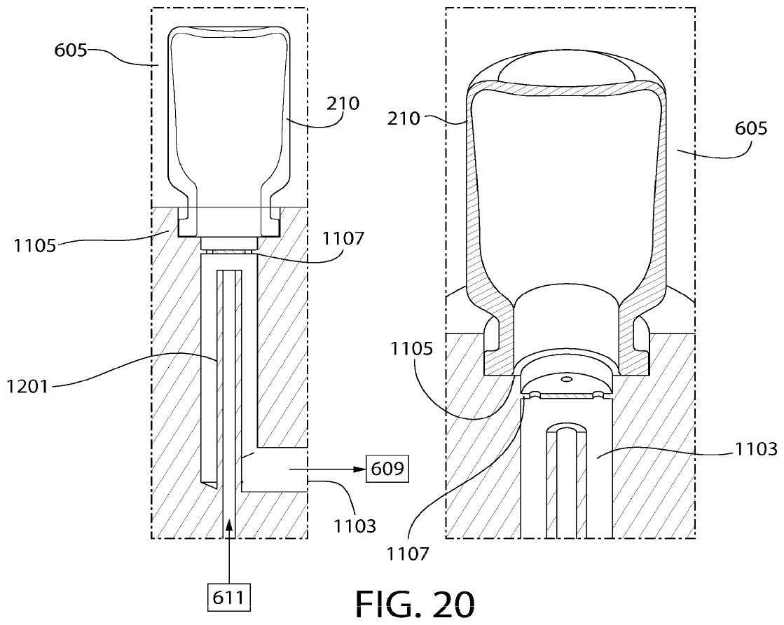

While the gas delivery probe 1101 may provide uniform gas distribution within the vessel 210, in other embodiments, pulsing the RF field that generates the plasma may allow for the removal of probe 1101, as the pulsing (as well as the precursor gas flow) may be controlled to provide enough time between pulses for the precursor gas to distribute in the vessel before each pulse. An example of such an embodiment is illustrated in FIG. 20.

FIG. 20 illustrates a pulsed RF PECVD vessel coating system without a gas delivery probe, in accordance with an example embodiment of the disclosure. Referring to FIG. 20, there is shown a cross-sectional view and a zoomed-in cross-sectional view of vessel 210, here a vial, placed within a vessel cavity 605, similar to that of FIG. 19, but without a gas delivery probe within the vessel 210. In this example, a precursor gas inlet line 1201 is present but does not extend into the lumen of the vessel 210. Instead, the gas inlet line 1201 is separated from the lumen of the vessel by a plasma screen 1107 that extends across the opening of the gas inlet line and which ensures that the plasma is confined above the screen 1107 and in the vessel 210.

As with the arrangement shown in FIG. 19, the opening of the vessel 210 is oriented downward in vessel holder 1105. In this example, with the electrode 603 providing an RF signal, an electric field is generated between the electrode 603 and the plasma screen 1107, which may act as an “inner” (though in this instance, not inside the vessel) electrode (e.g. it may comprise metal and may be grounded), thereby igniting a plasma within the vessel 210 during the deposition process. In the illustrated embodiment, the plasma screen 1107 extends across both the outlet of the gas inlet line 1201 and the inlet of the vacuum port 1103. However, in other embodiments, a first plasma screen 1107 may be associated with the gas inlet line 1201 and a second plasma screen 1107 may be associated with the vacuum port 1103.

FIG. 22 illustrates a detailed view of a first embodiment of a vessel holder 1105 as described above. Though the illustrated embodiment is sized and configured for the coating of a syringe barrel, the same components and arrangement of components is used for the coating of any vessel, including for instance a vial (though the sizes of the components may of course be different).

The vessel holder 1105, which is positioned at the bottom of a vessel cavity 605 of the electrode 603, comprises a sealing unit 700 which is configured to form a seal with the vessel 210, and more particularly with a portion of the vessel surrounding the opening to the lumen. This seal is important because it allows for the evacuation of the lumen and ensures that ambient air does not enter the lumen of the vessel during the coating process. The sealing unit comprises a puck 701 and a flexible seal 702.

The puck 701 has an upper surface 703 against with a portion of a vessel that surrounds an opening to the lumen comes into contact when the vessel is positioned within the cavity 605. The portion of the vessel that surrounds an opening to the lumen is an end surface of the vessel, e.g. an upper surface of a vial, a rear surface of a syringe barrel, etc. In some embodiments, such as that illustrated, the vessel 210 may have a flange, e.g. at the upper end of a vial, at the rear end of a syringe barrel, etc., and the end surface may be an end surface of the flange.

The puck 701 also has a central aperture 704 defined by an inner wall 705. The vacuum port 1103 through which the lumen of the vessel is evacuated passes through the central aperture 704. Similarly, as illustrated, the source gas inlet probe 1101 may pass through the central aperture 704. In alternate embodiments where the source gas inlet probe 1101 is excluded, such as that shown in FIG. 12, the precursor gas inlet line 1201 may extend into, but not through, the central aperture 704. Finally, the plasma screen 1107 may be positioned within the central aperture 704 of the puck 701. For instance, the puck 701 may comprise a smaller thickness portion near an upper end, thereby providing the inner wall 705 with a ledge upon which the plasma screen 1107 may be supported.

The puck 701 may be made out of any heat-resistant, non-conductive material, including for example ceramic materials or thermoplastics materials. In addition to ceramic materials, polyether ether ketone (PEEK) has been found to be a desirable material for the puck 701.

The sealing unit 700 also comprises a flexible seal 702. The flexible seal 702 is positioned vertically above the puck 701 and is configured to contact a portion of the vessel sidewall when a vessel is positioned within the electrode cavity 605. In some embodiments, such as that illustrated, the portion of the vessel sidewall may be flange and more particularly an outer surface of a flange. The seal is configured and position so that as a vessel 210 is inserted into the cavity 605 and into contact with the puck 701, the portion of the sidewall, e.g. outer surface of the flange, that contacts the flexible seal 702 will apply pressure against the flexible seal, creating a gas-tight or substantially gas-tight seal (meaning that if any gas does pass through the seal, it is not enough to have a measurable effect on the coating process conditions or the resulting one or more coatings) between the vessel sidewall and the sealing unit 700. As shown in the illustrated embodiment, the flexible seal 702 may be an o-ring, such as a silicone or elastomeric polymer o-ring.

The vessel holder 1105 may also comprise a housing 706 which at least partially encloses the sealing unit 700, i.e. the puck 701 and the flexible seal 702, and prevents undesired movement of the components and in particular the flexible seal. The vessel holder 1105 may also comprise an intermediate element 707 between the puck 701 and the housing 705. As shown in the illustrated embodiment, the intermediate element 707 and the housing 706 may form a recess that holds the flexible seal 702. In other (non-illustrated) embodiments, the puck 701 may have an increased thickness such that it takes the place of the intermediate element 707.

FIG. 23 illustrates a detailed view of a second embodiment of a vessel holder 1105 as described above. Again, though the illustrated embodiment is sized and configured for the coating of a syringe barrel, the same components and arrangement of components is used for the coating of any vessel, including for instance a vial (though the sizes of the components may of course be different). This embodiment is similar to the first embodiment described above, but unlike the first embodiment, the second embodiment includes a puck 701 that is configured to prevent accumulated particles from contacting the vessel and/or to enable more effective cleaning of the vessel-contacting areas of the sealing unit 700.

It has been observed that during the application of one or more coatings to the inner surfaces of the vessel, the one or more coatings are also deposited on the source gas inlet probe 1101. Over time, the coating deposited on the source gas inlet probe 1101 flakes off and accumulates on the vessel holder 1105, including the surfaces of the sealing unit 700 with which the vessels 210 come into contact, i.e. the upper surface 703 of the puck 701 and the flexible seal 702. Similarly, in embodiments in which the source gas inlet probe 1101 is excluded, such as that shown in FIG. 20, it is contemplated that flakes of coating may similarly end up on the vessel holder 1105, including the surfaces of the sealing unit 700 that contact the vessels 210, or that the coating may deposit on those portions of the vessel holder 1105. Flakes of coating and other particles present on the surfaces of the sealing unit 700 that contact the vessels 210 may become embedded on a vessel during a coating process, e.g. a subsequent coating process, leading to a vessel having potentially critical defects that prevent it from being used.

As shown in FIG. 23, the puck 701 comprises an upper surface 703 at least a portion of which is inclined from the inner wall 705 (and the central aperture 704) at an angle greater than 10 degrees, alternatively greater than 15 degrees, alternatively greater than 20 degrees, alternatively greater than 25 degrees, alternatively greater than 30 degrees, alternatively greater than 35 degrees, alternatively greater than 40 degrees, alternatively 45 degrees or greater. In contrast, the corresponding portion of the upper surface 703 of the puck 701 of the embodiment shown in FIG. 22 has an incline of only about 10 degrees.

By providing a portion of the upper surface 703 with an increased angle of incline, the puck 701 is configured to reduce the surface area that comes into contact with a vessel 210. The increased angle of incline of the portion of the upper surface 703 may also direct flakes or other particles toward the central aperture and away from the vessel-contacting surface. Accordingly, particles that fall to the puck 701 accumulate on surfaces that do not come into contact with the vessel and thus are less likely to become embedded in a vessel 210 during a coating process.

By providing a portion of the upper surface 703 with an increased angle of incline, the puck 701 may also facilitate a more effective cleaning of the sealing unit 700, e.g. using a method such as that described elsewhere herein. In particular, the increased angle of incline of at least a portion of the upper surface 703 may creates a stronger flow profile, e.g. vacuum flow, in the vicinity of the flexible seal 702 during a cleaning process. The increased angle of incline may also direct the particles toward the center of the puck 701 which may be subjected to the strongest flow profile, e.g. vacuum flow, during a cleaning process.

The following is an example process for coating a vessel using the above-described system, and in particular an example process for providing the inner surface of a vessel with a trilayer coating.

A vessel 210 is provided including a wall 214 consisting essentially of thermoplastic polymeric material defining a lumen 212. Optionally in any embodiment, the wall includes a polyester, polyethylene terephthalate (PET), polyethylene naphthalate (PEN); a polyolefm, cyclic block copolymer (CBC), cyclic olefin polymer (COP), cyclic olefin copolymer (COC), polypropylene (PP), or a polycarbonate, preferably COP, COC, or CBC. Optionally in any embodiment, the vessel lumen has a capacity of from 2 to 12 mL, optionally from 3 to 5 mL, optionally from 8 to 10 mL. The wall 214 has an inside surface 303 facing the lumen and an outside surface 305.

The vessel is placed into one of the cavities 605 in the electrode 603, with the opening to the vessel lumen oriented downward and a portion of the sidewall of the vessel, e.g. an outer surface of a flange, in sealing contact with flexible seal 702.

A partial vacuum is drawn in the lumen. In some embodiments, for example, the partial vacuum may be between about 20 and about 60 mTorr, alternatively between about 30 and about 50 mTorr.

While maintaining the partial vacuum unbroken in the lumen, a tie coating or layer 289 of SiOₓC_{y} is optionally applied by a pulsed PECVD tie layer coating step comprising applying sufficient pulsed RF power (alternatively the same concept is referred to in this specification as “energy”) to generate plasma within the lumen while feeding a precursor gas comprising a siloxane precursor, preferably a linear siloxane precursor, optionally oxygen, and optionally an inert gas diluent to stabilize the plasma. In some embodiments, the precursor gas may be introduced and the ratio of gas components stabilized before ignition of the plasma. Then, while maintaining the partial vacuum unbroken in the lumen, the plasma may be extinguished, which has the effect of stopping application of the tie coating or layer of SiOxCy.

The tie coating or layer, if present, can comprise SiOxCy or Si(NH) xCy. In either formulation, x is from about 0.5 to about 2.4 and y is from about 0.6 to about 3. The tie coating or layer has an interior surface facing the lumen and an outer surface facing the wall interior surface.

After the plasma used in the tie PECVD coating process is extinguished and before the barrier PECVD coating process is commenced, the feed of the gas employed in the tie PECVD coating process can be stopped and replaced, or simply changed, to a gas feed that is more suitable for depositing the barrier coating or layer, for example by increasing the ratio of oxygen to siloxane precursor, and optionally reducing or eliminating the inert gas (e.g. argon) from the gas feed.

While still maintaining the partial vacuum unbroken in the lumen, the barrier coating or layer 288 is applied by a pulsed PECVD barrier coating step comprising applying sufficient pulsed RF power to generate plasma within the lumen while feeding a precursor gas comprising a siloxane, preferably a linear siloxane, and oxygen. In some embodiments, the precursor gas may be introduced and the ratio of gas components stabilized before ignition of the plasma. After applying the barrier coating or layer, while maintaining the partial vacuum unbroken in the lumen, the plasma may be extinguished, which has the effect of stopping application of the barrier coating or layer. A barrier coating or layer of SiOₓ, wherein x is from 1.5 to 2.9 as determined by XPS is produced between the tie coating or layer and the lumen as a result of the barrier coating step. The barrier layer can be from 2 to 1000 nm thick. It can have an interior surface facing the lumen and an outer surface facing the interior surface of the tie coating or layer. The barrier coating or layer is effective to reduce the ingress of atmospheric gas into the lumen compared to a vessel without a barrier coating or layer.

After the plasma used in the barrier PECVD coating process is extinguished and before the pH protective PECVD coating process is commenced, the feed of the gas employed in the barrier PECVD coating process can be stopped and replaced, or simply changed, to a gas feed that is more suitable for depositing the pH protective coating or layer, for example by decreasing the ratio of oxygen to siloxane precursor, and optionally increasing or introducing the inert gas (e.g. argon) to the gas feed.

Then while maintaining the partial vacuum unbroken in the lumen, the pH protective coating or layer 286 of SiOxCy may be applied by a pulsed RF PECVD pH protective coating step. The pH protective coating or layer is applied between the barrier coating or layer and the lumen. The pH protective PECVD step comprises applying sufficient pulsed RF power to generate plasma within the lumen while feeding a precursor gas comprising a siloxane precursor, preferably a linear siloxane precursor, optionally oxygen, and optionally an inert gas diluent to stabilize the plasma. In some embodiments, the precursor gas may be introduced and the ratio of gas components stabilized before ignition of the plasma.

The pH protective coating or layer can comprise SiOxCy or Si(NH)xCy, where x is from about 0.5 to about 2.4 and y is from about 0.6 to about 3. The pH protective coating or layer can have an interior surface facing the lumen and an outer surface facing the interior surface of the barrier coating or layer. Barrier layers or coatings of SiOx are eroded or dissolved by some fluids, for example aqueous compositions having a pH above about 5. Since coatings applied by chemical vapor deposition can be very thin-tens to hundreds of nanometers thick-even a relatively slow rate of erosion can remove or reduce the effectiveness of the barrier layer in less time than the desired shelf life of a product package. This is particularly a problem for fluid pharmaceutical compositions, since many of them have a pH of roughly 7, or more broadly in the range of 5 to 9, similar to the pH of blood and other human or animal fluids. The higher the pH of the pharmaceutical preparation, the more quickly it erodes or dissolves the SiOx coating. Certain pH protective coatings or layers of SiOxCy or Si(NH)ₓC_{y} formed from polysiloxane precursors, which pH protective coatings or layers have a substantial organic component, do not erode quickly when exposed to fluids, and in fact erode or dissolve more slowly when the fluids have higher pHs within the range of 5 to 9. These pH protective coatings or layers of SiOxCy or Si(NH) xCy can therefore be used to cover a barrier layer of SiOx, retaining the benefits of the barrier layer by protecting it from the fluid in the pharmaceutical package. The protective layer is applied over the SiOx layer to protect the SiOx layer from contents stored in a vessel, where the contents otherwise would be in contact with the SiOx layer. The pH protective coating or layer may thus be effective to isolate the fluid from the barrier coating or layer, at least for sufficient time to allow the barrier coating to act as a barrier during the shelf life of the pharmaceutical package or other vessel.

If the pH protective coating layer is the final layer, then the vacuum may be broken and the coated vessel removed. If, on the other hand, another layer such as a lubricity layer is to be applied, while maintaining the partial vacuum unbroken in the lumen, the lubricity coating or layer of SiOₓC_{y} may be applied by a pulsed RF PECVD lubricity coating step. The lubricity PECVD step comprises applying sufficient pulsed RF power to generate plasma within the lumen while feeding a precursor gas comprising a siloxane precursor, preferably a linear siloxane precursor, optionally oxygen, and optionally an inert gas diluent. After applying the lubricity coating, while maintaining the partial vacuum unbroken in the lumen, the plasma may be extinguished, which has the effect of stopping application of the lubricity coating or layer.

Optionally in any embodiment, each linear siloxane precursor used to deposit the optional tie coating or layer, the barrier coating or layer, and the optional the pH protective coating or layer, can be hexamethylenedisiloxane (HMDSO) or tetramethylenedisiloxane (TMDSO), preferably HMDSO. Optionally in any embodiment, the same linear siloxane precursor is used in each coating process, which can be, for example the tie PECVD coating process, the barrier PECVD coating process, and the pH protective PECVD coating process. Using the same siloxane allows for the use of the same coating equipment without the need for valving arrangements to feed a different siloxane, and increases the throughput of the coating process (by eliminating time needed to switch between gases). Optionally in any embodiment, the technology can be further generalized to the use of any plasma enhanced chemical vapor deposition process using any precursors to generate any number of coatings, employing a process as described herein.

Optionally in any embodiment, at least 12 vessels, alternatively at least 16 vessels, may be coated simultaneously (e.g., in a 12-Up coater, a 16-Up coater, a 24-Up coater, a 32-Up coater, or the like) using the same RF power source, the same vacuum source, the same precursor gas source(s), or any combination thereof. Optionally, during each coating step, the precursor gas may be equally distributed to all of the vessels by a gas manifold. Optionally, during each coating step, the vacuum may be equally distributed to all of the vessels by a vacuum manifold.

### Cleaning of the Sealing Unit

As noted previously, during repeated coating cycles, various parts of the system 600, including for instance the source gas inlet probe 1101 and the sealing unit 700, may accumulate flakes of coating or other particles. Accordingly, after a certain number of coating cycles, the source gas inlet proble 1101 and puck 701 may be removed, cleaned, and replaced. This, of course, requires the coating equipment to be out of service for a period of time. One aspect of the present disclosure is a system and method for cleaning the source gas inlet proble 1101 and/or the sealing unit 700, in which the cleaning may be a step of a coating process, e.g. the cleaning may be performed in between the coating of individual (or a defined number of) vessels without the need to shut down the coating system 600 or otherwise interrupt a coating operation. In some embodiments, the source gas inlet probe 1101 and/or the sealing unit 700 of a one or more of the cavities 605, and desirably a plurality of source gas inlet probles and/or sealing units in a plurality of cavities, can be cleaned using automated equipment controlled by one or more processors as part of a coating cycle.

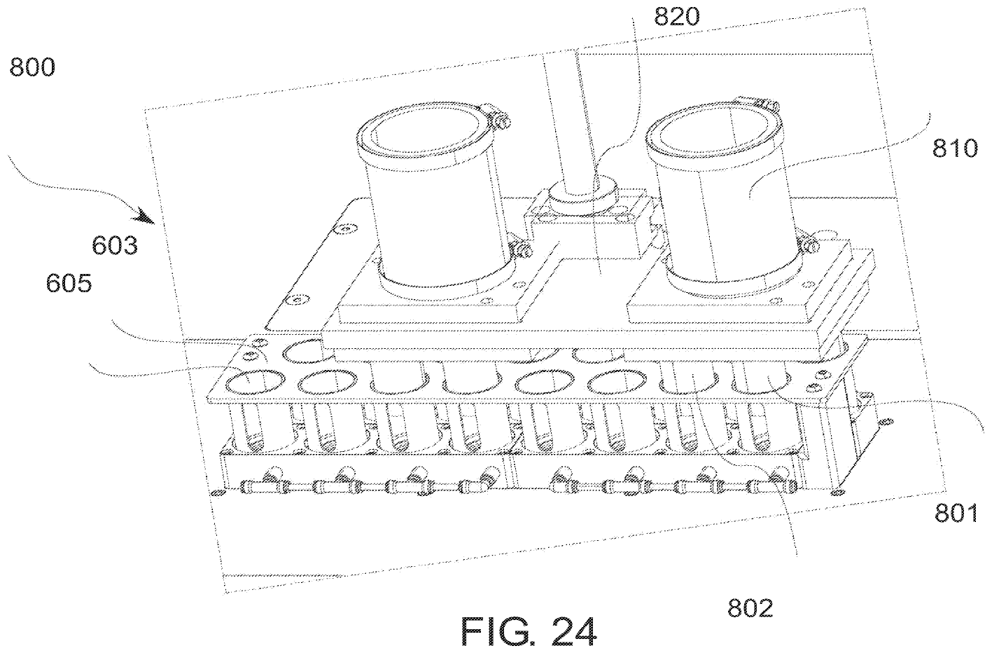

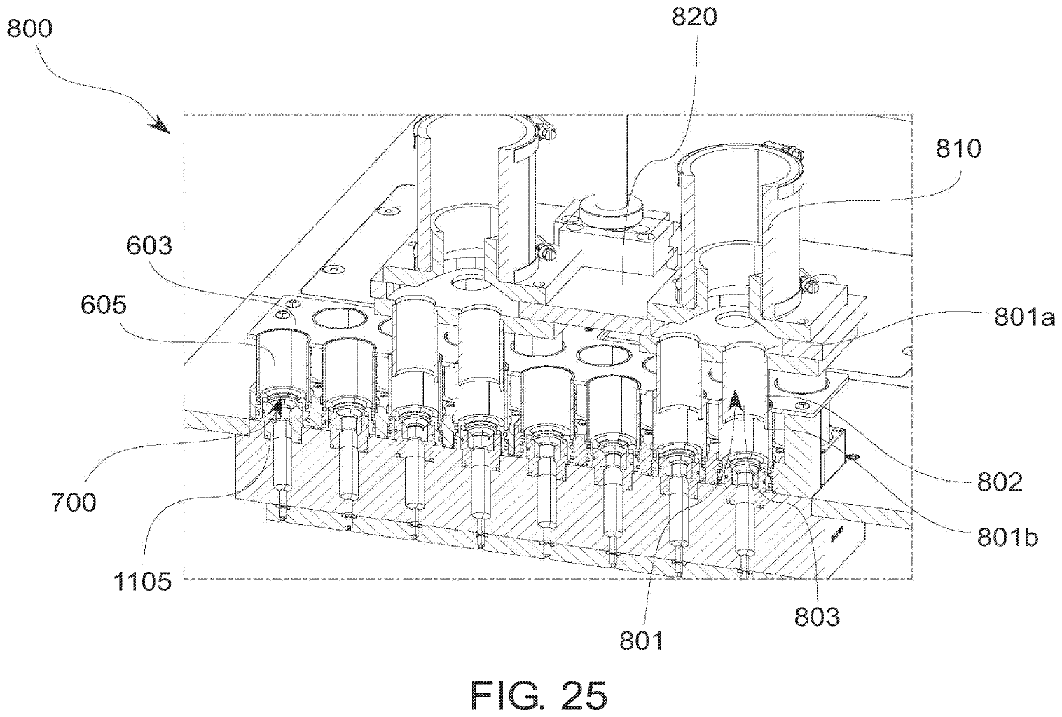

An embodiment of a system 800 for cleaning a sealing unit 700 of system 600, and more particularly for cleaning a plurality of sealing units 700 of system 600, is shown in FIGS. 24-25. System 800 may be configured to remove particles, e.g. coating flakes, from the source gas inlet probe 1101 and/or the sealing unit 700, and more particularly from the surfaces of the sealing unit 700 that come into contact with a vessel during a coating cycle (though other surfaces, such as the plasma screen 1107, etc. will also have particles removed therefrom).

System 800 comprises one or more inserts 801, each of which is configured to enter one of the vessel cavities 605. Each insert 801 comprises a wall 802 having an inner surface and an outer surface and which spans from a proximal end 801a of the insert to a distal end 801b of the insert. Both the proximal end and the distal end of the insert may be open. The inner surface of the wall 801 defines a central passage 803 that extends from the proximal end to the distal end of the insert 801. Each insert 801 is operably connected to a vacuum line 810 so as to produce a vacuum within the central passage 803. For instance, an open proximal end of the insert 801 may be operably connected to a vacuum line 810.

Preferably, and as illustrated, the system 800 comprises a plurality of inserts 801. The plurality of inserts 801 or a subset of the plurality of inserts may be operably connected to a single vacuum line 810. In the illustrated embodiment, for instance, the system 800 comprises two sets of inserts 801, each set being made up of four inserts. Each of the four inserts 810 within each set are operably connected to a single vacuum line 810. Regardless of the illustrated embodiment, however, other configurations are contemplated without departing from the scope of the present disclosure/invention.

The system 800 may also comprise a framework 820 which holds each of the plurality of inserts 801 and connects each of the plurality of inserts so that they are movable as a single unit. In other embodiments, however, there may be provided multiple frameworks 820, each of which holds a subset of the plurality of inserts 801 and connects the subset of inserts so that they are movable as a single unit. For instance, though not illustrated, each subset of four inserts 801 may have its own independent framework 820.

Additionally, although the illustrated embodiment shows eight total inserts 801 that are split into two subsets of four, any number and/or arrangement of inserts 801 may be provided without departing from the scope of the present disclosure/invention. For instance, in other embodiments, the number of inserts 801 may be the same as the number of vessel cavities 605, so that the system 600 can be cleaned in a single pass.

The cleaning system 800, and more particularly the one or more frameworks 820, may be movable between a first, cleaning position in which each of the one or more inserts 801 are at least partially positioned within one of the one or more cavities 605, and a second, coating position in which the cleaning system is positioned a distance away from the electrode 603 to allow for vessel loading and coating cycles. The movement of the cleaning system 800 may be controlled by one or more processors and may, for instance, be part of a fully automated coating operation.

During operation, the cleaning system 800 is moved to a cleaning position, with each of the one or more inserts 801 being at least partially positioned within one of the cavities 605 of the electrode 603. The one or more vacuum pumps are then operated to pull a vacuum within the central passage(s) 803 of the one or more inserts 801.

In order to obtain a desirable vacuum flow within each of the cavities 605, the outer diameter of the wall 802 of the insert 801 should be close to the diameter of the cavity 605, such that little of the vacuum is lost due to ambient air entering through a space between the wall of the electrode that defines the cavity and the insert. In some embodiments, for instance, the outer diameter of the wall 801 of each insert 801 may be within one inch, alternatively ¾ inch, alternatively ½ inch, alternatively ¼ inch, alternatively ⅛ inch of the diameter of each of the cavities 605.

By pulling a vacuum of suitable strength within the central passage 803 of each of the one or more inserts 801, particles present within the cavity—e.g. on the surfaces of the sealing unit 700 and/or the source gas inlet probe 1101—are carried through the central passage 803 and out of the cavity 605. In order to accomplish this removal of particles, the one or more vacuum pumps may desirably be configured to create a vacuum of at least 0.3 atm (a pressure of 0.3 atm or lower), alternatively at least 0.2 atm, alternatively at least 0.1 atm within the central passage 803 of each of the one or more inserts 801.

Although not illustrated, the system 800 may further comprise one or more particle collection units, e.g. comprising one or more screens or filters, to collect the particles removed from the cavity 605 and ensure that they do not enter into the one or more vacuum pumps. The particle collection unit may be positioned at any suitable location between the insert 801 and the vacuum pump.

In order to improve the cleaning step, it has presently been found that it is beneficial to position the insert 801 at a plurality of different depths in the the cavity 605 while the vacuum is being pulled. Doing so creates different flow profiles within the cavity 605, which helps to ensure that particles from various surfaces are subjected to a vacuum of suitable strength and sucked up into the insert 801. It may also be beneficial to hold the insert 801 at each of a plurality of different depths in the cavity 605 for a period before moving the insert to the next depth in order to allow the particular vacuum flow profile time to develop within the cavity.

In the illustrated embodiment, the cleaning system 800 moves from a first set of cavities 605 to a second set of cavities, cleaning each set in series. In some embodiments, the cleaning system 800 may move between the first and second sets of cavities 605 more than once during the cleaning process, i.e. it may make two or more passes at each set of cavities. Of course, other configurations are contemplated, including a configuration in which all of the cavities can be cleaned in a single step (e.g. the system 800 comprises the same number of inserts 801 as there are cavities 605, i.e. a ratio of 1:1) and configurations in which the ratio of inserts 801 to cavities 605 is either greater than or less than the 1:2 shown in the illustrated embodiment.

Once the cleaning of each of the one or more cavities 605 has been completed, the vacuum may be deactivated and the cleaning system 800 is moved away from the electrode 603 so that vessels may be loaded into the one or more cavities 605 and a coating cycle initiated.

The cleaning of the cavities 605 may be performed either in a routine manner or as determined to be necessary. In some embodiments, for example, the coating of one or more vessels in a single cycle may be followed by a cleaning cycle, i.e. each time a new set of vessels is removed from the system 600, the cavities 605 may be cleaned. In other embodiments, the cavities may be cleaned after a defined number of coating cycles. The exact number of coating cycles to be performed in between cleanings may be determined based on collected historical data or, more desirably, by a visual inspection step as described herein.

In some embodiments, for instance, the vessel holders 1105, and more particularly the sealing units 700, of each cavity 605 may be visually inspected for the presence of particles, the visual inspection being controlled and performed by one or more processors. In some embodiments, the visual inspection may be performed after each coating step and if a cavity 605 is determined to contain particles above a defined threshold (which may for instance be a number of particles, including zero), then the cleaning step may be initiated. Additionally or alternatively, the visual inspection may be performed after each cleaning step and if the cavity 605 is determined to contain particles above the defined threshold, the cleaning step may be repeated. This process may be repeated a number of times, after which the continued presence of particles above the defined threshold may result in the one or more processors halting the coating operation, alert an operator, etc.

The visual inspection may include obtaining an image of the one or more cavities 605, and in particular the sealing unit 700 at the base of each of the one or more cavities, and then sending the image to a processor which is configured to analyze the image to detect whether particles above a certain minimum size (e.g. 10 microns, alternatively 20 microns, alternatively 30 microns, alternatively 40 microns, alternatively 50 microns), i.e. detection limit, are present. The processor may also be configured to determine what number of particles above the minimum size are present, the size of each detected particle, or a combination thereof. If the particles are determined by the processor to be present in amounts, sizes, or a combination thereof that exceeds a defined and programmed/stored threshold value, then the processor may initiate a cleaning step.

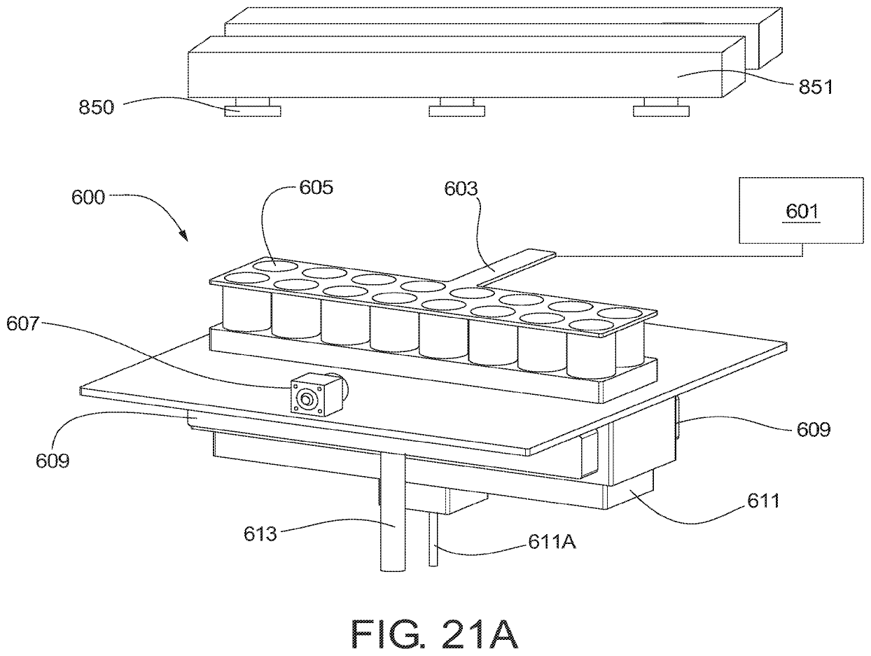

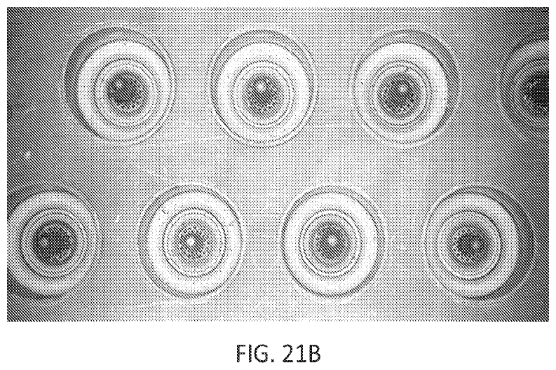

A system for visually inspecting the one or more cavities 605, and more specifically the sealing unit 700 at the base of each of the one or more cavities, may comprise one or more cameras 850, each of which is configured to obtain an image of the sealing unit of one or more cavities. The one or more cameras are desirably positioned above the electrode, preferably directly above the electrode. The system may also comprise one or more lights 851 configured to illuminate the interior and, in particular, the sealing unit 700 at the base of each cavity 605. In some embodiments, for instance, the system may comprise one or more isotropic linear lights. The one or more lights are also desirably positioned above the electrode, preferably directly above the electrode. An example of a visual inspection system is shown in FIG. 21A.

In some embodiments, the system may comprise an assembly, optionally a moveable assembly, that includes the one or more cameras and the one or more lights. The moveable assembly may thus be moved into place above the electrode 603 in order to perform visual inspection and, once the image or images have been captured, the assembly may be moved a distance away from the electrode 603 so as not to interference with the subsequent loading of vessels or cleaning of the cavities. In other embodiments, the assembly may be in a fixed position above the electrode 603 but at a sufficient distance so as not to interfere with the loading of vessels or the cleaning system 800. Where the assembly is movable, its movement may be controlled by one or more processors, e.g. it may form part of a fully automated and continuous coating operation.

The system further comprises one or more processors, the one or more processors being configured to receive an image from the one or more cameras and analyze the image to detect particles, e.g. as described above.

An example of an image of the sort that may be captured by the assembly described above and received by the one or more processors for analyzing is shown in FIG. 21B.

Although described above in connection with system 800 and method for cleaning the cavities 605 of an electrode 603 of the coating system 600 described herein, in some embodiments, the visual inspection system and method described herein may be performed as part of a coating system 600 and coating operation, regardless of whether or not the coating system and operation utilize a cavity cleaning step. For instance, in some embodiments, the visual inspection may be performed and the results may determine when to replace any one or more of a source gas inlet probe 1101, a puck 701, a flexible seal 702, or any combination thereof.

Typically, the source gas inlet probe 1101 is replaced after a defined number of coating cycles. During repeated coating cycles, the temperature of the inlet probe increases. During replacement of a source gas inlet probe 1101, therefore, the spent probe is cooled prior to removal. As the inlet probe cools, however, it often begins to shed loose flakes or particles of coating. In some embodiments, a vacuum may be applied during the cooling process. For instance, the cavity cleaning system described herein may be utilized to provide a vacuum during the gas inlet probe cooling step. By applying a vacuum during the cooling step, the cooling step may be significantly expedited. The vacuum may also prevent shedded material from landing in the areas of concern, e.g. the sealing unit, and removes shedded flakes and particles before they can pick up charge.

Methods and Systems for Removing Particles from Vessels

Another aspect of the present disclosure/invention is directed to methods and systems for removing particles from vessels, and in particular vessels having coatings prepared using the system and/or method described herein.

As described herein, the process of coating the inner surfaces of one or more vessels may result in particles being present on various portions of a vessel, including in particular the inner surface of a vessel and/or the portions of the vessel that come into contact with the sealing unit 700. Vessels may also collect particles during the molding process and/or during transportation or other process steps. The present disclosure provides a two-step method of removing particles from the surfaces of the vessel, including in particular the surfaces of a vessel that are most likely to collect particles during the coating process.

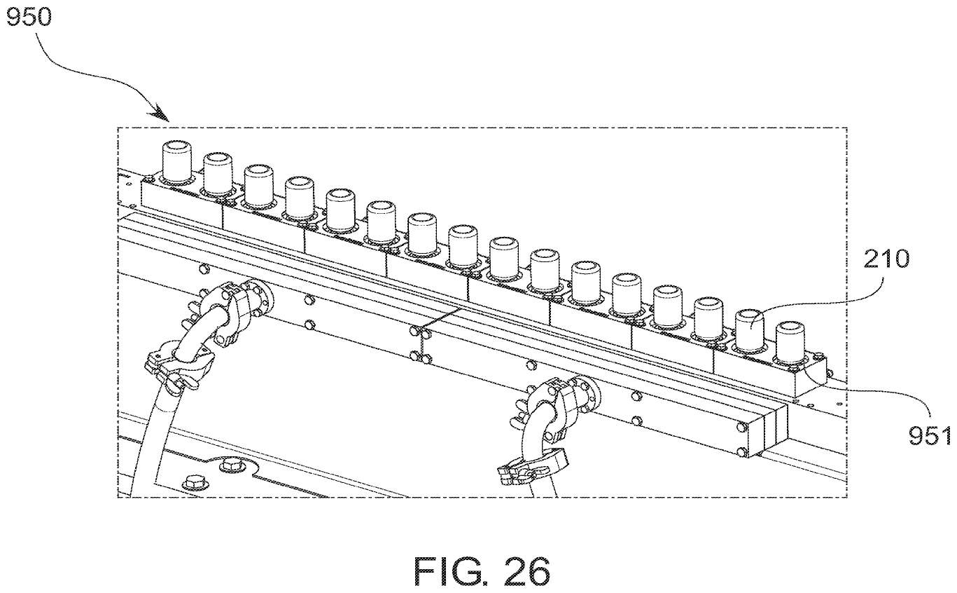

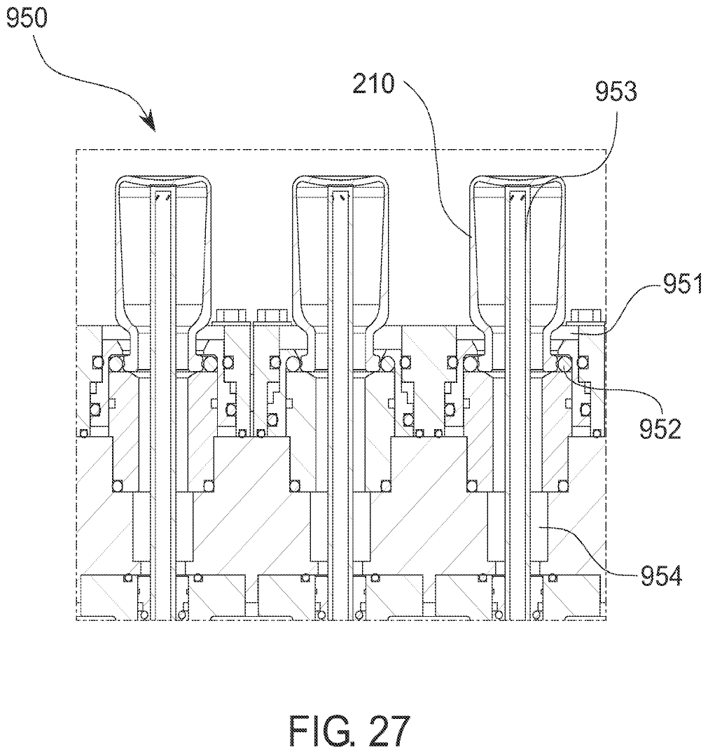

Embodiments of the present disclosure are directed to methods and systems for treating one or more vessels, e.g. one or more vessels coated according to the above process, to remove particles from the inner surfaces of the vessel. The method may comprise positioning the vessel in a cleaning station 950, and more particularly in a cavity 951 of a cleaning station, such as that illustrated in FIGS. 26-27. As in the coating system 600, the vessel is positioned with the opening to its lumen in the cavity 951. The lumen of the vessel may be sealed from the surrounding environment by one or more seals between the station 950 and the outer surface of the vessel. As shown in the illustrated embodiment, for example, sealing of the vessel may be performed by a sealing unit comprising a flexible seal 952 and which may be similar or identical to that shown and described above with reference to the coating system 600.

An air blower probe 953 may be inserted into the lumen of the vessel and used to spray high pressure air. In some embodiments, for instance, the air may be sprayed at a pressure of at least 50 psi, alternatively at least 55 psi, alternatively at least 60 psi, alternatively at least 70 psi, alternatively at least 80 psi. Because many of the particles may have a static charge associated with them, in some embodiments, the surface of the vessel may be contacted, e.g. sprayed, with ionized air. The ionized air removes the charges, allowing for an easier dislodgement of a particle. The air blower probe may be moved up and down, e.g. along the longitudinal axis of the vessel, and/or may be rotated, e.g. about the longitudinal axis of the vessel to ensure that the entire inner surface of the vessel has been contacted with the pressurized air.

During the spraying, vacuum may be pulled within the vessel lumen, e.g. through a vacuum line 954, to ensure that dislodged particles may be removed from the cleaning station 950 without contaminated a surrounding clean room environment.

Once the cleaning step has been completed, the vacuum may be deactivated and the vessel may be removed.

One or more vessels may be loaded into cleaning station 950 and removed from cleaning station 950 by a vessel conveyer. The movement of the one or more vessel conveyers may be controlled by one or more processors and may, for instance, be part of a fully automated coating and cleaning operation.

The vessels exiting cleaning station 950 are desirably free or substantially free from particles such as flakes of coating, e.g. particles having a dimension of 50 microns or greater, alternatively particles having a dimension of 40 microns or greater, alternatively particles having a dimension of 30 microns or greater, alternatively particles having a dimension of 20 microns or greater. For instance, upon exiting cleaning station 950 after the cleaning process has been performed, the inner surface of the vessel is desirably free or substantially free from particles, e.g. particles having a dimension of 50 microns or greater, alternatively particles having a dimension of 40 microns or greater, alternatively particles having a dimension of 30 microns or greater, alternatively particles having a dimension of 20 microns or greater.

An embodiment of a system, i.e. a cleaning station 950, for removing particles from the inner surface of one or more vessels is shown in FIGS. 26-27. As illustrated, the cleaning station may comprise one or more cavities 951, one or more sealing elements 952 located at the base of each cavitiy and being configured to form a gas-tight or substantially gas-tight seal with the vessel, a pressurized air delivery probe 953 which extends into the lumen of a vessel when the vessel is positioned in the cavity, and a vacuum line 954 operably connected to the cavity and configured to evacuate the vessel lumen.

Although not illustrated, the cleaning station 950 may further comprise one or more particle collection units, e.g. comprising one or more screens or filters, to collect the particles removed from the the one or more vessels and ensure that they do not enter into the one or more vacuum pumps. The particle collection unit may be positioned at any suitable location between the cavity 951 and the vacuum pump.

The cleaning station may further comprise one or more vessel conveyers (not illustrated), which may move the vessels into and out of the cleaning station 950. The operation of the cleaning station 950 and the movement of the one or more vessel conveyers may be controlled by one or more processors. As such, the cleaning station may be part of a fully automated coating and cleaning operation.

Embodiments of the present disclosure are directed to methods and systems for treating one or more vessels, e.g. one or more vessels coated according to the above process, to remove particles from a portion of the vessel that comes into contact with the sealing unit 700. The method may comprise inserting the vessel into a chamber 901 of a cleaning station 900; spraying at least a portion of the outside of the vessel with air, optionally ionized air; and applying a vacuum within the chamber 901 to remove any dislodged particles from the chamber. The portion of the vessel that is sprayed may include a portion of the vessel that comes into contact with the sealing unit 700 during the coating process. For instance, the portion of the vessel that is sprayed may include a portion of the vessel surrounding an opening to the lumen. Where the vessel comprises a flange, the portion of the vessel that is sprayed may include the upper and outer surfaces of the flange.

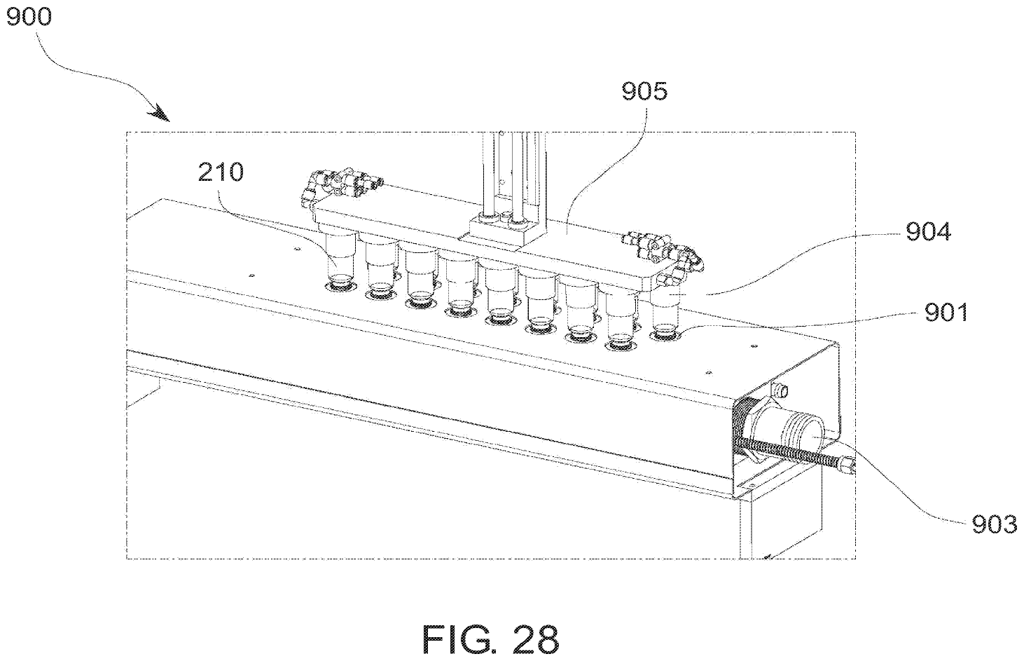

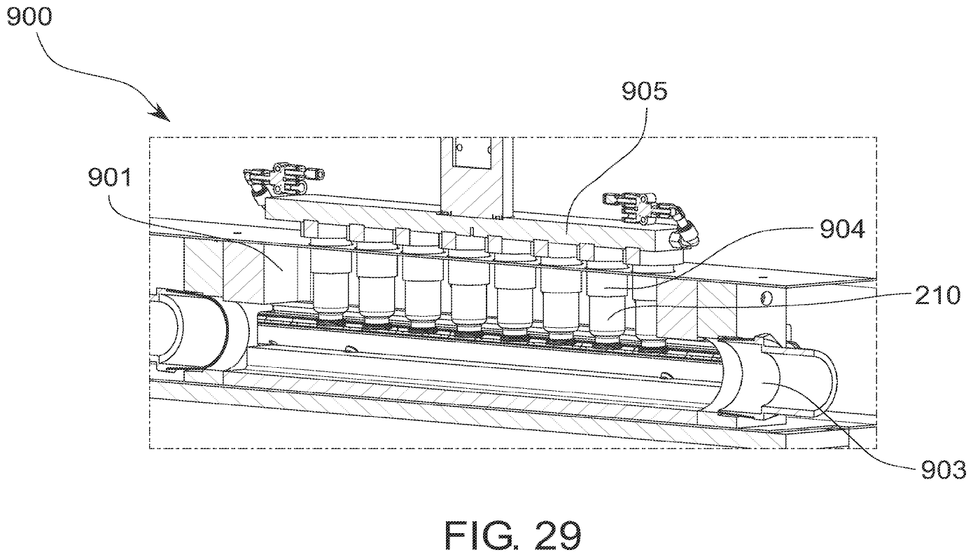

A system, or cleaning station 900, for removing particles from at least a portion of the the outer surfaces of the vessels is shown in FIGS. 28-30. The system 900 may comprise a chamber 901 configured to receive each of the one or more vessels, one or more nozzles 902 configured to spray air, optionally ionized air, toward a vessel positioned within the chamber, and one or more vacuum lines 903 configured to apply a vacuum within the chamber. Each of the one or more nozzles may be associated with one or more pressurized air supply manifold.

In some embodiments, including the illustrated embodiment, the system 900 may include at least a first nozzle or set of nozzles 902a and a second nozzle or set of nozzles 902b, each of which is positioned and oriented to spray a different (although possibly overlapping) portion of the vessel outer surface.

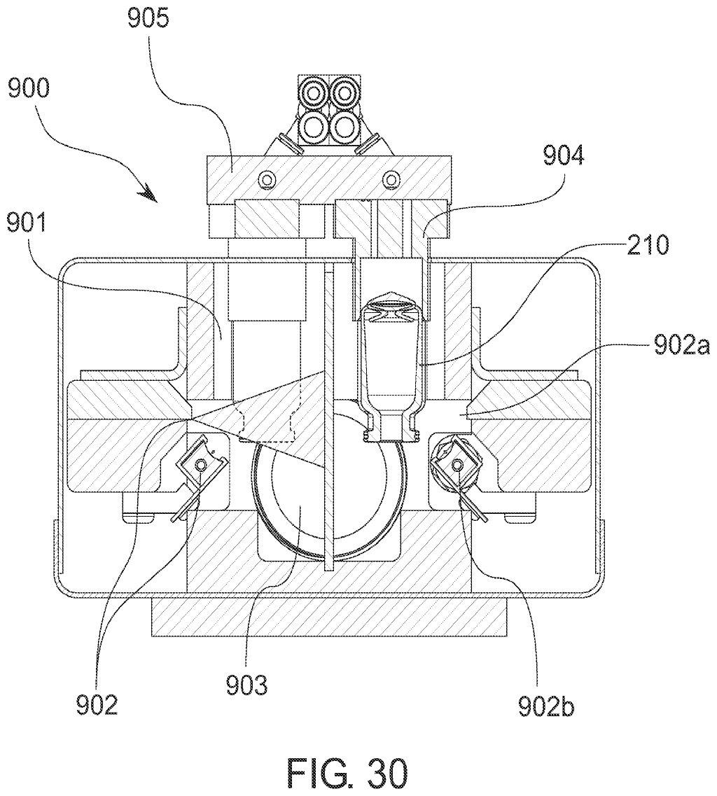

As shown in FIG. 30, the first nozzle or set of nozzles 902a may be configured to be in substantial alignment with a portion of the outer surface of the vessel side wall adjacent the opening to the lumen, for instance an outer surface of a flange, and may be directed substantially perpendicular to the longitudinal axis of the vessel when the vessel is received in the chamber 901. The first nozzle or set of nozzles 902a may thus be configured to remove particles from the portion of the vessel that comes into contact with flexible seal 702 during the coating process. Although illustrated as a single nozzle 902a, the first nozzle may comprise a set of nozzles which may, for example, be positioned around the circumference of the vessel when the vessel is in the chamber 901. When positioned around the circumference of the vessel, the plurality of nozzles 902a may be substantially evenly spaced around the circumference of the vessel. Adjacent nozzles in the set of nozzles 902a may provide overlapping sprays to ensure that the entire circumference of the vessel has been contacted.

The second nozzle or set of nozzles 902b may be configured to be positioned below the vessel (or above should the orientation of the chamber be flipped) and directed toward an end surface of the vessel that immediately surrounds the opening to the lumen, for instance an end surface of a flange, when a vessel is received in the chamber 901. In some embodiments, for instance, the second nozzle of set of nozzles 902b may be directed at an angle between about 20 degrees and about 70 degrees, optionally between about 30 degrees and about 60 degrees, optionally between about 40 degrees and about 50 degrees, optionally about 45 degrees, relative to the longitudinal axis of the vessel when the vessel is receive in the chamber. The second nozzle or set of nozzles 902b may thus be configured to remove particles from the portion of the vessel that comes into contact with the upper surface 703 of the puck 701 during the coating process. Although illustrated as a single nozzle 902b, the second nozzle may comprise a set of nozzles which may, for example, be positioned around the circumference of the vessel when the vessel is in the chamber 901. When positioned around the circumference of the vessel, the plurality of nozzles 902b may be substantially evenly spaced around the circumference of the vessel. Adjacent nozzles in the set of nozzles 902b may provide overlapping sprays to ensure that the entire circumference of the vessel has been contacted.

In the illustrated embodiment, the system 900 is oriented such that a vessel is placed into the chamber 901 with the end of the vessel that contains the opening to the lumen being inserted first and faces downward. However, other orientations are contemplated without departing from the scope of the present invention/disclosure.

One or more vessels may be held in the one or more chambers 901 by a vessel holder 904. The vessel holder 904 may be configured to contact the end of the vessel opposite the end having the opening to the lumen. For instance, in the illustrated embodiment, the vessel holder 904 is shown contacting the bottom of a vial. When configured for a syringe barrel, the vessel holder 904 may contact the front end of the barrel (since the opening to the lumen is at the rear of the syringe barrel).

In some embodiments, the vessel holder 904 may be configured to rotate the vessel during the cleaning process. Rotation of the vessel may be desirable in order to ensure that the outer surface(s) of the vial are contacted by air from the sprayers across the entire circumference of the vessel. In other embodiments, the vessel may not need to be rotated.

As shown in the illustrated embodiment, the vessel holder 904 may be configured to place the vessel in the chamber 901 and remove the vessel from the chamber. For instance, system 900 may also include a framework 905 which operatively connects each of the plurality of a plurality of vessel holders 904 so that they are movable as a single unit. In other embodiments, however, there may be provided multiple frameworks 905, each of which holds a subset of the plurality of vessel holders 904 and connects the subset of vessel holders so that they are movable as a single unit. The vessel holder 904, and more particularly the framework 905, may be movable toward and away from a unit containing the one or more chambers 901, so as to place the vessels in the chambers and remove the vessel from the chambers when the cleaning step has been completed. The movement of the one or more vessel holders 904, and more particularly the movement of the framework 905, may be controlled by one or more processors. Because the operation of the cleaning station 900 and the movement of the one or more vessel holders 904 may be controlled by one or more processes, the cleaning station 900 may be part of a fully automated coating operation.

Although not illustrated, the system 900 may further comprise one or more particle collection units, e.g. comprising one or more screens or filters, to collect the particles removed from the the one or more vessels and ensure that they do not enter into the one or more vacuum pumps. The particle collection unit may be positioned at any suitable location between the chamber 901 and the vacuum pump.

In order to remove particles from the outer surface of one or more vessels, the one or more vessels are inserted into a chamber 901 of a cleaning system 900. The one or more vessels may be held in position by a vessel holder 904, including but not limited to the sort shown in FIGS. 28-30. Once in the chamber 901, at least a portion of the outer surface of the vessel, desirably including at least a portion of the vessel that comes into contact with the sealing unit 700 during the coating operation, e.g. the portion of the vessel surrounding an opening to the lumen (which may comprise upper and outer surfaces of a flange), is sprayed with pressurized air, and desirably ionized air.

The pressurized air desirably removes any particles that are present on the surface of the vessel that is contacted. In some embodiments, for instance, the air may be sprayed at a pressure of at least 50 psi, alternatively at least 60 psi, alternatively at least 70 psi, alternatively at least 80 psi, alternatively at least 90 psi, alternatively at least 100 psi, alternatively at least 110 psi, alternatively at least 120 psi, alternatively at least 130 psi. Because many of the particles may have a static charge associated with them, in some embodiments, the surface of the vessel be contacted, e.g. sprayed, with ionized air. The ionized air may remove the charges, allowing for an easier dislodgement of a particle by the pressurized air.

In some embodiments, the vessel may be moved within the chamber during the spraying. For instance, in some embodiments the vessel may be moved up and down within the chamber (along the longitudinal axis of the vessel) during the spraying to ensure that a larger surface area of the vessel is contacted by the pressurized air. In some embodiments the vessel may be rotated about its longitudinal axis during the spraying to ensure that an entire circumference of the vessel is contacted by the pressured air. In some embodiments, both movements may take place. The one or more movements may be performed by the vessel holder 904. The movement of the vessel holder 904, and more particularly the framework 905, may be controlled by one or more processors and may, for instance, be part of a fully automated vessel coating and cleaning operation.

During the spraying, a vacuum is pulled in the chamber, so that all particles dislodged from the vessel are evacuated from the chamber without contaminating a clean-room environment. As shown in the illustrated embodiment, a single vacuum line 903 may be operably connected to a plurality of chambers 901 and/or a plurality of chambers may be associated so as to be open to one another.

In some embodiments, at least a portion of the vessel sidewall is sprayed with pressurized air and any particles present thereon removed. As shown in FIG. 30, for instance, the spraying may be performed by one or more nozzles 902a positioned in substantial alignment with a portion of the outer surface of the side wall adjacent the opening to the lumen, e.g. an outer surface of a flange, and directed substantially perpendicular to the longitudinal axis of the vessel.

In some embodiments, at least a portion of the vessel end wall is sprayed with pressurized air and any particles present thereon removed. As shown in FIG. 30, for instance, the spraying may be performed by one or more nozzles 902b positioned below the vessel and directed toward an end surface of the vessel, e.g. an upper surface of a flange, that immediately surrounds the opening to the lumen. The one or more nozzles 902b may, for example, be directed at an angle between about 20 degrees and about 70 degrees, optionally between about 30 degrees and about 60 degrees, optionally between about 40 degrees and about 50 degrees, relative to the longitudinal axis of the vessel.

Once the cleaning process has been carried out, the one or more vessels are removed from chamber(s) 901. The placing of the vessels in chamber 901 and the removal of the vessels from the chamber may be performed by vessel holder 904, which may be controlled by one or more processors. As such, the step of cleaning at least a portion of the outer surface of the vessel may be part of a fully automated vessel coating and cleaning operation.

The vessels exiting chamber 901 are desirably free or substantially free from particles such as flakes of coating, e.g. particles having a dimension of 50 microns or greater, alternatively particles having a dimension of 40 microns or greater, alternatively particles having a dimension of 30 microns or greater, alternatively particles having a dimension of 20 microns or greater. For instance, upon exiting chamber 901 after the cleaning process has been performed, the portion of the vessel outer surfaces surrounding an opening to the lumen, including for instance the portion of the vessel end wall and/or sidewall that comes into contact with the sealing unit 700 of coating system 600, is desirably free or substantially free from particles, e.g. particles having a dimension of 50 microns or greater, alternatively particles having a dimension of 40 microns or greater, alternatively particles having a dimension of 30 microns or greater, alternatively particles having a dimension of 20 microns or greater.

In some embodiments, vessels may be transported between inner surface cleaning station 950 and outer surface cleaning station 900, e.g. in a clean room environment.

When both the vessel inner surfaces and the vessel outer surfaces have been cleaned according to the present disclosure, the vessel is desirably free or substantially free from particles such as flakes of coating, e.g. particles having a dimension of 50 microns or greater, alternatively particles having a dimension of 40 microns or greater, alternatively particles having a dimension of 30 microns or greater, alternatively particles having a dimension of 20 microns or greater. Further, by using the cleaning operations described herein, no washing or water rinsing is required to be performed.

Embodiments of the present disclosure may provide a fully automated system for coating, cleaning, and/or inspecting a vessel. For example, a clean room environment may contain a coating station 600, a vessel inner surface cleaning station 950 and a vessel outer surface cleaning station 900, and a plurality of vessels may be transported from the coating station to each of the cleaning stations by one or more transport lines. Similarly, a clean room environment may contain vessel cleaning stations 950, 900 and a plurality of inspection stations 101, 102, 103, 104, 105 as described herein and a plurality of vessels may be transported between the cleaning stations and the inspection stations by one or more transport lines. The entire coating, cleaning, and/or inspection operation may be controlled by one or more processors.

Although many of the illustrations of coating system 600 and systems 900, 950 are shown being configured to coat and then remove particles from the surfaces of vials, the same systems may also be configured to coat and remove particles from the surfaces of other containers, e.g. syringe (and cartridge) barrels, blood collection tubes, etc., using the same technology shown in the illustrated embodiments. Unless otherwise stated, the present disclosure is in no way limited to the specific vessels 210 shown in the illustrated embodiments.

In still further embodiments, the fully automated system for coating, cleaning, and/or inspecting a vessel may be configured to store information related to operational parameters during manufacturing of the vessels (including, but not limited to the batch numbers for all components for molding the polymeric or glass vessels, the batch numbers for all components used in the coating process, the molding parameters used, the coating parameters used, the specific operators on duty, and the maintenance status for all elements of the clean rooms and manufacturing machinery); the resulting particulate load on the source gas inlet probe 1101, the sealing unit 700, or other components; and the resulting particulate load and/or defects on the coated vessels. This information may be stored in conventional databases as known in the art. Further the system may be configured to analyze the data to identify process parameters that result in an increased particulate burden or increased number of defects at any point in the process. In still further embodiments, this analysis may identify components, settings, environmental conditions, or personnel that are negatively impacting the particulate load or defect count earlier so that mitigation may be employed. In still further embodiments, this analysis may permit permutations in molding and coating parameters to be tested in order to optimize process efficiency while maintaining acceptably low particulate burdens and defect counts on produced vessels.

### Example 1

An automated coating, cleaning, and inspection system in accordance with the present disclosure was used to prepare and inspect a plurality of 10 ml vials. After coating, each vial was treated (1) to clean the inner surface which defines the lumen (inner blow-off) and (2) to clean the outer surfaces of the vial that come into direct contact with the coating system during the coating step (face blow-off), as described herein. Specifically, each surface was contacted with pressurized ionized air to remove particles in the cleaning stations described and shown herein. Additionally, after each coating cycle, the coating system was cleaned to remove particles from the surfaces of the sealing units that contact the vials during coating using the sealing unit cleaning system described and shown herein.

After inner blow-off and face blow-off cleaning treatments, each vial was inspected using both the automated inspection system described and shown herein and light obscuration testing techniques for measing subvisible particles. Extensive information was stored, including cleaning group number, pre/post clean association, time stamp, time since last cleaning, cavity number, particle count (for various particle sizes), and total area of particles. Data was generated and stored in a database accessible through a computer.

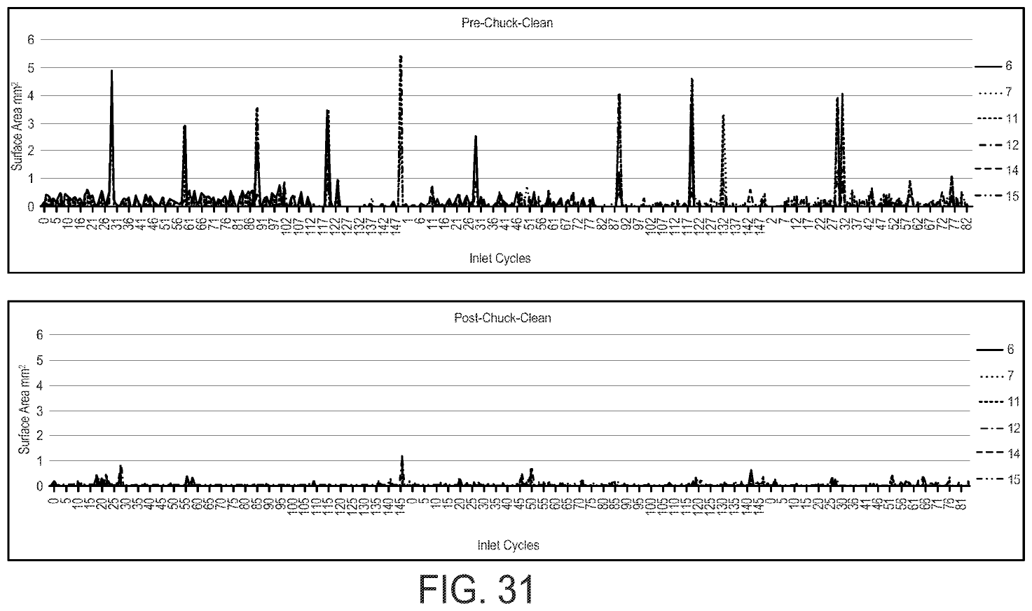

As a comparison, a second plurality of vials were coated using the same coating system. For this control sample, however, neither the vials nor the coating system was cleaned to remove particles after each cycle. The control vials were also inspected using both the automated inspection system described and shown herein and light obscuration testing techniques for measing subvisible particles. The results were compared against the test sample. The comparative results are shown in FIG. 31. As shown in FIG. 31, implementation of the cleaning system drastically reduced the total particle count to fewer than 25 particles per 10 mL vial, in all inlet counts (out of 150 cycles) and vials tested (here 142).

The average size distribution of particles for the vials that were subjected to the cleaning steps (and coated after the sealing unit of the coating system was cleaned) is provided in Table 1. Table 1 demonstrates that by using the cleaning system described herein, particles above 50 μm were completely eliminated from the vials.

TABLE 1

| | Subvisible particles/mLs | | |
|---|---|---|---|
| | >2 μm | >10 μm | >50 μm |
| Particle count | 33 | 1.5 | 0.0 |
| (n = 124 vials) | | | |

Particulate size distribution in vials after implementation of the automated cleaning technology, showing the automated system successfully eliminates particles above 50 μm (numbers averaged over 3 runs).

The cleaning system and method also consistently and repeatably produced vials that passed the particulate size rejection requirement of >0.0019 mm², meaning that if any particle remains in the vial, its surface area should be less than 0.0019 mm².

### Specific Embodiments

### Vessel Inspection Methods

1. A method of inspecting a pharmaceutical container, optionally a ready-to-use pharmaceutical container, for particles, the container having a generally cylindrical side wall, a top comprising a neck defining an opening, a shoulder connecting the side wall to the neck, and optionally a bottom wall and a transition region connecting the bottom wall to the side wall, the method comprising
capturing a plurality of images of a side wall portion of the container with a side body camera,
optionally, capturing a plurality of images of a shoulder portion of the container with an angled shoulder camera,
optionally, capturing a plurality of images of a top portion of the container with an angled top camera,
optionally, capturing a plurality of images of a transition region portion of the container with an angled bottom camera, and
optionally, capturing one or more images of a bottom wall portion of the container with a bottom camera;
defining one or more inspection areas for each image; and
determining whether there are any particles or defects within the one or more inspection areas, the number of particles or defects within the one or more inspection areas, a size of at least one particle or defect that is identified, or any combination thereof.

2. A method of inspecting a pharmaceutical container, optionally a ready-to-use pharmaceutical container, for particles, the method comprising
a. any combination of one or more of the following:
   for a container having a side wall, capturing a plurality of images of a side wall portion of the container with a side body camera,
   for a container having a shoulder, capturing a plurality of images of a shoulder portion of the container with an angled shoulder camera,
   for a container having a top, capturing a plurality of images of a top portion of the container with an angled top camera,
   for a container having a side wall, a bottom wall, and a transition region between the side wall and the bottom wall, capturing a plurality of images of a transition region portion of the container with an angled bottom camera, and
   for a container having a bottom wall, capturing one or more images of a bottom wall of the container with a bottom camera;
b. defining one or more inspection areas for each image; and
c. determining whether there are any particles or defects within the one or more inspection areas, the number of particles or defects within the one or more inspection areas, a size of at least one particle or defect that is identified, or any combination thereof.
3. The method of any preceding embodiment, wherein the step of determining whether there are any particles or defects within the one or more inspection areas, the number of particles or defects within the one or more inspection areas, a size of any particles or defects that are identified, or any combination thereof, is performed by at least one processor.
4. The method of any preceding embodiment, wherein the step of applying one or more inspection areas to each image is performed by at least one processor.
5. A method of inspecting a pharmaceutical container, e.g. a ready-to-use pharmaceutical container, for particles, the method comprising
a. any combination of one or more of the following:
   for a container having a side wall, capturing a plurality of images of a side wall portion of the container with a side body camera,
   for a container having a shoulder, capturing a plurality of images of a shoulder portion of the container with an angled shoulder camera,
   for a container having a top, capturing a plurality of images of a top portion of the container with an angled top camera,
   for a container having a side wall, a bottom wall, and a transition region between the side wall and the bottom wall, capturing a plurality of images of a transition region portion of the container with an angled bottom camera, and
   for a container having a bottom wall, capturing one or more images of a bottom wall of the container with a bottom camera;
b. defining, by at least one processor, one or more inspection areas for each image; and
c. determining, by at least one processor, whether there are any particles or defects within the one or more inspection areas, the number of particles or defects within the one or more inspection areas, a size of at least one particle or defect that is identified, or any combination thereof.

6. The method of any preceding embodiment, wherein the step of capturing a plurality of images of side wall portions of the container comprises
supporting the container above a bottom light and between a side light and the side body camera;
rotating the container about its central axis, optionally continuously rotating the container about its central axis;
using the side body camera to capture a plurality of images of the container side wall as it rotates, the images coinciding or overlapping so that the plurality of images cover a 360° arc of the container side wall.

7. The method of any preceding embodiment, in which the bottom light is a direct backlight, optionally a blue direct backlight.

8. The method of any preceding embodiment, in which the side body camera comprises an ultra-high-resolution area scan camera equipped with a telecentric lens.

9. The method of any preceding embodiment, in which the side light comprises a high output flat light, optionally a high output flat blue light.

10. The method of any preceding embodiment, wherein the step of capturing a plurality of images of side wall portions of the container is performed at a station of a transport line for a plurality of containers.

11. The method of any preceding embodiment, further comprising
a. providing a vessel holder
b. operating the vessel holder to remove a container from the transport line;
c. at least one of: (i) operating the vessel holder to move the container to the station or (ii) moving the bottom light and side light into an operative position adjacent the container to form the station;
d. after the plurality of images are captured, at least one of: (i) operating the vessel holder to move the container away from the station or (ii) moving the bottom light and side light move into a standby position away from the container; and
e. operating the the vessel holder to re-place the container on the transport line.

12. The method of any preceding embodiment, wherein the step of capturing a plurality of images of shoulder portions of the container comprises
supporting the container above a bottom light and between a side light and the angled shoulder camera;
rotating the container about its central axis, optionally continuously rotating the container about its central axis;
using the angled shoulder camera to capture a plurality of images of the container as it rotates, the images coinciding or overlapping so that the plurality of images cover a 360° arc of the container shoulder.

13. The method of any preceding embodiment, in which the bottom light is a direct backlight, optionally a blue direct backlight.

14. The method of any preceding embodiment, in which the angled shoulder camera comprises an ultra-high-resolution area scan camera.

15. The method of any preceding embodiment, in which the side light comprises a direct backlight, optionally a blue direct backlight.

16. The method of any preceding embodiment, wherein the step of capturing a plurality of images of shoulder portions of the container is performed at a station of a transport line for a plurality of containers.

17. The method of any preceding embodiment, further comprising
a. providing a vessel holder
b. operating the vessel holder to remove a container from the transport line;
c. at least one of: (i) operating the vessel holder to move the container to the station or (ii) moving the bottom light and side light into an operative position adjacent the container to form the station;
d. after the plurality of images are captured, at least one of: (i) operating the vessel holder to move the container away from the station or (ii) moving the bottom light and side light move into a standby position away from the container; and
e. operating the the vessel holder to re-place the container on the transport line.

18. The method of any preceding embodiment, wherein the step of capturing a plurality of images of top portions of the container comprises
supporting the bottom surface of the container on or above a bottom light, such that the container is between a side light and the angled top camera;
rotating the container about its central axis, optionally continuously rotating the container about its central axis;
using the angled top camera to capture a plurality of images of the container as it rotates, the images coinciding so that the plurality of images cover a 360° arc of the container top.

19. The method of any preceding embodiment, in which the bottom light is a direct backlight, optionally a blue direct backlight.

20. The method of any preceding embodiment, in which the angled top camera comprises an ultra-high-resolution area scan camera.

21. The method of any preceding embodiment, in which the side light comprises a direct backlight, optionally a blue direct backlight.

22. The method of any preceding embodiment, in which the container is supported above the bottom light by a rotatable platform.

23. The method of any preceding embodiment, wherein the rotatable platform is configured so that it does not substantially distort the bottom light.

24. The method of any preceding embodiment, wherein the bottom light is rotatable.

25. The method of any preceding embodiment, further comprising reducing or eliminating shadows by providing a reflective wall on the side of the container opposite the side light.

26. The method of any preceding embodiment, wherein the step of capturing a plurality of images of top portions of the container is performed at a station of a transport line for a plurality of containers.

27. The method of any preceding embodiment, further comprising
a. providing a vessel holder
b. operating the vessel holder to remove a container from the transport line;
c. at least one of: (i) operating the vessel holder to move the container to the station or (ii) moving the bottom light and side light into an operative position adjacent the container to form the station;
d. after the plurality of images are captured, at least one of: (i) operating the vessel holder to move the container away from the station or (ii) moving the bottom light and side light move into a standby position away from the container; and
e. operating the the vessel holder to re-place the container on the transport line.

28. The method of any preceding embodiment, wherein the step of capturing a plurality of images of a transition region between a side wall and a bottom wall of the container comprises
supporting the top surface of the container on or above a bottom light, such that the container is inverted and between a side light and the angled bottom camera;
rotating the container about its central axis, optionally continuously rotating the container about its central axis;
using the angled bottom camera to capture a plurality of images of the container as it rotates, the images coinciding so that the plurality of images cover a 360° arc of the container transition region.

29. The method of any preceding embodiment, in which the bottom light is a direct backlight, optionally a blue direct backlight.

30. The method of any preceding embodiment, in which the angled bottom camera comprises an ultra-high-resolution area scan camera.

31. The method of any preceding embodiment, in which the side light comprises a direct backlight, optionally a blue direct backlight.

32. The method of any preceding embodiment, in which the container is supported above the bottom light by a rotatable platform.

33. The method of any preceding embodiment, wherein the rotatable platform is configured so that it does not substantially distort the bottom light.

34. The method of any preceding embodiment, wherein the bottom light is rotatable.

35. The method of any preceding embodiment, wherein the step of capturing a plurality of images of transition regions of the container is performed at a station of a transport line for a plurality of containers.

36. The method of any preceding embodiment, further comprising
a. providing a vessel holder
b. operating the vessel holder to remove a container from the transport line;
c. at least one of: (i) operating the vessel holder to move the container to the station or (ii) moving the bottom light and side light into an operative position adjacent the container to form the station;
d. after the plurality of images are captured, at least one of: (i) operating the vessel holder to move the container away from the station or (ii) moving the bottom light and side light move into a standby position away from the container; and
e. operating the the vessel holder to re-place the container on the transport line.

37. The method of any preceding embodiment, wherein the step of capturing one or more images of the bottom wall of the container comprises
supporting the top surface of the container on or above a bottom light, such that the container is inverted and between the bottom light and the bottom camera;
using the bottom camera to capture one or more images of the bottom wall of the container.

38. The method of any preceding embodiment, in which the bottom light is a direct backlight, optionally a blue direct backlight.

39. The method of any preceding embodiment, wherein the step of capturing one or more images of the bottom wall of the container further comprises supporting the container adjacent a side light.

40. The method of any preceding embodiment, in which the side light comprises a direct backlight, optionally a blue direct backlight.

41. The method of any preceding embodiment, wherein the step of capturing one or more images of the bottom wall of the container is performed at a station of a transport line for a plurality of containers.

42. The method of any preceding embodiment, wherein the step of capturing one or more images of the bottom wall of the container is performed at the same station as the step of capturing a plurality of images of the transition regions of the container.

43. The method of any preceding embodiment, wherein
a. providing a vessel holder
b. operating the vessel holder to remove a container from the transport line;
c. at least one of: (i) operating the vessel holder to move the container to the station or (ii) moving the bottom light and side light into an operative position adjacent the container to form the station;
d. after the plurality of images are captured, at least one of: (i) operating the vessel holder to move the container away from the station or (ii) moving the bottom light and side light move into a standby position away from the container; and
e. operating the the vessel holder to re-place the container on the transport line.

44. The method of any preceding embodiment, in which one or more of the side body camera, the angled shoulder camera, the angled top camera, and the angled bottom camera is configured to capture an image having an inspection area that extends across at least a 50° arc, optionally at least a 55° arc, optionally at least a 60° arc, optionally at least a 65° arc, optionally at least a 70° arc.

45. The method of any preceding embodiment, in which each of the side body camera, the angled shoulder camera, the angled top camera, and the angled bottom camera is configured to capture an inspection area that extends across at least a 50° arc, optionally at least a 55° arc, optionally at least a 60° arc, optionally at least a 65° arc, optionally at least a 70° arc.

46. The method of any preceding embodiment, in which one or more of the side body camera, the angled shoulder camera, the angled top camera, and the angled bottom camera captures at least six images of the container.

47. The method of any preceding embodiment, in which each of the side body camera, the angled shoulder camera, the angled top camera, and the angled bottom camera captures at least six images of the container.

48. The method of any preceding embodiment, in which the inspection area of each of the images overlaps with the inspection area of another of the images.

49. The method of any preceding embodiment, wherein the container is configured to store an injectable drug.

50. The method of any preceding embodiment, wherein the container is a vial, syringe barrel, or cartridge.

51. The method of any preceding embodiment, wherein the container is a vial.

52. The method of any preceding embodiment, wherein the container has a glass wall or a plastic wall.

53. The method of any preceding embodiment, wherein the container wall is transparent.

54. The method of any preceding embodiment, wherein the method comprises determining whether there are any particles or defects within the one or more inspection areas.

55. The method of any preceding embodiment, wherein the method comprises determining the number of particles or defects within the one or more inspection areas.

56. The method of any preceding embodiment, wherein the method comprises determining the size of any particles or defects within the one or more inspection areas.

57. The method of any preceding embodiment, wherein the method comprises determining the surface area of any particles or defects within the one or more inspection areas.

58. The method of any preceding embodiment, wherein the step of determining whether there are any particles or defects within the one or more inspection areas comprises determining whether there are any particles or defects 20 microns or greater, alternatively 25 microns or greater, alternatively 30 microns or greater, alternatively 40 microns or greater, alternatively 50 microns or greater, alternatively 60 microns or greater, alternatively 70 microns or greater, alternatively between 25 and 500 microns, alternatively between 30 and 500 microns, alternatively between 40 and 500 microns, alternatively between 50 and 500 microns, alternatively between 60 and 500 microns, alternatively between 70 and 500 microns, alternatively between 80 and 500 microns, alternatively between 25 and 400 microns, alternatively between 30 and 400 microns, alternatively between 40 and 400 microns, alternatively between 50 and 400 microns, alternatively between 60 and 400 microns, alternatively between 70 and 400 microns, alternatively between 80 and 400 microns, alternatively between 25 and 300 microns, alternatively between 30 and 300 microns, alternatively between 40 and 300 microns, alternatively between 50 and 300 microns, alternatively between 60 and 300 microns, alternatively between 70 and 300 microns, alternatively between 80 and 300 microns.

59. The method of any preceding embodiment, wherein the step of determining the surface area of any particles or defects within the one or more inspection areas comprises determining whether any particles have a surface area that meets or exceeds a threshold value, optionally wherein the threshold value is 0.0019 mm².

60. The method of any previous embodiment, further comprising removing a container from the transport line if the particles or defects within the one or more inspection areas are determined to be above a threshold value.

61. The method of any previous embodiment, wherein the threshold value relates to the number of particles or defects, the threshold value relates to the size of a particle or defect, the threshold value relates to the surface area of a particle or defect, or the threshold value relates to any combination thereof.

62. The method of any previous embodiment, further comprising compensating for changes in ambient lighting in one or more of the following:
capturing a plurality of images of side wall portions of the container with a side body camera,
capturing a plurality of images of a shoulder portion of the container with an angled shoulder camera,
capturing a plurality of images of a top portion of the container with an angled top camera,
capturing a plurality of images of a transition region between a side wall and a bottom wall of the container with an angled bottom camera, and
capturing one or more images of a bottom wall of the container with a bottom camera.

63. The method of any previous embodiment, wherein one or more, and optionally each, of the side body camera, the angled shoulder camera, the angled top camera, the angled bottom camera, and the bottom camera is configured to compensate for changes in ambient lighting.

64. The method of any previous embodiment, wherein one or more, and optionally each, of the side body camera, the angled shoulder camera, the angled top camera, the angled bottom camera, and the bottom camera include a bandpass filter, optionally a bandpass filter that only passes light having wavelengths required for the determining step.

65. The method of any previous embodiment, further comprising monitoring the intensity of the one or more back lights, the intensity of the one or more side lights, or both to ensure that the intensity/intensities remains within a defined range.

66. The method of any previous embodiment, further comprising stopping the inspection if the intensity of the one or more back lights, the one or more side lights, or both fall outside of the defined range.

67. The method of any previous embodiment, further comprising determining, by the at least one processor, whether a defect is a cosmetic defect or a critical defect.

68. The method of any previous embodiment, further comprising removing a container from the transport line if a defect is determined to be a critical defect.

69. The method of any previous embodiment, wherein determining, by at least one processor, whether a defect is a cosmetic defect or a critical defect comprises analyzing, by the at least one processor, a shape of the defect, a depth of the defect, or a combination thereof.

### Systems

70. A system for inspecting a pharmaceutical container, the system comprising:
a plurality of cameras comprising
   a side body camera,
   an angled shoulder camera,
   an angled top camera,
   an angled bottom camera, and
   a bottom camera;
one or more vessel holders, at least one of the one or more vessel holders being configured to rotate the container;
a plurality of lights comprising at least
   one or more bottom lights, and
   one or more side lights.

71. A system for inspecting a pharmaceutical container, the system comprising:
any combination of the following cameras:
   a side body camera,
   an angled shoulder camera,
   an angled top camera,
   an angled bottom camera, and
   a bottom camera;
one or more vessel holders, optionally at least one of the one or more vessel holders being configured to rotate the container during inspection;
a plurality of lights comprising at least
   one or more bottom lights, and
   one or more side lights.

72. The system of any preceding embodiment, further comprising at least one processor configured to receive images captured by each camera, apply one or more inspection areas to the image, and detect whether there are any particles or defects within the one or more inspection areas.

73. The system of any preceding embodiment, in which the at least one processor is also configured to determine a size of any particles or defects that are detected.

74. The system of any preceding embodiment, in which the at least one processor is also configured to determine a number of particles or defects within the one or more inspection areas.

75. The system of any preceding embodiment, in which the at least one processor is also configured to determine the surface area of any particles that are detected.

76. The system of any preceding embodiment, in which the processor is configured to determine if the container is not perfectly aligned with the camera and to adjust an inspection area based on that determination.

77. The system of any previous embodiment, in which the system is configured to remove a container from a transport line if the particles or defects in the one or more inspection areas are determined to be above a threshold value.

78. The system of any previous embodiment, wherein the threshold value relates to the number of particles or defects, the threshold value relates to the size of a particle or defect, or the threshold value relates to a combination of the number of particles or defects and the size of a particle or defect.

79. The system of any preceding embodiment, in which the processor is configured to determine whether a defect is a cosmetic defect or a critical defect.

80. The system of any previous embodiment, wherein the system is configured to remove a container from a transport line if a defect is determined to be a critical defect.

81. The system of any previous embodiment, wherein to determine whether a defect is a cosmetic defect or a critical defect, the processor is configured to analyze a shape of the defect, a depth of the defect, or a combination thereof.

82. The system of any preceding embodiment, in which at least one of the lights is a blue backlight, optionally a blue LED backlight.

83. The system of any preceding embodiment, in which one or more of the cameras is an ultra-high-resolution area scan camera.

84. The system of any preceding embodiment, in which at least one of the cameras comprises a telecentric lens, optionally in which the side body camera comprises a telecentric lens.

85. The system of any previous embodiment, wherein one or more, and optionally each, of the side body camera, the angled shoulder camera, the angled top camera, the angled bottom camera, and the bottom camera is configured to compensate for changes in ambient lighting.

86. The system of any previous embodiment, wherein one or more, and optionally each, of the side body camera, the angled shoulder camera, the angled top camera, the angled bottom camera, and the bottom camera include a bandpass filter, optionally a bandpass filter that only passes light having wavelengths required for the detecting of particles or defects.

87. The system of any preceding embodiment, in which at least one of the vessel holders is configured to continuously rotate the container during an inspection with which it is associated.

88. The system of any preceding embodiment, in which at least one of the cameras is configured to capture an inspection area while the container is rotating, optionally wherein the shutter of the camera is open for less than one millisecond.

89. The system of any preceding embodiment, in which at least one, and optionally each, of the side body camera, the angled shoulder camera, the angled top camera, and the angled bottom camera is configured to capture an image having an inspection area that extends across at least a 50° arc, optionally at least a 55° arc, optionally at least a 60° arc, optionally at least a 65° arc, optionally at least a 70° arc of the circumference of the container region being inspected.

90. The system of any preceding embodiment, in which at least one, and optionally each, of the side body camera, the angled shoulder camera, the angled top camera, and the angled bottom camera captures at least six images of the container.

91. The system of any preceding embodiment, in which the inspection area of each of the images taken by the camera overlaps with the inspection area of another of the images taken by that camera.

92. The system of any preceding embodiment, in which at least one of the vessel holders holds the top of the container such that the bottom of the container is not in contact with any surface.

93. The system of any preceding embodiment, in which at least one of the vessel holders is a rotating platform that supports the vessel.

94. The system of any preceding embodiment, in which the rotating platform is mounted on top of a bottom light, and wherein the rotating platform is configured so that it does not substantially distort the bottom light.

95. The system of any preceding embodiment, in which the rotating platform comprises a gear, and wherein the gear is configured so that it does not substantially distort the bottom light.

96. The system of any preceding embodiment, in which the system comprises a plurality of inspection stations.

97. The system of any preceding embodiment, in which the system comprises a side body inspection station comprising:
the side body camera;
a bottom light, optionally a direct backlight, optionally a blue direct backlight;
a vessel holder configured to hold the top of the container such that the container is suspended above the bottom light and configured to rotate the container about its central axis; and
a side light positioned on an opposite side of the vessel holder from the side body camera.

98. The system of any preceding embodiment, in which the side body camera comprises an ultra-high-resolution area scan camera equipped with a telecentric lens.

99. The system of any preceding embodiment, in which the side light comprises a high output flat light, optionally a high output flat blue light.

100. The system of any preceding embodiment, in which the side body inspection station is part of a transport line for a plurality of containers.

101. The system of any preceding embodiment, wherein the system is configured such that
a. a vessel holder removes a container from the transport line;
b. either (i) the vessel holder moves the container to the side body inspection station or (ii) components including the bottom light and side light move into positions adjacent the container to at least partially form the side body inspection station;
c. either (i) the vessel holder moves the container back to the transport line or (ii) components including the bottom light and side light move away from the container; and
d. the vessel holder replaces the container to the transport line.

102. The system of any preceding embodiment, wherein movement of the vessel holder and/or the components is controlled by at least one processor, optionally wherein the movement is fully automated.

103. The system of any preceding embodiment, in which the system comprises an angled shoulder inspection station comprising:
the angled shoulder camera;
a bottom light, optionally a direct backlight, optionally a blue direct backlight;
a vessel holder configured to hold the top of the container such that the container is suspended above the bottom light and configured to rotate the container about its central axis;
a side light positioned on an opposite side of the vessel holder from the angled shoulder camera.

104. The system of any preceding embodiment, in which the angled shoulder camera comprises an ultra-high-resolution area scan camera.

105. The system of any preceding embodiment, in which the side light is a direct backlight, optionally a blue direct backlight.

106. The system of any preceding embodiment, in which the shoulder inspection station is part of a transport line for a plurality of containers.

107. The system of any preceding embodiment, wherein the system is configured such that
a. a vessel holder removes a container from the transport line;
b. either (i) the vessel holder moves the container to the shoulder inspection station or (ii) components including the bottom light and side light move into positions adjacent the container to at least partially form the shoulder inspection station;
c. either (i) the vessel holder moves the container back to the transport line or (ii) components including the bottom light and side light move away from the container; and
d. the vessel holder replaces the container to the transport line.

108. The system of any preceding embodiment, wherein movement of the vessel holder and/or the components is controlled by at least one processor, optionally wherein the movement is fully automated.

109. The system of any preceding embodiment, in which the system comprises an angled top inspection station comprising:
the angled top camera;
a bottom light, optionally a direct backlight, optionally a blue direct backlight;
a rotatable vessel holder that supports the bottom wall of the vessel, optionally a rotatable platform, the rotatable platform being configured so that it does not substantially distort the bottom light;
a side light positioned on an opposite side of the vessel holder from the angled top camera; and
optionally, a reflective wall positioned on an opposite side of the vessel holder from the side light, the reflective wall being configured to reduce or eliminate shadows, optionally wherein the reflective wall has a concave surface.

110. The system of any preceding embodiment, in which the angled top camera comprises an ultra-high-resolution area scan camera.

111. The system of any preceding embodiment, in which the side light is a direct backlight, optionally a blue direct backlight.

112. The system of any preceding embodiment, in which the angled top inspection station is part of a transport line for a plurality of containers.

113. The system of any preceding embodiment, wherein the system is configured such that
a. a vessel conveying unit removes a container from the transport line;
b. either (i) the vessel conveying unit moves the container to the angled top inspection station or (ii) components including the bottom light and side light move into positions adjacent the container to at least partially form the angled top inspection station;
c. either (i) the vessel conveying unit moves the container back to the transport line or (ii) components including the bottom light and side light move away from the container; and
d. the vessel conveying unit replaces the container to the transport line.

114. The system of any preceding embodiment, wherein movement of the vessel conveying unit and/or the components is controlled by at least one processor, optionally wherein the movement is fully automated.

115. The system of any preceding embodiment, in which the system comprises an angled bottom inspection station comprising:
the angled bottom camera;
a bottom light, optionally a direct backlight, optionally a blue direct backlight;
a rotatable vessel holder that supports the top surface of the vessel, optionally a rotatable platform, the rotatable platform being configured so that it does not distort the bottom light;
a side light positioned on an opposite side of the vessel holder from the angled bottom camera.

116. The system of any preceding embodiment, in which the angled bottom camera comprises an ultra-high-resolution area scan camera.

117. The system of any preceding embodiment, in which the side light is a direct backlight, optionally a blue direct backlight.

118. The system of any preceding embodiment, in which the angled bottom inspection station further comprises the bottom camera.

119. The system of any preceding embodiment, in which the bottom camera is mounted directly above the vessel holder.

120. The system of any preceding embodiment, in which the angled bottom inspection station is part of a transport line for a plurality of containers.

121. The system of any preceding embodiment, wherein the system is configured such that
a. a vessel conveying unit removes a container from the transport line;
b. either (i) the vessel conveying unit moves the container to the angled bottom inspection station or (ii) components including the bottom light and side light move into positions adjacent the container to at least partially form the angled bottom inspection station;
c. either (i) the vessel conveying unit moves the container back to the transport line or (ii) components including the bottom light and side light move away from the container; and
d. the vessel conveying unit replaces the container to the transport line.

122. The system of any preceding embodiment, wherein movement of the vessel conveying unit and/or the components is controlled by at least one processor, optionally wherein the movement is fully automated.

123. The system of any preceding embodiment, in which the system comprises a bottom inspection station comprising:
the bottom camera; and
a bottom light, optionally a direct backlight, optionally a blue direct backlight.

124. The system of any preceding embodiment, in which the bottom camera comprises an ultra-high-resolution area scan camera.

125. The system of any preceding embodiment, in which the bottom inspection station is part of a transport line for a plurality of containers.

126. The system of any preceding embodiment, wherein the system is configured such that
a. a vessel conveying unit removes a container from the transport line;
b. either (i) the vessel conveying unit moves the container to the bottom inspection station or (ii) components including the bottom light and optionally side light move into positions adjacent the container to at least partially form the bottom inspection station;
c. either (i) the vessel conveying unit moves the container back to the transport line or (ii) components including the bottom light and optionally side light move away from the container; and
d. the vessel conveying unit replaces the container to the transport line.

127. The system of any preceding embodiment, wherein movement of the vessel conveying unit and/or the components is controlled by at least one processor, optionally wherein the movement is fully automated.

128. The system of any preceding embodiment, configured such that transfer of the container between each of the inspection stations and the transport line is controlled by at least one processor, optionally is fully automated.

129. The system of any preceding embodiment, further comprising a plurality of containers.

130. The system of any preceding embodiment, wherein the containers are each configured to store an injectable drug.

131. The system of any preceding embodiment, wherein the containers are vials, syringe barrels, or cartridges.

132. The system of any preceding embodiment, wherein the containers are vials.

133. The system of any preceding embodiment, wherein the system processes at least about 20,000 containers per day, at least about 30,000 containers per day, at least about 35,000 containers per day, or at least about 40,000 containers per day.

134. The system of any preceding embodiment, wherein the system processes at least about 30,000 containers per day.

135. The system of any preceding embodiment, wherein the system comprises one or more image analysis tools by which the one or more processors are configured to determine the size of a particle, the surface area of a particle, or both.

136. A method of inspecting a container for particles, defects, or both, using the system of any preceding embodiment.

### Application of Coating Set

137. A system for preparing a coating set on a vessel, optionally the vessel of any preceding embodiment, comprising:
a power supply, optionally a radio frequency (RF) power supply;
an electrode, the electrode comprising one or more cavities operable to receive a vessel;
a source gas line configured to provide one or more source gases into a lumen of a vessel positioned within one of the cavities;
a vacuum line configured to evacuate a lumen of a vessel positioned within one of the cavities;
a sealing unit positioned at the bottom of at least one of the cavities, the sealing unit comprising:
   a puck defining a central aperture and having an upper surface against which a portion of a vessel that surrounds an opening to the lumen, optionally an end surface of a flange, comes into contact when a vessel is positioned within the cavity; and
   a flexible seal that comes into contact with a portion of the vessel sidewall, optionally an outer surface of the flange, when a vessel is positioned within the cavity; the system being operable to:
   receive one or more vessels in the one or more cavities of the electrode;
   evacuate an internal volume of each of the one or more vessels;
   introduce one or more source gases into each of the one or more vessels;
   generate a plasma within each of the one or more vessels using the one or more source gases and a signal applied to the electrode by the power supply, optionally an RF signal applied to the electrode by the RF power supply; and
   deposit a coating on an inner surface of each of the one or more vessels using the plasma.

138. The system of any previous embodiment, further comprising a source gas inlet probe that extends into a lumen of a vessel positioned within the opening.

### New Puck

139. The system of any previous embodiment, in which at least a portion of the upper surface of the puck is configured to prevent particles, optionally flakes of coating, optionally flakes of coating from the source gas inlet probe, from contacting the portion of a vessel that surrounds an opening to the lumen, optionally a flange.

140. The system of any previous embodiment, in which at least a portion of the upper surface of the puck is configured to reduce the surface area of the puck in contact or close proximity with the vessel when a vessel is positioned within the cavity.

141. The system of any previous embodiment, in which at least a portion of the upper surface of the puck is inclined from the central aperture at an angle greater than 10 degrees, optionally greater than 15 degrees, optionally greater than 20 degrees, optionally greater than 25 degrees, optionally greater than 30 degrees, optionally greater than 35 degrees, optionally greater than 40 degrees, optionally 45 degrees or greater.

142. The system of any previous embodiment, in which the upper surface of the puck is inclined from the central aperture at an angle greater than 10 degrees, optionally greater than 15 degrees, optionally greater than 20 degrees, optionally greater than 25 degrees, optionally greater than 30 degrees, optionally greater than 35 degrees, optionally greater than 40 degrees, optionally 45 degrees or greater.

143. The system of any previous embodiment, the sealing unit further comprising a plasma screen positioned within the central aperture of the puck.

144. The system of any previous embodiment, wherein the inner wall of the puck comprises a ledge configured to support the plasma screen.

145. The system of any previous embodiment, in which the system is configured to accommodate a vessel selected from the following: a syringe barrel, a vial, or a blood collection tube; optionally a syringe barrel; optionally a vial; optionally a blood collection tube.

146. The system of any previous embodiment, in which the puck is made of a heat-resistant, non-conductive material; optionally a ceramic or a thermoplastic, e.g. polyether ether ketone (PEEK), material.

147. The system of any previous embodiment, wherein the flexible seal is an o-ring, optionally a silicone o-ring.

Sealing Unit Cleaning (Including w/Visual Inspection)

148. The system of any previous embodiment, further comprising a sealing unit cleaning system, the sealing unit cleaning system being configured to remove particles from the surfaces of the sealing unit that contact a vessel.

149. The system of any previous embodiment, wherein the sealing unit cleaning system comprises:
one or more inserts, each of the one or more inserts being configured to enter the one or more cavities, and each of the one more inserts defining a central passage;
one or more vacuum lines configured to create a vacuum within the central passage of each of the one or more inserts.

150. The system of any previous embodiment, in which each of the one or more inserts has an outer surface, the diameter of the outer surface being within ½-inch of a diameter of each of the one or more cavities.

151. The system of any previous embodiment, in which the sealing unit cleaning system is configured to position each of the one or more inserts at a plurality of depths in the one or more cavities.

152. The system of any previous embodiment, in which the sealing unit cleaning system is configured to hold each of the one or more inserts at each of a plurality of depths in the one or more cavities.

153. The system of any previous embodiment, wherein each of the one or more vacuum lines has an air flow of at least 400 cfm and a water lift of at least 35 inches.

154. The system of any previous embodiment, in which the sealing unit cleaning system is movable between at least (i) a first, cleaning position in which each of the one or more inserts is at least partially positioned within one of the one or more cavities, and (ii) a second, coating position in which the sealing unit cleaning system is positioned away from the coating system.

155. The system of any previous embodiment, in which movement of the sealing unit cleaning system is controlled by one or more processors.

156. A method comprising a step of removing particles from the sealing unit of the system of any of the previous embodiments, the step comprising:
a. positioning one or more inserts into the one or more cavities, each of the one or more inserts being operably connected to a vacuum line and vacuum pump; and
b. operating the vacuum pump, thereby pulling a vacuum within each of the one or more inserts.

157. The method of any previous embodiment, further comprising:
c. moving each of the one or more inserts to a plurality of depths within the one or more cavities during operation of the vacuum pump.

158. The method of any previous embodiment, further comprising:
d. holding each of the one or more inserts at each of a plurality of depths for a period of time during operation of the vacuum pump.

159. The method of any previous embodiment, further comprising deactivating the vacuum, removing the one or more inserts from the one or more cavities, and positioning the one or more inserts a distance away from the electrode that allows for one or more vessels to be positioned in the one or more cavities.

160. The method of any previous embodiment, wherein the diameter of an outer surface of each of the one or more inserts is within ½-inch of a diameter of each of the one or more cavities.

161. The method of any previous embodiment, wherein operation of the vacuum creates a pressure of 0.3 atm or less, optionally 0.2 atm or less, optionally 0.1 atm or less within a portion of each of the one or more cavities.

162. The method of any previous embodiment, wherein movement of the one or more inserts is controlled by one or more processors.

163. The method of any previous embodiment, further comprising a coating step comprising:
a. positioning one or more vessels in the one or more cavities of the electrode;
b. evacuating an internal volume of each of the one or more vessels;
c. introducing one or more source gases into each of the one or more vessels;
d. generating a plasma within each of the one or more vessels using the one or more source gases and a signal applied to the electrode by the power supply, optionally an RF signal applied to the electrode by the RF power supply;
e. depositing a coating on an inner surface of each of the one or more vessels using the plasma; and
f. removing the one or more vessels from the one or more cavities of the electrode.

164. The method of any previous embodiment, further comprising cleaning the interior surface, the exterior surface, or both the interior and exterior surface of the one or more vessels with pressurized gas, optionally pressurized air, optionally ionized and pressurized air, optionally pressurized nitrogen, optionally pressurized CO₂, prior to positioning the one or more vessels in the one or more cavities of the electrode.

165. The method of any previous embodiment, further comprising cleaning the interior surface, the exterior surface, or both the interior and exterior surface of the one or more vessels with pressurized gas, optionally pressurized air, optionally ionized and pressurized air, optionally pressurized nitrogen, optionally pressurized CO₂, after removing the one or more vessels from the one or more cavities of the electrode.

166. The method of any previous embodiment, further comprising applying a vacuum during the cleaning of the one or more vessels to capture any particles dislodged by the pressurized gas.

167. The method of any previous embodiment, further comprising alternating between the coating step and the step of removing particles from the sealing unit.

168. The method of any previous embodiment, further comprising performing the step of removing particles from the sealing unit after a defined number of coating steps.

169. The method of any previous embodiment, wherein the defined number of coating steps has been determined by visual inspection of the sealing unit of each of the one or more cavities.

170. The method of any previous embodiment, further comprising a step of visual inspection of the sealing unit of each of the one or more cavities.

171. The method of any previous embodiment, wherein the visual inspection is performed after each coating step.

172. The method of any previous embodiment, wherein the visual inspection is performed after each step of removing particles from the sealing unit.

173. The method of any previous embodiment, wherein the visual inspection comprises obtaining an image of the sealing unit of each of the one or more cavities by one or more cameras positioned above the electrode.

174. The method of any previous embodiment, wherein the obtaining an image of the sealing unit of each of the one or more cavities further comprises applying light into the one or more cavities, optionally by one or more isotropic linear lights.

175. The method of any previous embodiment, wherein the obtaining an image of the sealing unit of each of the one or more cavities further comprises adjusting the position and spectral power distribution of the one or more lights.

176. The method of any previous embodiment, wherein the one or more lights have wavelengths in the visible spectrum, the IR spectrum, or a combination thereof.

177. The method of any previous embodiment, wherein the visual inspection further comprises having one or more processors analyze each image to determine whether the amount of particles present on the sealing unit, the size of one or more particles present on the sealing unit, or a combination thereof meet or exceed a threshold to initiate the step of removing particles from the sealing unit.

178. The method of any previous embodiment, further comprising initiating the step of removing particles from the sealing unit if the amount of particles present on the sealing unit, the size of one or more particles present on the sealing unit, or a combination thereof meet or exceed the threshold.

### Visual Inspection of Sealing Unit (Independent of Cleaning Step)

179. The system of any preceding embodiment, further comprising a sealing unit inspection station configured to inspect the sealing units for particles.

180. The system of any preceding embodiment, wherein the sealing unit inspection station comprises
one or more cameras configured to obtain an image of the sealing unit of each of the one or more cavities, and
one or more processors configured to analyze the image taken by the one or more cameras and detect the presence of particles.

181. The system of any preceding embodiment, further comprising one or more lights configured to illuminate the one or more cavities, optionally wherein the one or more lights comprise one or more isotropic linear lights.

182. The system of any preceding embodiment, wherein the one or more cameras and the one or more lights are on a movable assembly.

183. The system of any preceding embodiment, wherein the one or more lights are moveable relative to the one or more cavities to illuminate the one or more cavities at any angle from directly above to obliquely during image acquisition.

184. The system of any preceding embodiment, wherein the one or more lights are configured to illuminate the one or more cavities from above.

185. The system of any preceding embodiment, wherein a variety of spectral power distributions may be emitted by the one or more lights.

186. The system of any preceding embodiment, wherein the one or more lights have wavelengths in the visible spectrum, the IR spectrum, or a combination thereof.

187. The system of any preceding embodiment, wherein the one or more processors are configured to analyze the image to detect the amount of particles present on the sealing unit, the size of one or more particles present on the sealing unit, or a combination thereof.

188. The system of any preceding embodiment, wherein the one or more processors are configured to analyze the image to determine whether the amount of particles present on the sealing unit, the size of one or more particles present on the sealing unit, or a combination thereof meet or exceed a threshold value.

189. A method of visually inspecting the sealing unit of the system of any of the previous embodiments, the method comprising:
a. obtaining an image of the sealing unit of each of the one or more cavities by one or more cameras positioned above the electrode; and
b. analyzing the image by one or more processors to detect the amount of particles present on the sealing unit, the size of one or more particles present on the sealing unit, or both.

190. The method of any previous embodiment, wherein the obtaining an image of the sealing unit of each of the one or more cavities further comprises applying light into the one or more cavities, optionally by one or more isotropic linear lights.

191. The method of any previous embodiment, wherein the obtaining an image of the sealing unit of each of the one or more cavities further comprises adjusting the position and spectral power distribution of the one or more lights.

192. The method of any previous embodiment, wherein the one or more lights have wavelengths in the visible spectrum, the IR spectrum, or a combination thereof.

193. The method of any previous embodiment, further comprising initiating a step of removing particles from the sealing unit if the amount of particles present on the sealing unit, the size of one or more particles present on the sealing unit, or a combination thereof meet or exceed a threshold value.

194. The method of any previous embodiment, further comprising replacing a source gas inlet probe if the amount of particles present on the sealing unit, the size of one or more particles present on the sealing unit, or a combination thereof meet or exceed a threshold value.

195. The method of any previous embodiment, further comprising a coating step comprising:
a. positioning one or more vessels in the one or more cavities of the electrode;
b. evacuating an internal volume of each of the one or more vessels;
c. introducing one or more source gases into each of the one or more vessels;
d. generating a plasma within each of the one or more vessels using the one or more source gases and a signal applied to the electrode by the power supply, optionally an RF signal applied to the electrode by the RF power supply;
e. depositing a coating on an inner surface of each of the one or more vessels using the plasma; and
f. removing the one or more vessels from the one or more cavities of the electrode.

196. The method of any previous embodiment, further comprising cleaning the interior, exterior, or interior and exterior surface of the one or more vessels with pressurized gas, optionally pressurized air, optionally ionized and pressurized air, optionally pressurized nitrogen, optionally pressurized CO₂, prior to positioning the one or more vessels in the one or more cavities of the electrode.

197. The method of any previous embodiment, further comprising cleaning the interior, exterior, or interior and exterior surface of the one or more vessels with pressurized gas, optionally pressurized air, optionally ionized and pressurized air, optionally pressurized nitrogen, optionally pressurized CO₂, after removing the one or more vessels from the one or more cavities of the electrode.

198. The method of any previous embodiment, further comprising applying a vacuum during the cleaning of the one or more vessels to capture any particles dislodged by the pressurized gas.

199. The method of any previous embodiment, wherein the visual inspection is performed after each coating step.

200. The method of any previous embodiment, further comprising performing the following if the amount of particles present on the sealing unit, the size of one or more particles present on the sealing unit, or a combination thereof meet or exceed the threshold:
removing particles from the sealing unit;
replacing the puck, the flexible seal, or both;
replacing the gas source inlet probe; or
any combination thereof.
   Removal of Particles from Vessel Contact Surfaces

201. A method of preparing a vessel having reduced particles, the method comprising:
a. providing a system for preparing a coating set on a vessel comprising
a power supply, optionally a radio frequency (RF) power supply;
an electrode, the electrode comprising one or more cavities operable to receive a vessel;
a source gas line configured to provide one or more source gases into a lumen of a vessel positioned within one of the cavities;
a vacuum line configured to evacuate a lumen of a vessel positioned within one of the cavities;
a sealing unit positioned at the bottom of at least one of the cavities, the sealing unit comprising:
   a puck defining a central aperture and having an upper surface against which a portion of a vessel that surrounds an opening to the lumen, optionally an end surface of a flange, comes into contact when a vessel is positioned within the cavity; and
   a flexible seal that comes into contact with a portion of the vessel sidewall, optionally an outer surface of the flange, when a vessel is positioned within the cavity;
b. coating an inner surface of one or more vessels by
   i. positioning the one or more vessels in the one or more cavities of the electrode;
   ii. evacuating an internal volume of each of the one or more vessels;
   iii. introducing one or more source gases into each of the one or more vessels;
   iv. generating a plasma within each of the one or more vessels using the one or more source gases and a signal applied to the electrode by the power supply, optionally an RF signal applied to the electrode by the RF power supply;
   v. depositing a coating on an inner surface of each of the one or more vessels using the plasma; and
   vi. removing the one or more vessels from the one or more cavities of the electrode.
c. treating the one or more vessels to remove particles from at least the portion of each vessel that comes into contact with the sealing unit.

202. The method of any previous embodiment, further comprising treating the one or more vessels to remove particles from each vessel prior to positioning the one or more vessels in the one or more cavities of the electrode, optionally wherein the treating comprises contacting the interior, the exterior, or the interior and exterior surface of each vessel with pressurized gas, optionally pressurized air, optionally ionized and pressurized air, optionally pressurized nitrogen, optionally pressurized CO₂.

203. A method of treating a vessel provided with a coating by the system of any preceding embodiment to remove particles from at least a portion of the vessel that comes into contact with the sealing unit.

204. The method of any previous embodiment wherein removing particles from at least the portion of the vessel that comes into contact with the sealing unit comprises:
a. inserting the vessel into a chamber of a cleaning station;
b. spraying at least a portion of the vessel that comes into contact with the sealing unit, i.e. the portion of the vessel surrounding an opening to the lumen, optionally comprising the upper and outer surfaces of a flange, with pressurized gas, optionally pressurized air, optionally pressurized ionized air, optionally pressurized nitrogen, optionally pressurized CO₂; and
c. applying a vacuum within the chamber to remove any dislodged particles from the chamber.

205. A method of removing particles from a vessel, the vessel having a lumen defined at least in part by a side wall, the side wall having an inner surface facing the lumen and an outer surface, the method comprising:
a. inserting the vessel into a chamber of a cleaning station;
b. spraying at least a portion of the vessel surrounding an opening to the lumen, optionally upper and outer surface of a flange, with pressurized gas, optionally pressurized air, optionally pressurized ionized air, optionally pressurized nitrogen, optionally pressurized CO₂; and
c. applying a vacuum within the chamber to remove any dislodged particles from the chamber.

206. The method of any previous embodiment, wherein the inner surface of the vessel comprises a coating set that is at least partially applied by PECVD.

207. The method of any previous embodiment, wherein the spraying is performed by one or more nozzles positioned in substantial alignment with a portion of the outer surface of the side wall adjacent the opening to the lumen, optionally an outer surface of a flange, and directed substantially perpendicular to the longitudinal axis of the vessel.

208. The method of any previous embodiment, wherein the spraying is performed by one or more nozzles positioned above or below the vessel and directed toward an end surface of the vessel that immediately surrounds the opening to the lumen, optionally an end surface of a flange.

209. The method of any previous embodiment, wherein the one or more nozzles are directed at an angle between about 20 degrees and about 70 degrees, optionally between about 30 degrees and about 60 degrees, optionally between about 40 degrees and about 50 degrees, to the longitudinal axis of the vessel.

210. The method of any previous embodiment, wherein the portion of the vessel surrounding the opening to the lumen is sprayed with pressurized gas, optionally pressurized air, optionally pressurized ionized air, optionally pressurized nitrogen, optionally pressurized CO₂, by at least a first nozzle and a second nozzle, the first nozzle and the second nozzle having different positions and orientations relative to the vessel.

211. The method of any previous embodiment, wherein the first nozzle is positioned in substantial alignment with a portion of the outer surface of the side wall adjacent the opening to the lumen, optionally an outer surface of a flange, and directed substantially perpendicular to the longitudinal axis of the vessel.

212. The method of any previous embodiment, wherein the second nozzle is positioned above or below the vessel and directed toward an end surface of the vessel that immediately surrounds the opening to the lumen, optionally an end surface of a flange.

213. The method of any previous embodiment, wherein the second nozzle is directed at an angle between about 20 degrees and about 70 degrees, optionally between about 30 degrees and about 60 degrees, optionally between about 40 degrees and about 50 degrees, to the longitudinal axis of the vessel.

214. The method of any previous embodiment, further comprising rotating the vessel about its longitudinal axis during the spraying.

215. The method of any previous embodiment, wherein the spraying is performed by a plurality of nozzles located at different points circumferentially around the vessel.

216. The method of any previous embodiment, wherein the plurality of nozzles are substantially evenly spaced around the circumference of the vessel.

217. The method of any previous embodiment, wherein the spraying is performed by a plurality of nozzles positioned in substantial alignment with a portion of the outer surface of the side wall adjacent the opening to the lumen, optionally an outer surface of a flange, and directed substantially perpendicular to the longitudinal axis of the vessel, each of the plurality of nozzles being located at different points circumferentially around the vessel.

218. The method of any previous embodiment, wherein the spraying is performed by a plurality of nozzles positioned above or below the vessel and directed toward an end surface of the vessel that immediately surrounds the opening to the lumen, optionally an end surface of a flange, each of the plurality of nozzles being located at different points circumferentially around the vessel.

219. The method of any preceding embodiment, wherein the plurality of nozzles are substantially evenly spaced around the circumference of the vessel.

220. The method of any preceding embodiment, wherein the vessel is held with the opening to the lumen positioned downward.

221. The method of any preceding embodiment, wherein the end of the vessel opposite the opening to the lumen is held by a vessel holder.

222. The method of any preceding embodiment, wherein the spraying is performed in the presence of the vacuum.

223. The method of any preceding embodiment, wherein the pressurized gas is sprayed at a pressure of 100 psi or greater.

224. The method of any preceding embodiment, further comprising:
d. removing the vessel from the chamber.

225. The method of any preceding embodiment, wherein upon exiting the chamber, the portion of the vessel surrounding an opening to the lumen is substantially free from particles having a dimension of 50 microns or greater, optionally a dimension of 40 microns or greater, optionally a dimension of 30 microns or greater, optionally a dimension of 20 microns or greater.

226. The method of any preceding embodiment, wherein upon exiting the chamber, the portion of the vessel that comes into contact with the sealing unit is free or substantially free from particles having a dimension of 50 microns or greater, optionally a dimension of 40 microns or greater, optionally a dimension of 30 microns or greater, optionally a dimension of 20 microns or greater.

227. The method of any preceding embodiment, wherein upon exiting the chamber, the portion of the vessel surrounding the opening to the lumen and/or that comes into contact with the sealing unit is free or substantially free of particles having a surface area of 0.0019 mm² or greater.

228. A system for removing particles from a vessel, the vessel having a lumen defined at least in part by a side wall, the side wall having an inner surface facing the lumen and an outer surface, the system comprising:
a. a chamber configured to receive the vessel;
b. one or more nozzles configured to spray pressurized gas, optionally pressurized air, optionally pressurized ionized air, optionally pressurized nitrogen, optionally pressurized CO₂, toward the vessel, and in particular against at least a portion of the vessel surrounding an opening to the lumen, optionally upper and outer surface of a flange, when the vessel is received in the chamber; and
c. one or more vacuum lines operable to apply a vacuum within the chamber.

229. The system of any preceding embodiment, wherein the inner surface of the vessel comprises a coating set, the coating set being at least partially applied by PECVD.

230. The system of any preceding embodiment, wherein the one or more nozzles comprises at least one nozzle configured to be in substantial alignment with a portion of the outer surface of the vessel side wall adjacent the opening to the lumen, optionally an outer surface of a flange, and directed substantially perpendicular to the longitudinal axis of the vessel when the vessel is received in the chamber.

231. The system of any previous embodiment, wherein the one or more nozzles comprises at least one nozzle configured to be positioned above or below the vessel and directed toward an end surface of the vessel that immediately surrounds the opening to the lumen, optionally an end surface of a flange, when the vessel is received in the chamber.

232. The system of any previous embodiment, wherein the at least one nozzle is configured to be directed at an angle between about 20 degrees and about 70 degrees, optionally between about 30 degrees and about 60 degrees, optionally between about 40 degrees and about 50 degrees, to the longitudinal axis of the vessel when the vessel is received in the chamber.

233. The system of any previous embodiment, comprising at least a first nozzle and a second nozzle, the first nozzle and the second nozzle having different positions and orientations relative to the vessel.

234. The system of any previous embodiment, wherein the first nozzle is configured to be positioned in substantial alignment with a portion of the outer surface of the side wall adjacent the opening to the lumen, optionally an outer surface of a flange, and directed substantially perpendicular to the longitudinal axis of the vessel when the vessel is received in the chamber.

235. The system of any previous embodiment, wherein the second nozzle is configured to be positioned above or below the vessel and directed toward an end surface of the vessel that immediately surrounds the opening to the lumen, optionally an end surface of a flange, when the vessel is received in the chamber.

236. The system of any previous embodiment, wherein the second nozzle is configured to be directed at an angle between about 20 degrees and about 70 degrees, optionally between about 30 degrees and about 60 degrees, optionally between about 40 degrees and about 50 degrees, to the longitudinal axis of the vessel when the vessel is received in the chamber.

237. The system of any previous embodiment, wherein a plurality of nozzles are located at different points circumferentially around the vessel when the vessel is received in the chamber.

238. The system of any previous embodiment, wherein the plurality of nozzles are substantially evenly spaced around the circumference of the vessel when the vessel is received in the chamber.

239. The system of any previous embodiment, wherein a plurality of nozzles are positioned in substantial alignment with a portion of the outer surface of the vessel side wall adjacent the opening to the lumen, optionally an outer surface of a flange, and directed substantially perpendicular to the longitudinal axis of the vessel, each of the plurality of nozzles being located at different points circumferentially around the vessel, when the vessel is received in the chamber.

240. The system of any previous embodiment, wherein a plurality of nozzles are positioned above or below the vessel and directed toward an end surface of the vessel that immediately surrounds the opening to the lumen, optionally an end surface of a flange, each of the plurality of nozzles being located at different points circumferentially around the vessel, when the vessel is received in the chamber.

241. The system of any preceding embodiment, wherein the plurality of nozzles are substantially evenly spaced around the circumference of the vessel when the vessel is received in the chamber.

242. The system of any preceding embodiment, wherein the chamber is configured for the vessel to be received in the chamber with the opening to the lumen positioned downward.

243. The system of any preceding embodiment, further comprising a vessel holder that is configured to hold the vessel in the chamber.

244. The system of any preceding embodiment, wherein the vessel holder is configured to contact the end of the vessel opposite the opening to the lumen.

245. The system of any previous embodiment, wherein the vessel holder is configured to rotate the vessel about its longitudinal axis.

246. The system of any previous embodiment, wherein the vessel holder is configured to move the vessel into and out of the chamber.

Removal of Particles from Inner Surfaces of Vessel

247. The method of any preceding embodiment, further comprising treating the one or more vessels, optionally after coating the one or more vessels, to remove particles from the inner surface of the vessels.

248. A method of preparing a vessel having reduced particles, comprising:
a. coating an inner surface of one or more vessels by
   i. positioning the one or more vessels in one or more cavities of an electrode;
   ii. evacuating an internal volume of each of the one or more vessels;
   iii. introducing one or more source gases into each of the one or more vessels;
   iv. generating a plasma within each of the one or more vessels using the one or more source gases and a signal applied to the electrode by a power supply, optionally an RF signal applied to the electrode by an RF power supply;
   v. depositing a coating on an inner surface of each of the one or more vessels using the plasma; and
   vi. removing the one or more vessels from the one or more cavities of the electrode; and
b. after coating the one or more vessels, treating the one or more vessels to remove particles from the inner surface of the vessels.

249. The method of any previous embodiment, further comprising treating the one or more vessels to remove particles from each vessel prior to positioning the one or more vessels in the one or more cavities of the electrode, optionally wherein the treating comprises contacting the interior surface, the exterior surface, or the interior and exterior surfaces of each vessel with pressurized gas, optionally pressurized air, optionally pressurized ionized air, optionally pressurized nitrogen, optionally pressurized CO₂.

250. The method of any preceding embodiment, wherein treating the one or more vessels to remove particles from the inner surfaces of the vessels comprises:
a. positioning the vessel in a cleaning station;
b. inserting an air blower probe through an opening of the vessel and into the lumen;
c. spraying pressurized gas, optionally pressurized air, optionally pressurized ionized air, optionally pressurized nitrogen, optionally pressurized CO₂, against the inner surface of the side wall lumen; and
d. applying a vacuum within the lumen to remove any dislodged particles through the opening of the vessel.

251. A method of removing particles from the inner surface of a vessel, the vessel having a lumen defined at least in part by a side wall, the side wall having an inner surface facing the lumen and an outer surface, the method comprising:
a. positioning the vessel in a cleaning station;
b. inserting a gas blower probe through an opening of the vessel and into the lumen;
c. spraying pressurized gas, optionally pressurized air, optionally pressurized ionized air, optionally pressurized nitrogen, optionally pressurized CO₂, out of the air blower probe and against the inner surface of the side wall lumen; and
d. applying a vacuum within the lumen to remove any dislodged particles through the opening of the vessel.

252. The method of any previous embodiment, wherein the inner surface of the vessel comprises a coating set that is at least partially applied by PECVD.

253. The method of any previous embodiment, further comprising rotating the gas blower probe during the spraying.

254. The method of any previous embodiment, further comprising moving the gas blower probe longitudinally within the lumen during the spraying.

255. The method of any previous embodiment, wherein the pressurized gas is sprayed out of the gas blower probe at a pressure of 60 psi or greater.

256. The method of any previous embodiment, wherein the spraying is performed in the presence of the vacuum.

257. The method of any previous embodiment, wherein positioning the vessel in the cleaning station comprises forming a gas-tight seal with a portion of the vessel sidewall, optionally an outer surface of a flange.

258. The method of any previous embodiment, further comprising
e. removing the vessel from the cleaning station.

259. The method of any preceding embodiment, wherein upon exiting the cleaning station, the inner surface of the vessel side wall is free or substantially free from particles having a dimension of 50 microns or greater, optionally a dimension of 40 microns or greater, optionally a dimension of 30 microns or greater, optionally a dimension of 20 microns or greater.

260. The method of any preceding embodiment, wherein upon exiting the cleaning station, the inner surface of the vessel side wall is free or substantially free of particles having a surface area of 0.0019 mm² or greater.

### Combined Methods

261. A method of preparing coated vessels that are substantially free from particles, the method comprising:
a. providing a system for preparing a coating set on one or more vessels, comprising
a power supply, optionally a radio frequency (RF) power supply;
an electrode, the electrode comprising one or more cavities configured to receive a vessel;
a source gas line configured to provide one or more source gases into a lumen of a vessel positioned within one of the cavities;
a vacuum line configured to evacuate a lumen of a vessel positioned within one of the cavities;
a sealing unit positioned at the bottom of at least one of the cavities, the sealing unit comprising:
   a puck defining a central aperture and having an upper surface against which a portion of a vessel that surrounds an opening to the lumen, optionally an end surface of a flange, comes into contact when a vessel is positioned within the cavity; and
   a flexible seal that comes into contact with a portion of the vessel sidewall, optionally an outer surface of the flange, when a vessel is positioned within the cavity;
b. coating an inner surface of one or more vessels by
   i. positioning the one or more vessels in the one or more cavities of the electrode;
   ii. evacuating an internal volume of each of the one or more vessels;
   iii. introducing one or more source gases into each of the one or more vessels;
   iv. generating a plasma within each of the one or more vessels using the one or more source gases and a signal applied to the electrode by the power supply, optionally an RF signal applied to the electrode by an RF power supply;
   v. depositing a coating on an inner surface of each of the one or more vessels using the plasma; and
   vi. removing one or more coated vessels from the one or more cavities of the electrode;
c. treating the one or more coated vessels to remove particles from the inner surfaces of the vessels; and
d. treating the one or more coated vessels to remove particles from the portion of each vessel that comes into contact with the sealing unit;
   wherein the resulting coated vessels are
(1) free or substantially free from particles having a dimension of 50 microns or greater, optionally a dimension of 40 microns or greater, optionally a dimension of 30 microns or greater, optionally a dimension of 25 microns or greater, optionally a dimension of 20 microns or greater;
(2) free or substantially free of particles having a surface area of 0.0019 mm² or greater; or
(3) both (1) and (2).

262. The method of any previous embodiment, further comprising treating the one or more vessels to remove particles from each vessel prior to positioning the one or more vessels in the one or more cavities of the electrode, optionally wherein the treating comprises contacting the interior, the exterior, or the interior and exterior surface of each vessel with pressurized gas, optionally pressurized air, optionally ionized and pressurized air, optionally pressurized nitrogen, optionally pressurized CO₂.

263. The method of any preceding embodiment, wherein treating the one or more vessels to remove particles from the inner surfaces of the vessels comprises:
a. positioning the vessel in a cleaning station;
b. inserting a gas blower probe through an opening of the vessel and into the lumen;
c. spraying pressurized gas, optionally pressurized air, optionally pressurized ionized air, optionally pressurized nitrogen, optionally pressurized CO₂, against the inner surface of the side wall lumen; and
d. applying a vacuum within the lumen to remove any dislodged particles through the opening of the vessel.

264. The method of any previous embodiment wherein removing particles from the portion of the vessel that comes into contact with the sealing unit comprises:
a. inserting the vessel into a chamber of a cleaning station;
b. spraying at least a portion of the vessel that comes into contact with the sealing unit, i.e. the portion of the vessel surrounding an opening to the lumen, optionally comprising the upper and outer surfaces of a flange, with pressurized gas, optionally pressurized air, optionally pressurized ionized air, optionally pressurized nitrogen, optionally pressurized CO₂; and
c. applying a vacuum within the chamber to remove any dislodged particles from the chamber.

265. The method of any previous embodiment, further comprising treating the sealing unit to remove particles before the coating step, optionally wherein treating the sealing unit to remove particles is by the method of any previous embodiment.

### Containers

266. A pharmaceutical container coated, cleaned, and/or inspected by the method of any previous embodiment.

267. A vial coated, cleaned, and/or inspected by the method of any previous embodiment.

268. A syringe barrel or injection cartridge coated, cleaned, and/or inspected by the method of any previous embodiment.

269. A blood collection tube coated, cleaned, and/or inspected by the method of any previous embodiment.

270. The container, optionally vial, syringe barrel, injection cartridge, or blood collection tube, of any previous embodiment, wherein the vessel has been inspected and found to be free of particles sized between 80 and 500 microns, optionally between 70 and 500 microns, optionally between 60 and 500 microns, optionally between 50 and 500 microns, optionally between 40 and 500 microns, optionally between 30 and 500 microns, optionally between 25 and 500 microns.

271. The container, optionally vial, syringe barrel, injection cartridge, or blood collection tube, of any previous embodiment, wherein the vessel has been inspected and found to be free of particles having a surface area of 0.0019 mm² or greater.

272. A batch or lot of containers, optionally vials, syringe barrels, injection cartridges, or blood collection tubes, of any previous embodiment, in which the containers have been inspected for particles between 80 and 500 microns, optionally between 70 and 500 microns, optionally between 60 and 500 microns, optionally between 50 and 500 microns, optionally between 40 and 500 microns, optionally between 30 and 500 microns, optionally between 25 and 500 microns, and
the batch or lot has an AQL less than 0.5, optionally less than 0.4, optionally less than 0.3, optionally less than 0.2, optionally 0.1 or less.

273. A vial comprising:
a lumen defined at least in part by a side wall and a bottom wall,
   the side wall having an interior surface facing the lumen and an outer surface;
   the bottom wall having an upper surface facing the lumen and a lower surface;
an opening to the lumen located opposite the bottom wall;
the side wall comprising
   a body region,
   a neck region having a reduced diameter relative to the body region,
   a shoulder region between the body region and the neck region, and
   a transition region between the body region and the bottom wall.
   wherein using an automated system, the vial has been inspected and found to be free of
   (1) particles sized between 80 and 500 microns, optionally between 70 and 500 microns, optionally between 60 and 500 microns, optionally between 50 and 500 microns, optionally between 40 and 500 microns, optionally between 30 and 500 microns, optionally between 25 and 500 microns;
   (2) particles having a surface area of 0.0019 mm² or greater; or
   (3) both (1) and (2).

274. A batch or lot of vials in which the vials have been inspected for particles between 80 and 500 microns, optionally between 70 and 500 microns, optionally between 60 and 500 microns, optionally between 50 and 500 microns, optionally between 40 and 500 microns, optionally between 30 and 500 microns, optionally between 25 and 500 microns, and
the batch or lot has an AQL less than 0.5, optionally less than 0.4, optionally less than 0.3, optionally less than 0.2, optionally 0.1 or less;
   wherein each vial comprises
a lumen defined at least in part by a side wall and a bottom wall,
   the side wall having an interior surface facing the lumen and an outer surface;
   the bottom wall having an upper surface facing the lumen and a lower surface;
an opening to the lumen located opposite the bottom wall;
the side wall comprising
   a body region,
   a neck region having a reduced diameter relative to the body region,
   a shoulder region between the body region and the neck region, and
   a transition region between the body region and the bottom wall.

275. The vial or vials of any preceding embodiment, in which the vial has been inspected by the method of any previous embodiment.

276. The vial or vials of any preceding embodiment, in which the vial has been inspected using the system of any previous embodiment.

### Fully Automated System

277. A system for producing a plurality of pharmaceutical containers coated, cleaned, and/or inspected by the method of any previous embodiment.

278. The system of any preceding embodiment 277, the system comprising:
a) one or more systems for preparing a coating set on a plurality of pharmaceutical containers (“coating sytems”), comprising:
   a. optionally, one or more sealing unit inspection stations, and
   b. optionally, one or more sealing unit cleaning systems;
b) one or more systems for removing particles from a plurality of pharmaceutical containers (“cleaning systems”), and
c) one or more systems for inspecting a plurality of pharmaceutical containers (“inspection systems”).

279. A system comprising
a. one or more coating systems comprising the system for preparing a coating set on a vessel of any preceding embodiment, optionally including the sealing unit cleaning system of any preceding embodiment and/or the sealing unit inspection station of any preceding embodiment;
b. one or more cleaning systems comprising:
   i. the system for removing particles from a vessel and in particular from at least a portion of the vessel surrounding an opening to the lumen of any preceding embodiment;
   ii. a system for removing particles from the inner surface of the vessel; or
   iii. both i. and ii.; and
c. one or more inspection systems comprising the system for inspecting a pharmaceutical container of any preceding embodiment.

280. The system of any preceding embodiment, further comprising one or more transport lines, wherein the transport lines transport the plurality of pharmaceutical containers between the one or more coating systems, the one or more cleaning systems, and the one or more inspection systems.

281. The system of any preceding embodiment, wherein the one or more transport lines, the one or more coating systems, the one or more cleaning systems, and the one or more inspection systems are each controlled by one or more processors, optionally where they are fully automated.

282. The system of any preceding embodiment, wherein the system is configured to store information related to one or more operational parameters associated with the manufacturing of the pharmaceutical containers into a database.

283. The system of any preceding embodiment, wherein the system is configured to analyze the stored information to identify one or more operational parameters associated with the manufacturing of the pharmaceutical containers that are associated with an increased particulate burden or an increased number of defects.

284. The system of any preceding embodiment, wherein the system is configured to alter one or more operational parameters identified as being associated with an increased particulate burden or an increased number of defects.

285. The system of any preceding embodiment, wherein the system is configured to test permutations in the one or more operational parameters associated with the manufacturing of the pharmaceutical containers in order to increase the speed of producing a plurality of pharmaceutical containers while maintaining particulate burden and/or defective pharmaceutical containers below a set threshold.

Please amend the claims as set forth below:

1. A method of preparing coated vessels that are substantially free from particles, the method comprising:
a. providing a system for preparing a coating set on one or more vessels, comprising
a power supply, optionally a radio frequency (RF) power supply;
an electrode, the electrode comprising one or more cavities configured to receive a vessel;
a source gas line configured to provide one or more source gases into a lumen of a vessel positioned within one of the cavities;
a vacuum line configured to evacuate a lumen of a vessel positioned within one of the cavities;
a sealing unit positioned at the bottom of at least one of the cavities, the sealing unit comprising:
a puck defining a central aperture and having an upper surface against which a portion of a vessel that surrounds an opening to the lumen, optionally an end surface of a flange, comes into contact when a vessel is positioned within the cavity; and
a flexible seal that comes into contact with a portion of the vessel sidewall, optionally an outer surface of the flange, when a vessel is positioned within the cavity;
b. coating an inner surface of one or more vessels by
i. positioning the one or more vessels in the one or more cavities of the electrode;
ii. evacuating an internal volume of each of the one or more vessels;
iii. introducing one or more source gases into each of the one or more vessels;
iv. generating a plasma within each of the one or more vessels using the one or more source gases and a signal applied to the electrode by the power supply, optionally an RF signal applied to the electrode by an RF power supply;
v. depositing a coating on an inner surface of each of the one or more vessels using the plasma; and
vi. removing one or more coated vessels from the one or more cavities of the electrode;
c. treating the one or more coated vessels to remove particles from the inner surfaces of the vessels; and
d. treating the one or more coated vessels to remove particles from the portion of each vessel that comes into contact with the sealing unit;
wherein the resulting coated vessels are
(1) free or substantially free from particles having a dimension of 50 microns or greater, optionally a dimension of 40 microns or greater, optionally a dimension of 30 microns or greater, optionally a dimension of 25 microns or greater, optionally a dimension of 20 microns or greater;
(2) free or substantially free of particles having a surface area of 0.0019 mm² or greater; or
(3) both (1) and (2).

2. The method of claim 1, further comprising treating the one or more vessels to remove particles from each vessel prior to positioning the one or more vessels in the one or more cavities of the electrode, optionally wherein the treating comprises contacting the interior, the exterior, or the interior and exterior surface of each vessel with pressurized gas, optionally pressurized air, optionally ionized and pressurized air, optionally pressurized nitrogen, optionally pressurized CO₂.

3. The method of claim 1, wherein treating the one or more vessels to remove particles from the inner surfaces of the vessels comprises:
a. positioning the vessel in a cleaning station;
b. inserting a gas blower probe through an opening of the vessel and into the lumen;
c. spraying pressurized gas, optionally pressurized air, optionally pressurized ionized air, optionally pressurized nitrogen, optionally pressurized CO₂, against the inner surface of the side wall lumen; and
d. applying a vacuum within the lumen to remove any dislodged particles through the opening of the vessel.

4. The method of claim 1, wherein removing particles from the portion of the vessel that comes into contact with the sealing unit comprises:
a. inserting the vessel into a chamber of a cleaning station;
b. spraying at least a portion of the vessel that comes into contact with the sealing unit, i.e. the portion of the vessel surrounding an opening to the lumen, optionally comprising the upper and outer surfaces of a flange, with pressurized gas, optionally pressurized air, optionally pressurized ionized air, optionally pressurized nitrogen, optionally pressurized CO₂; and
c. applying a vacuum within the chamber to remove any dislodged particles from the chamber.

5. The method of claim 1, further comprising treating the sealing unit to remove particles before the coating step, optionally wherein treating the sealing unit to remove particles is by the method of any previous claim.

6. A system for producing a plurality of pharmaceutical containers coated, cleaned, and/or inspected by the method of claim 1.

7. (canceled)

8. A system comprising:
a. one or more coating systems for preparing a coating set on an inner surface of a pharmaceutical container that defines a lumen, optionally including a sealing unit cleaning system and/or a sealing unit inspection station;
b. one or more cleaning systems comprising:
i. a system for removing particles from at least a portion of the vessel pharmaceutical container surrounding an opening to the lumen;
ii. a system for removing particles from the inner surface of the pharmaceutical container; or
iii. both i. and il.; and
c. one or more inspection systems comprising a system for inspecting the pharmaceutical container.

9. The system of claim 8, further comprising one or more transport lines, wherein the one or more transport lines transport a plurality of pharmaceutical containers between the one or more coating systems, the one or more cleaning systems, and the one or more inspection systems.

10. The system of claim 9, wherein the one or more transport lines, the one or more coating systems, the one or more cleaning systems, and the one or more inspection systems are each controlled by one or more processors, optionally where they are fully automated.

11. The system of claim 8, wherein the system is configured to store information related to one or more operational parameters associated with the manufacturing of a plurality of the pharmaceutical containers into a database.

12. The system of claim 11, wherein the system is configured to analyze the stored information to identify one or more operational parameters associated with the manufacturing of the pharmaceutical containers that are associated with an increased particulate burden or an increased number of defects.

13. The system of claim 12, wherein the system is configured to alter one or more operational parameters identified as being associated with an increased particulate burden or an increased number of defects.

14. The system of claim 13, wherein the system is configured to test permutations in the one or more operational parameters associated with the manufacturing of the pharmaceutical containers in order to increase the speed of producing a plurality of pharmaceutical containers while maintaining particulate burden and/or defective pharmaceutical containers below a set threshold.

15. A pharmaceutical container, optionally vial, syringe barrel, injection cartridge, or blood collection tube, that is coated, cleaned, and inspected by the method of claim 1.

16. The pharmaceutical container, optionally vial, syringe barrel, injection cartridge, or blood collection tube, of claim 15, wherein the container has been inspected and found to be free of particles having a surface area of 0.0019 mm² or greater.

17. A vial comprising:
a lumen defined at least in part by a side wall and a bottom wall,
the side wall having an interior surface facing the lumen and an outer surface;
the bottom wall having an upper surface facing the lumen and a lower surface;
an opening to the lumen located opposite the bottom wall;
the side wall comprising
a body region,
a neck region having a reduced diameter relative to the body region,
a shoulder region between the body region and the neck region, and
a transition region between the body region and the bottom wall,
wherein using an automated system, the vial has been inspected and found to be free of
(1) particles sized between 80 and 500 microns, optionally between 70 and 500 microns, optionally between 60 and 500 microns, optionally between 50 and 500 microns, optionally between 40 and 500 microns, optionally between 30 and 500 microns, optionally between 25 and 500 microns;
(2) particles having a surface area of 0.0019 mm² or greater; or
(3) both (1) and (2).
